(19) United States
(12) Patent Application Publication
(10) Pub. No.: US 2024/0404833 A1
(43) Pub. Date: Dec. 5, 2024

(54) ETCHING METHODS USING SILICON-CONTAINING HYDROFLUOROCARBONS

(71) Applicant: L'Air Liquide, Société Anonyme pour I'Etude et I'Exploitation des Procédés Georges Claude, Paris (FR)

(72) Inventors: Nicolas GOSSET, Yokosuka (JP); Vladislav GAMALEEV, Yokosuka (JP); Tomo HASEGAWA, Yokosuka (JP)

(21) Appl. No.: 18/702,402

(22) PCT Filed: Oct. 18, 2022
(86) PCT No.: PCT/US2022/046985

§ 371 Date: Apr. 18, 2024

Related U.S. Application Data
(60) Provisional application No. 63/256,698, filed on Oct. 18, 2021.

(51) Int. Cl. H01L 21/3065; C09K 13/00; H01L 21/311

(52) U.S. Cl. CPC H01L 21/3065; C09K 13/00; H01L 21/31116

(57) ABSTRACT

Methods of plasma dry etching employing an etching gas mixture containing a compound that has a general formula: where 1≤x≤6, 1≤y≤9, 1≤z≤15, n=1 or 2. In some embodiments, the compound contains one or more methyl group(s) and at least one methyl group is attached to the Si atom. The methods include HAR dry etching processes. selective dry etching processes and cyclic selective dry etching processes.

### CROSS-REFERENCE TO RELATED APPLICATIONS

This application claims the benefit of the filing date of U.S. provisional application No. 63/256,698, filed on Oct. 18, 2021, the teachings of which are incorporated herein by reference.

### TECHNICAL FIELD

The present invention relates to methods for dry etching of an etching film such as silicon-containing films, metal-containing films and organic films, in particular, to dry etching methods, selective dry etching methods and cyclic selective dry etching methods for dry etching of the etching films employing an etching gas mixture including a Si-containing hydrofluorocarbon compound that has a general formula:

CₓH_{y}F_{z}Siₙ (I)

where 1≤x≤6, 1≤y≤9, 1≤z≤15, n=1 or 2. In some embodiments, the Si-containing hydrofluorocarbon contains at least one methyl group or comprises at least one methyl group attached to the Si atom.

### BACKGROUND

Recently the control of the profile (control of shape, reduced defects and damage to the structure, etc.) and etching speed during formation of high aspect ratio structures (holes, pillars, etc.) became a significant challenge for the fabrication of new semiconductor devices (3D NAND and DRAM memories, low-k dielectric in BEOL). These devices, which are based on thick stacks of silicon oxide and/or alternated layers of silicon nitride and oxide, need to be etched with a fast etch rate and keeping a defined profile (no etch stop, bowing, twisting, or other pattern distortions).

Selective etching of various Si-containing compounds with high selectivity to each other in the same process is required for advanced patterning. Most preferable is so-called “infinite selectivity” regime where non-etching material is not etched or some polymer is deposited on top of it when an etching target material is effectively removed during etching process. Main drawback of this process is deposition of polymer on non-etching material and development of polymer thickness with increase of process time. In the case of advanced patterning presence of thick polymer film after the process will require additional cleaning step, which can cause unintentional modification of films on substrate or damage those films, further limit applicability of certain etching processes with infinite selectivity. This invention provides a new cyclic etching process utilizing Si-containing chemistry to achieve infinite selectivity of etching while not growing thick film of polymer on top of non-etching material or chamber walls. In the present disclosure we demonstrated that addition of Si-containing hydrofluorocarbon to the process gas mixture at least one step of the cyclic etching allows to increase selectivity by growth of polymer on non-etching material, when use of etching process with low selectivity during another step of cyclic etching allows to effectively control thickness of deposited polymer. In particular, it is demonstrated that it is possible to etch Si₃N₄ (or SiO₂) with high selectivity to other tested materials when either thin film of polymer or thin interface layer is formed on surface of non-etching material after the cyclic etching.

Plasma etching method using an etching gas is a key process used for production of semiconductor devices on a substrate. Etching allows to remove material from surface of a substrate, moreover in particular cases it is possible to remove one material selectively to other using dry etching process, which allows to form fine pattern on surface of a substrate. Patterning of various thin films on a workpiece or substrate allows to form components of semiconductor device (e.g. transistors and capacitors, interconnects, signal lines and insulation). Examples of thin films commonly used in fabrication of semiconductor devices are silicon-containing compounds (e.g. polycrystalline silicon, silicon oxide or nitride), organic films (having carbon as a main component), metals, metal oxides or nitrides. For state of art semiconductor devices with most advanced technical nodes, patterning in nanometer or tens of nanometers scale order is required.

Due to the extremely small size of pattern and complex structure at the front end of semiconductor device, extremely high selectivity of the etching process to materials not targeted by the etching is required. Example of such process is so-called “multicolor etching” or “low contrast etching”, where a substrate containing multi-line layer consisting of several materials is exposed during the etching process and only one or several materials of multi-line layer are targeted to be etched. Multicolor etching and similar selective etching processes are crucial for formation of active components in front end of line, interconnects, self-aligned patterning (e.g. self-aligned multiple patterning for lithography and self-aligned contact hole etch) and other fine structures on substrate; therefore, poor selectivity and etching defects related to poor selectivity may result in degraded performance or even compromised functionality of produced semiconductor device.

Various etching processes (e.g. plasma etching, atomic layer etching, thermal etching, and wet etching) and chemistries (e.g. fluorocarbons, Cl- or Br-containing etchants) have been developed to address issue of selective etching in multicolor etching process.

Koyagura et al. (Chemical Etching Treatment of Polydimethylsiloxane for Smoothing Microchannel Surface, Journal of Photopolymer Science and Technology Volume 33, Number 5(2020) 485 490) disclose wet etching process where Si-containing fluorocarbon (C₄H₉F₃Si) appeared in the etching mixture as byproduct. US 2021/0054286 to Lim et al discloses a wet etching method where Si-containing hydrofluorocarbon is used as part of the solvent. US 2005/0263901 to America discloses a method of modifying layer of material during deposition process using addition of Si-containing hydrofluorocarbon to the process gas mixture. U.S. Pat. No. 6,107,166 to Butterbaugh et al. discloses an etching method of alkali and alkaline earth metals based on the use of HF as a main etchant when Si-containing hydrofluorocarbon may be used as addition to the main etchant. US 2021/0193477 to Ishikawa et al. discloses used Si-containing compound as a process gas for deposition of passivation layer during cyclic etching process. WO 2009/019219 to Uenveren et al. discloses etching method of SiO₂ for self-aligned contact using hydrofluorocarbons. Although several Si-containing hydrofluorocarbons (i.e., CH₂F₆Si₂, C₃H₄F₆Si, C₃H₇F₃Si, C₃H₄F₆Si) are listed, these Si-containing hydrofluorocarbons have no methyl group attached to the silicon atom and no any supporting etching examples are disclosed. US 2003/0232504 to Eppler et al, discloses a process of etching openings in a dielectric layer, in which an etchant gas includes a fluorocarbon gas (CₓF_{y}H_{z}, where x>=1, y>=1, and z>=0), and a silane-containing gas, hydrogen or a hydrocarbon gas (CₓH_{y}, where x>=1 and y>=4).

Patterning of the substrate containing several thin films consisting of various materials is a key process for production of semiconductor devices. During patterning of substrate some etching target material could be completely or partially removed from a substrate resulting in the formation of fine pattern which allows to form components of semiconductor device (e.g. transistors and capacitors, interconnects, signal lines and insulation) after several iterations of formation of thin films and patterning. Commonly, various etching processes are used for removal of etching target material or part of etching target material during patterning of a substrate. If partial removal of target material (part of material is targeted for the etching and another part of material presented on the substrate should remain after the etching process) is desired, typically protective film (e.g. hard mask) on top of non-etching film is used. Considering extremely small feature size of patterns in modern semiconductor devices, it may be noted that hard mask should have same order of critical dimensions (e.g. diameter of hole opening, width of trench) of the pattern comparing to pattern formed on the etching target layer. It leads to the necessity to form pattern in a hard mask material with the same feature sizes as in resulting pattern on an etching target material, while keeping high selectivity of the etching process to other materials during patterning of mask to avoid damage and unwanted modifications of etching target film and non-etching films. On the other hand, there are patterning processes requiring long time, such as high aspect ratio etching of 3D NAND channels and DRAM capacitors. Long duration of the process requires use of thicker hard mask and resistant mask material. Use of thick mask results in increase of aspect ratio of pattern on mask and brings additional challenges during patterning process. Typically, thick amorphous carbon, amorphous silicon, or doped amorphous carbon or amorphous silicon are used for high aspect ratio etching processes as a hard mask. Therefore, it is necessary to have etching process capable to remove mask material with reasonable etch rate and high selectivity to other materials presented on the substrate to avoid damage of films other than hard mask for formation of semiconductor devices.

Further development of semiconductor devices requires more complex processes for formation and patterning of thin films in order to keep scaling down components, such as transistors, signal and power lines. Scaling down of feature sizes of components of semiconductor device is necessary to improve performances, efficiency and size of the final device and dramatic decrease of feature size over the past few decades brought extremely strict requirements to fabrication processes. In addition to reduction of feature sizes, portfolio of used materials increased significantly bringing new fabrication challenges. Even though there are few well established processes for selective etching of, for example, SiO₂ selectively to Si₃N₄, using common gas mixtures (such as fluorocarbon or hydrofluorocarbon gases, Cl or Br-containing compounds), there is still a big window for improvement due to the increasing complexity of new semiconductor devices and need in increased number of materials in multicolor etching processes together with possibility to etch each of these materials highly-selective to others.

### SUMMARY

Disclosed is an etching method for forming an aperture in a substrate, the method comprising:
mounting the substrate on a mounting table in a reactor, the substrate including a silicon-containing film deposited thereon and a patterned mask layer deposited on the silicon-containing film;
introducing an etching gas containing a vapor of a Si-containing hydrofluorocarbon into the reactor;
converting the etching gas into a plasma; and
allowing an etching reaction to proceed between the plasma and the silicon-containing film so that the silicon-containing film is etched versus the patterned mask layer, thereby forming the aperture. The disclosed etching method may include one or more of the following aspects:
the etching gas containing a vapor of a fluorocarbon or hydrofluorocarbon selected from one or more of CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇;
the etching gas containing a vapor of a fluorocarbon or hydrofluorocarbon selected from one or more of C₄F₆, C₄F₈, and CH₂F₂;
the etching gas containing an oxidizing gas selected from O₂, O₃, CO, CO₂, SO, SO₂, FNO, NO, N₂O, NO₂, H₂O, COS or combinations thereof;
the etching gas containing an inert gas selected from He, Ar, Xe, Kr or Ne;
the etching gas containing an additional gas selected from H₂, SF₆, NF₃, N₂, NH₃, Cl₂, BCl₃, BF₃, Br₂, F₂, HBr, HCl or combinations thereof;
the Si-containing hydrofluorocarbon having a general formula CₓH_{y}F_{z}Siₙ, where 1≤x≤6, 1≤y≤9, 1≤z≤15, n=1 or 2;
the Si-containing hydrofluorocarbon contains at least one methyl group;
the Si-containing hydrofluorocarbon comprising at least one methyl group attached to the Si atom;
the Si-containing hydrofluorocarbon is a methyl-silyl-hydrofluorocarbon;
the Si-containing hydrofluorocarbon is selected from CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom;
the Si-containing hydrofluorocarbon being selected from CH₃F₃Si, C₂H₆F₂Si, C₄H₉F₃Si, C₅H₉F₅Si or their isomers;
the Si-containing hydrofluorocarbon is CH₃F₃Si or its isomers;
the Si-containing hydrofluorocarbon is C₂H₅F₂Si or its isomers;
the Si-containing hydrofluorocarbon is C₄H₉F₃Si or its isomers;
the Si-containing hydrofluorocarbon is C₅H₉F₅Si or its isomers;
the Si-containing hydrofluorocarbon containing no methyl groups;
the Si-containing hydrofluorocarbon containing methyl groups but no methyl groups attached to the Si element;
the Si-containing hydrofluorocarbon having no methyl groups or no methyl groups attached to the Si element selected from CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃HF₉Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, C₆H₇F₉Si, CH₅FSi₂, CH₃F₃Si₂, CH₂F₆Si₂, C₂H₇F₃Si₂, C₂H₉FSi₂, C₂H₄F₆Si₂, C₂HF₇Si₂, C₂H₂F₆Si₂, C₂H₃F₅Si₂, C₂H₄F₄Si₂, C₃H₄F₈Si₂, C₃H₆F₄Si₂, C₄H₁₀F₄Si₂, C₄H₆F₆Si₂, C₄H₁₁FSi₂, or C₄H₈F₂Si₂;
the silicon-containing film comprising a layer of SiₐO_{b}H_{c}C_{d}Nₑ, where a>0, b, c, d and e≥0, selected from silicon oxide, silicon nitride, crystalline Si, poly-silicon, polycrystalline silicon, amorphous silicon, low-k SiCOH, SiOCN, SiC, SiON, or a layer of alternating silicon oxide and silicon nitride (ONON) layers or alternating silicon oxide and poly-silicon (OPOP) layers;
the silicon-containing film optionally containing dopants such as B, C, P, As Ga, In, Sn, Sb, Bi and/or Ge, and combinations thereof;
the silicon-containing film optionally containing dopants such as B, C, P, As Ga, In, Sn, Sb, Bi and/or Ge, and combinations thereof; and
the aperture formed in the substrate having an aspect ratio between approximately 1:1 and approximately 500:1.

Also disclosed is an etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing C₅H₉F₅Si into the reactor;
converting the etching gas into a plasma; and
allowing an etching reaction to proceed between the plasma and the silicon-containing film so that the silicon-containing film is etched versus the patterned mask layer forming the aperture.

Also disclosed is an etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing C₄H₉F₃Si into the reactor;
converting the etching gas into a plasma; and
allowing an etching reaction to proceed between the plasma and the silicon-containing film so that the silicon-containing film is etched versus the patterned mask layer forming the aperture.

Also disclosed is an etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing C₂H₆F₂Si into the reactor;
converting the etching gas into a plasma; and
allowing an etching reaction to proceed between the plasma and the silicon-containing film so that the silicon-containing film is etched versus the patterned mask layer forming the aperture.

Also disclosed is an etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing CH₃F₃Si into the reactor;
converting the etching gas into a plasma; and
allowing an etching reaction to proceed between the plasma and the silicon-containing film so that the silicon-containing film is etched versus the patterned mask layer forming the aperture.

Also disclosed is an etching gas composition suitable for use in semiconductor etching reactions, the etching gas composition comprising:
a first etchant vapor being a Si-containing hydrofluorocarbon selected from the formula CₓH_{y}F_{z}Siₙ, where 1≤x≤6, 1≤y≤9, 1≤z≤15, n=1 or 2. The disclosed etching method may include one or more of the following aspects:
the Si-containing hydrofluorocarbon comprising at least one methyl group;
the Si-containing hydrofluorocarbon comprising at least one methyl group attached to the Si atom;
the Si-containing hydrofluorocarbon being selected from CH₄F₂Si, CH₃F₃Si, C₂H₆F₂Si, C₃H₉FSi, C₄H₉F₃Si, C₅H₉F₃Si, C₄H₁₀F₄Si₂, C₂H₆F₄Si₂, C₃H₉F₃Si₂, C₆H₉F₇Si or their isomers that has at least one methyl group attached to the Si atom;
the Si-containing hydrofluorocarbon contains at least one methyl group;
the Si-containing hydrofluorocarbon comprising at least one methyl group attached to the Si atom;
the Si-containing hydrofluorocarbon is a methyl-silyl-hydrofluorocarbon;
the Si-containing hydrofluorocarbon is selected from CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom;
the Si-containing hydrofluorocarbon being selected from CH₃F₃Si, C₂H₆F₂Si, C₄H₉F₃Si, C₅H₉F₅Si or their isomers;
the Si-containing hydrofluorocarbon is CH₃F₃Si or its isomers;
the Si-containing hydrofluorocarbon is C₂H₆F₂Si or its isomers;
the Si-containing hydrofluorocarbon is C₄H₉F₃Si or its isomers;
the Si-containing hydrofluorocarbon is C₅H₉F₅Si or its isomers;
the Si-containing hydrofluorocarbon containing no methyl groups;
the Si-containing hydrofluorocarbon containing methyl groups but no methyl groups attached to the Si element;
the Si-containing hydrofluorocarbon having no methyl groups or no methyl groups attached to the Si element selected from CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃HF₉Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, C₆H₇F₉Si, CH₅FSi₂, CH₃F₃Si₂, CH₂F₆Si₂, C₂H₇F₃Si₂, C₂H₉FSi₂, C₂H₄F₆Si₂, C₂HF₇Si₂, C₂H₂F₆Si₂, C₂H₃F₅Si₂, C₂H₄F₄Si₂, C₃H₄F₈Si₂, C₃H₆F₄Si₂, C₄H₁₀F₄Si₂, C₄H₆F₆Si₂, C₄H₁₁Si₂, or C₄H₈F₂Si₂;
further comprising a second etchant vapor selected from a hydrofluorocarbon or fluorocarbon;
the hydrofluorocarbon or fluorocarbon being selected from CF₄, C₂F₆, C₃F₆, C₄F₆, C₄F₈, C₅F₈, C₅F₁₀, C₆F₁₂, C₇F₁₄, C₈F₁₆, CH₂F₂, C₂H₅F, CHF₃, C₂H₅F, C₃H₇F, C₅HF₇, C₃H₂F₆, C₃H₄F₂, C₃H₂F₄, C₄H₂F₆ or C₄H₃F₇;
further comprising an oxidizing gas selected from O₂, O₃, CO, CO₂, SO, SO₂, FNO, NO, N₂O, NO₂, H₂O or COS;
further comprising an inert gas selected from He, Ar, Xe, Kr or Ne;
further comprising an additional gas selected from H₂, SF₆, NF₃, N₂, NH₃, Cl₂, BCl₃, BF₃, Br₂, F₂, HBr, HCl or combinations thereof;
a purity of the first etching gas being greater than 95% v/v;
a purity of the first etching gas being greater than 99.99% v/v;
the boiling point of the first etching gas being between approximately −50 to 250° C.; and
use of the etching gas composition in a semiconductor etching process.

Also disclosed is a selective etching method for forming a structure in a substrate, the selective method comprising:
mounting the substrate on a mounting table in a reactor, the substrate having a pattern containing an etching film and at least one non-etching films deposited thereon;
introducing a vapor of a Si-containing hydrofluorocarbon into the reactor;
igniting a plasma to produce an activated Si-containing hydrofluorocarbon; and
allowing an etching reaction to proceed between the activated Si-containing hydrofluorocarbon and the silicon-containing film so that the silicon-containing film is selectively etched versus the at least one non-etching films forming the structure. The disclosed etching method may include one or more of the following aspects:
further comprising introducing a fluorocarbon or hydrofluorocarbon selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇ into the reactor;
further comprising introducing an oxidizing gas selected from O₂, O₃, CO, CO₂, SO, SO₂, FNO, NO, N₂O, NO₂, H₂O or COS into the reactor;
further comprising introducing an inert gas selected from He, Ar, Xe, Kr or Ne into the reactor;
further comprising introducing an additional gas into the reaction chamber, wherein the additional gas is selected from H₂, SF₆, NF₃, N₂, NH₃, Cl₂, BCl₃, BF₃, Br₂, F₂, HBr, HCl or combinations thereof;
the Si-containing hydrofluorocarbon having a general formula CₓH_{y}F_{z}Siₙ, 1≤x≤6, 1≤y≤9, 1≤z≤15, n=1 or 2;
the Si-containing hydrofluorocarbon containing at least one methyl group;
the Si-containing hydrofluorocarbon comprising at least one methyl group attached to the Si atom;
the Si-containing hydrofluorocarbon is a methyl-silyl-hydrofluorocarbon;
the Si-containing hydrofluorocarbon is selected from CHF₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom;
the Si-containing hydrofluorocarbon being selected from CHF₃Si, C₂H₆F₂Si, C₄H₉F₃Si, C₅H₉F₅Si or their isomers;
the Si-containing hydrofluorocarbon is CH₃F₃Si or its isomers;
the Si-containing hydrofluorocarbon is C₂H₆F₂Si or its isomers;
the Si-containing hydrofluorocarbon is C₄H₉F₃Si or its isomers;
the Si-containing hydrofluorocarbon is C₅H₉F₅Si or its isomers;
the Si-containing hydrofluorocarbon containing no methyl groups;
the Si-containing hydrofluorocarbon containing methyl groups but no methyl groups attached to the Si element;
the Si-containing hydrofluorocarbon having no methyl groups or no methyl groups attached to the Si element selected from CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃HF₉Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, C₆H₇F₉Si, CH₅Si₂, CH₃F₃Si₂, CH₂F₆Si₂, C₂H₇F₃Si₂, C₂H₉FSi₂, C₂H₄F₆Si₂, C₂HF₇Si₂, C₂H₂F₆Si₂, C₂H₃F₅Si₂, C₂H₄F₄Si₂, C₃H₄F₈Si₂, C₃H₆F₄Si₂, C₄H₁₀F₄Si₂, C₄H₈F₆Si₂, C₄H₁₁FSi₂, or C₄H₈F₂Si₂;
the pattern being a 2D pattern or a 3D pattern on the substrate;
a selectivity of the Si-containing film to the at least one non-etching film being larger than 5;
a selectivity of the Si-containing film to the at least one non-etching film being larger than 10;
a selectivity of the Si-containing film to the at least one non-etching film etching being infinite;
silicon-containing film comprising a layer of SiₐO_{b}H_{c}C_{d}Nₑ, where a>0, b, c, d and e≥0, selected from silicon oxide, silicon nitride, crystalline Si, poly-silicon, polycrystalline silicon, amorphous silicon, low-k SiCOH, SiOCN, SiC, SiON, or a layer of alternating silicon oxide and silicon nitride (ONON) layers or alternating silicon oxide and poly-silicon (OPOP) layers; and.
the non-etching films being selected from Si-containing films different from the Si-containing film to be etched, organic film, or metal-containing film.

Also disclosed is a selective etching method for forming a structure in a substrate, the selective method comprising
mounting the substrate on a mounting table in a reactor, the substrate having a pattern containing an etching film and at least one non-etching films deposited thereon;
introducing a vapor of C₄H₉F₃Si into the reactor;
igniting a plasma to produce an activated C₄H₉F₃Si; and
allowing an etching reaction to proceed between the activated C₄H₉F₃Si and the silicon-containing film so that the silicon-containing film is selectively etched versus the at least one non-etching films forming the structure. The disclosed etching method may include one or more of the following aspects:

Also disclosed is a selective etching method for forming a structure in a substrate, the selective method comprising mounting the substrate on a mounting table in a reactor, the substrate having a pattern containing an etching film and at least one non-etching films deposited thereon;
introducing a vapor of C₅H₉F₅Si into the reactor;
igniting a plasma to produce an activated C₅H₉F₅Si; and
allowing an etching reaction to proceed between the activated C₅H₉F₅Si and the silicon-containing film so that the silicon-containing film is selectively etched versus the at least one non-etching films forming the structure.

Also disclosed is a selective etching method for forming a structure in a substrate, the selective method comprising
mounting the substrate on a mounting table in a reactor, the substrate having a pattern containing an etching film and at least one non-etching films deposited thereon;
introducing a vapor of CH₃F₃Si into the reactor;
igniting a plasma to produce an activated CH₃F₃Si; and allowing an etching reaction to proceed between the activated CH₃F₃Si and the silicon-containing film so that the silicon-containing film is selectively etched versus the at least one non-etching films forming the structure.

Also disclosed is a selective etching method for forming a structure in a substrate, the selective method comprising
mounting the substrate on a mounting table in a reactor, the substrate having a pattern containing an etching film and at least one non-etching films deposited thereon;
introducing a vapor of C₂H₆F₂Si into the reactor;
igniting a plasma to produce an activated C₂H₆F₂Si; and
allowing an etching reaction to proceed between the activated C₂H₆F₂Si and the silicon-containing film so that the silicon-containing film is selectively etched versus the at least one non-etching films forming the structure.

Also disclosed is a selective etching method for forming a structure in a substrate, the selective etching method comprising:
mounting the substrate on a mounting table in a reactor, the substrate having a pattern containing an etching film and at least one non-etching films deposited thereon;
introducing an etching gas containing a vapor of a Si-containing hydrofluorocarbon and an oxidizing gas into the reactor;
igniting a plasma to produce an activated etching gas; and
allowing an etching reaction to proceed between the activated etching gas and the etching film so that the etching film is selectively etched versus the at least non-etching film forming the structure. The disclosed etching method may include one or more of the following aspects:
the oxidizing gas being selected from O₂, O₃, CO, CO₂, SO, SO₂, FNO, NO, N₂O, NO₂, H₂O or COS;
the etching gas including an inert gas selected from He, Ar, Xe, Kr or Ne;
the Si-containing hydrofluorocarbon having a general formula CₓH_{y}F_{z}Siₙ, 1≤x≤6, 1≤y≤9, 1≤z≤15, n=1 or 2;
the Si-containing hydrofluorocarbon containing at least one methyl group;
the Si-containing hydrofluorocarbon comprising at least one methyl group attached to the Si atom;
the Si-containing hydrofluorocarbon is a methyl-silyl-hydrofluorocarbon;
the Si-containing hydrofluorocarbon is selected from CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom;
the Si-containing hydrofluorocarbon being selected from CH₃F₃Si, C₂H₆F₂Si, C₄H₉F₃Si, C₅H₉F₅Si or their isomers;
the Si-containing hydrofluorocarbon is CH₃F₃Si or its isomers;
the Si-containing hydrofluorocarbon is C₂H₆F₂Si or its isomers;
the Si-containing hydrofluorocarbon is C₄H₉F₃Si or its isomers;
the Si-containing hydrofluorocarbon is C₅H₉F₅Si or its isomers;
the Si-containing hydrofluorocarbon containing no methyl groups;
the Si-containing hydrofluorocarbon containing methyl groups but no methyl groups attached to the Si element;
the Si-containing hydrofluorocarbon having no methyl groups or no methyl groups attached to the Si element selected from CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃HF₉Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, C₆H₇F₉Si, CH₅FSi₂, CH₃F₃Si₂, CH₂F₆Si₂, C₂H₇F₃Si₂, C₂H₉FSi₂, C₂H₄F₆Si₂, C₂HF₇Si₂, C₂H₂F₆Si₂, C₂H₃F₅Si₂, C₂H₄F₄Si₂, C₃H₄F₈Si₂, C₃H₆F₄Si₂, C₄H₁₀F₄Si₂, C₄H₆F₆Si₂, C₄H₁₁FSi₂, or C₄H₈F₂Si₂;
the etching film is an organic film;
the organic film being an a-C film, a doped a-C film, an a-Si or a doped a-Si film;
the etching film being a metal-containing film;
the non-etching film being organic film(s) different from the etching film, metal-containing film(s) different from the etching film, or silicon-containing film(s);
a selectivity of the Si-containing film to the at least one non-etching film being larger than 5;
a selectivity of the Si-containing film to the at least one non-etching film being larger than 10; and
a selectivity of the Si-containing film to the at least one non-etching film etching being infinite.

Also disclosed is a selective etching method for forming a structure in a substrate, the selective etching method comprising:
mounting the substrate on a mounting table in a reactor, the substrate having a pattern containing an etching film and at least one non-etching films deposited thereon;
introducing an etching gas containing a vapor of a CH₃F₃Si and an oxidizing gas into the reactor;
igniting a plasma to produce an activated etching gas, and
allowing an etching reaction to proceed between the activated etching gas and the etching film so that the etching film is selectively etched versus the at least non-etching film forming the structure.

Also disclosed is a selective etching method for forming a structure in a substrate, the selective etching method comprising:
mounting the substrate on a mounting table in a reactor, the substrate having a pattern containing an etching film and at least one non-etching films deposited thereon;
introducing an etching gas containing a vapor of a C₂H₆F₂Si and an oxidizing gas into the reactor;
igniting a plasma to produce an activated etching gas; and
allowing an etching reaction to proceed between the activated etching gas and the etching film so that the etching film is selectively etched versus the at least non-etching film forming the structure.

Also disclosed is a selective etching method for forming a structure in a substrate, the selective etching method comprising:
mounting the substrate on a mounting table in a reactor, the substrate having a pattern containing an etching film and at least one non-etching films deposited thereon;
introducing an etching gas containing a vapor of a C₄H₉F₃Si and an oxidizing gas into the reactor;
igniting a plasma to produce an activated etching gas; and
allowing an etching reaction to proceed between the activated etching gas and the etching film so that the etching film is selectively etched versus the at least non-etching film forming the structure.

Also disclosed is a selective etching method for forming a structure in a substrate, the selective etching method comprising:
mounting the substrate on a mounting table in a reactor, the substrate having a pattern containing an etching film and at least one non-etching films deposited thereon;
introducing an etching gas containing a vapor of a C₅H₉F₅Si and an oxidizing gas into the reactor;
igniting a plasma to produce an activated etching gas, and
allowing an etching reaction to proceed between the activated etching gas and the etching film so that the etching film is selectively etched versus the at least non-etching film forming the structure.

Also disclosed is a cyclic selective etching method for removing a film, the method comprising: )
i) introducing a first etching gas containing a vapor of a Si-containing hydrofluorocarbon compound into a reactor that contains a substrate, the substrate having a pattern containing the etching film and at least one non-etching films deposited thereon;
ii) initiating a plasma to form an activated first etching gas;
iii) allowing an etching reaction to proceed between the activated first etching gas and the etching film so that the etching film is selectively etched versus the at least one non-etching films and simultaneously a polymer layer is deposited on the at least one non-etching films;
iv) introducing a second etching gas into the reactor;
v) initiating a plasma to form an activated second etching gas;
vi) allowing an etching reaction to proceed between the activated second etching gas and the etching film and the polymer layer to etch the etching film and the polymer layer; and
vii) repeating i) to vi) until the etching film is removed. The disclosed etching method may include one or more of the following aspects:
further comprising purging the reactor with an inert gas selected from N₂, He, Ar, Xe, Kr or Ne after step iii) and vi), respectively, with the plasma deactivated;
the Si-containing hydrofluorocarbon having a general formula CₓH_{y}F_{z}Siₙ, 1≤x≤6, 1≤y≤9, 1≤z≤15, n=1 or 2;
the Si-containing hydrofluorocarbon containing at least one methyl group;
the Si-containing hydrofluorocarbon comprising at least one methyl group attached to the Si atom;
the Si-containing hydrofluorocarbon is a methyl-silyl-hydrofluorocarbon;
the Si-containing hydrofluorocarbon is selected from CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom;
the Si-containing hydrofluorocarbon being selected from CH₃F₃Si, C₂H₆F₂Si, C₄H₉F₃Si, C₅H₉F₅Si or their isomers;
the Si-containing hydrofluorocarbon is CH₃F₃Si or its isomers;
the Si-containing hydrofluorocarbon is C₂H₃F₂Si or its isomers;
the Si-containing hydrofluorocarbon is C₄H₉F₃Si or its isomers;
the Si-containing hydrofluorocarbon is C₅H₉F₅Si or its isomers;
the Si-containing hydrofluorocarbon containing no methyl groups;
the Si-containing hydrofluorocarbon containing methyl groups but no methyl groups attached to the Si element;
the Si-containing hydrofluorocarbon having no methyl groups or no methyl groups attached to the Si element selected from CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃HF₉Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, C₆H₇F₉Si, CH₅FSi₂, CH₃F₃Si₂, CH₂F₆Si₂; C₂H₇F₃Si₂, C₂H₉FSi₂, C₂H₄F₆Si₂, C₂HF₇Si₂, C₂H₂F₆Si₂, C₂H₃F₅Si₂, C₂H₄F₄Si₂, C₃H₄F₈Si₂, C₃H₆F₄Si₂, C₄H₁₀F₄Si₂, C₄H₆F₆Si₂, C₄H₁₁FSi₂, or C₄H₈F₂Si₂;
the first etching gas including a vapor of a hydrofluorocarbon or fluorocarbon compound;
the fluorocarbon or hydrofluorocarbon being selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₂H₂F₆, C₃H₄F₂, C₃H₂F₄, C₄H₂F₆ or C₄H₃F₇;
the first etching gas including an oxidizing gas selected from O₂, O₃, CO, CO₂, SO, SO₂, FNO, NO, N₂O, NO₂, or H₂O, COS;
the first etching gas including an inert gas selected from the group consisting of He, Ar, Xe, Kr or Ne;
the first etching gas including an additional gas selected from H₂, SF₆, NF₃, N₂, NH₃, Cl₂, BCl₃, BF₃, Br₂, F₂, HBr, HCl or combinations thereof;
the second etching gas including a vapor of a hydrofluorocarbon or fluorocarbon or combination thereof;
the fluorocarbon or hydrofluorocarbon being selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇;
the second etching gas including an oxidizing gas selected from O₂, O₃, CO, CO₂, SO, SO₂, FNO, NO, NO, NO₂, or H₂O, COS;
the second etching gas including an inert gas selected from the group consisting of He, Ar, Xe, Kr or Ne;
the second etching gas including an additional gas selected from H₂, SF₆, NF₃, N₂, NH₃, Cl₂, BCl₃, BF₃, Br₂, F₂, HBr, HCl or combinations thereof;
further comprising:
   introducing a third etching gas into the reactor between step vi) and step vii);
   igniting a plasma to produce an activated third etching gas; and
   allowing an etching reaction to proceed between the activated third etching gas and the etching film and the polymer layer to etch the etching film and the polymer layer;
the third etching gas being the same as the second etching gas, but both do not have the same combinations of gas compositions in one or each cycle;
the etching film comprising a layer of SiₐO_{b}H_{c}C_{d}Nₑ, where a>0, b, c, d and e≥0, selected from silicon oxide, silicon nitride, crystalline Si, poly-silicon, polycrystalline silicon, amorphous silicon, low-k SiCOH, SiOCN, SiC, SiON, or a layer of alternating silicon oxide and silicon nitride (ONON) layers or alternating silicon oxide and poly-silicon (OPOP) layers; and
the etching film comprising a Si-containing film, an organic film or a metal-containing film.

Also disclosed is a cyclic selective etching method for removing a film, the method comprising: )
i) introducing a first etching gas containing a vapor of C₄H₉F₃Si into a reactor that contains a substrate, the substrate having a pattern containing the etching film and at least one non-etching films deposited thereon;
ii) initiating a plasma to form an activated first etching gas;
iii) allowing an etching reaction to proceed between the activated first etching gas and the etching film so that the etching film is selectively etched versus the at least one non-etching films and simultaneously a polymer layer is deposited on the at least one non-etching films;
iv) introducing a second etching gas into the reactor;
v) initiating a plasma to form an activated second etching gas;
vi) allowing an etching reaction to proceed between the activated second etching gas and the etching film and the polymer layer to etch the etching film and the polymer layer; and
vii) repeating i) to vi) until the etching film is removed.

Also disclosed is a cyclic selective etching method for removing a film, the method comprising:
i) introducing a first etching gas containing a vapor of C₅H₉F₅Si into a reactor that contains a substrate, the substrate having a pattern containing the etching film and at least one non-etching films deposited thereon;
ii) initiating a plasma to form an activated first etching gas;
iii) allowing an etching reaction to proceed between the activated first etching gas and the etching film so that the etching film is selectively etched versus the at least one non-etching films and simultaneously a polymer layer is deposited on the at least one non-etching films;
iv) introducing a second etching gas into the reactor;
v) initiating a plasma to form an activated second etching gas;
vi) allowing an etching reaction to proceed between the activated second etching gas and the etching film and the polymer layer to etch the etching film and the polymer layer; and
vii) repeating i) to vi) until the etching film is removed.

Also disclosed is a cyclic selective etching method for removing a film, the method comprising:
i) introducing a first etching gas containing a vapor of CH₃F₃Si into a reactor that contains a substrate, the substrate having a pattern containing the etching film and at least one non-etching films deposited thereon;
ii) initiating a plasma to form an activated first etching gas;
iii) allowing an etching reaction to proceed between the activated first etching gas and the etching film so that the etching film is selectively etched versus the at least one non-etching films and simultaneously a polymer layer is deposited on the at least one non-etching films;
iv) introducing a second etching gas into the reactor;
v) initiating a plasma to form an activated second etching gas;
vi) allowing an etching reaction to proceed between the activated second etching gas and the etching film and the polymer layer to etch the etching film and the polymer layer; and
vii) repeating i) to vi) until the etching film is removed.

Also disclosed is a cyclic selective etching method for removing a film, the method comprising:
i) introducing a first etching gas containing a vapor of C₂H₆F₂Si into a reactor that contains a substrate, the substrate having a pattern containing the etching film and at least one non-etching films deposited thereon;
ii) initiating a plasma to form an activated first etching gas;
iii) allowing an etching reaction to proceed between the activated first etching gas and the etching film so that the etching film is selectively etched versus the at least one non-etching films and simultaneously a polymer layer is deposited on the at least one non-etching films;
iv) introducing a second etching gas into the reactor;
v) initiating a plasma to form an activated second etching gas;
vi) allowing an etching reaction to proceed between the activated second etching gas and the etching film and the polymer layer to etch the etching film and the polymer layer; and
vii) repeating i) to vi) until the etching film is removed.

Also disclosed is apparatus for delivering an etching gas composition to a semiconductor etching process, the apparatus comprising:
a) a source of the first etchant;
b) a source of the second etchant;
c) at least two fluidic conduits connecting the sources a) and b) to a common fluidic conduit;
d) optionally a mixing element adapted to mix the first etching gas and the second etching gas, the mixing element fluidically connected to the common fluidic conduit;
e) optionally a thermal element adapted to regulate the temperature of the first etching gas, the temperature of the second etching gas and the temperature of a mixture thereof;
f) optionally a vaporizer element, fluidically connected to one or more of the at least two fluidic conduits and/or the common fluidic conduit, adapted to produce a vapor of the first etching gas, the second etching gas and a mixture thereof; and
g) optionally a PLC controller adapted to control valves connected to the elements and the sources. The disclosed etching method may include one or more of the following aspects:
the apparatus being adapted to regulate the flow of the first etchant and the second etchant to form the etching gas composition having a predefined ratio of the first etchant and the second etchant based on a chemical formula of the first etchant and the second etchant;
a container comprising the first etchant, the container adapted to connect to a device used for semiconductor etching process(es);
the apparatus comprising the container, operatively connected to the device used for semiconductor etching process(es);
the first etchant being a Si-containing hydrofluorocarbon;
the Si-containing hydrofluorocarbon having a general formula CₓH_{y}F_{z}Siₙ, 1≤x≤6, 1≤y≤9, 1≤z≤15, n=1 or 2;
the Si-containing hydrofluorocarbon containing at least one methyl group;
the Si-containing hydrofluorocarbon comprising at least one methyl group attached to the Si atom;
the Si-containing hydrofluorocarbon is a methyl-silyl-hydrofluorocarbon;
the Si-containing hydrofluorocarbon is selected from CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom;
the Si-containing hydrofluorocarbon being selected from CH₃F₃Si, C₂H₆F₂Si, C₄H₉F₃Si, C₅H₉F₅Si or their isomers;
the Si-containing hydrofluorocarbon is CH₃F₃Si or its isomers;
the Si-containing hydrofluorocarbon is C₂H₆F₂Si or its isomers;
the Si-containing hydrofluorocarbon is C₄H₉F₃Si or its isomers;
the Si-containing hydrofluorocarbon is C₅H₉F₅Si or its isomers;
the Si-containing hydrofluorocarbon containing no methyl groups;
the Si-containing hydrofluorocarbon containing methyl groups but no methyl groups attached to the Si element;
the Si-containing hydrofluorocarbon having no methyl groups or no methyl groups attached to the Si element selected from CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃HF₉Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, C₆H₇F₉Si, CH₅FSi₂, CH₃F₃Si₂, CH₂F₆Si₂, C₂H₇F₃Si₂, C₂H₉FSi₂, C₂H₄F₆Si₂, C₂HF₇Si₂, C₂H₂F₆Si₂, C₂H₃F₅Si₂, C₂H₄F₄Si₂, C₃H₄F₈Si₂, C₃H₆F₄Si₂, C₄H₁₀F₄Si₂, C₄H₆F₆Si₂, C₄H₁₁FSi₂, or C₄H₈F₂Si₂;
the second etchant being including a vapor of a hydrofluorocarbon or fluorocarbon or combination thereof;
the fluorocarbon or hydrofluorocarbon being selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇;
the second etching gas including an oxidizing gas selected from O₂, O₃, CO, CO₂, SO, SO₂, FNO, NO, N₂O, NO₂, or H₂O, COS;
the second etching gas including an inert gas selected from the group consisting of He, Ar, Xe, Kr or Ne; and
the second etching gas including an additional gas selected from H₂, SF₆, NF₃, N₂, NH₃, Cl₂, BCl₃, BF₃, Br₂, F₂, HBr, HCl or combinations thereof.

### NOTATION AND NOMENCLATURE

The following detailed description and claims utilize a number of abbreviations, symbols, and terms, which are generally well known in the art.

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 25° C.

The term “wafer” or “patterned wafer” refers to a wafer having a stack of any existing films including silicon-containing films on a substrate and a patterned hardmask layer on the stack of any existing films including silicon-containing films formed for pattern etch.

The term “substrate” refers to a material or materials on which a process is conducted. The substrate may refer to a wafer or a patterned wafer having a material or materials on which an etching process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon-containing layers (e.g., SiO₂, SiN, SiON, SiCOH, etc.), metal containing layers (e.g., copper, cobalt, ruthenium, tungsten, indium, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.), nitride-based films (for example, TaN, TiN, NbN) that are used as electrodes, or metal-containing or metal-alloy-based films (for example, InGaAs, InₓO_{y} (x=0.5 to 1.5, y=0.5 to 1.5), InSnO (ITO), InGaZnO (IGZO), InN, InP, InAs, InSb, In₂S₃, or In(OH)₃, etc.) that are the stronger contenders for the future replacement of silicon in CMOS systems. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

Please note that the films or layers to be etched, such as silicon oxide or silicon nitride, may be listed throughout the specification and claims without reference to their proper stoichiometry (i.e., SiO₂, SiO₃, Si₃N₄). The layers may include pure (Si) layers, such as crystalline Si, poly-silicon (p-Si or polycrystalline Si), or amorphous silicon; silicon carbide (SiₒCₚ) layers, silicon nitride (SiₖNₗ) layers; silicon oxide (SiₙOₘ) layers; or mixtures thereof, wherein k, l, m, n, o, and p inclusively range from 0.1 to 6. For instance, silicon nitride is SiₖNₗ, where k and l each range from 0.5 to 1.5. More preferably silicon nitride is Si₃N₄. Herein, SiN in the following description may be used to represent SiₖNₗ containing layers. For instance, silicon oxide is SiₙOₘ, wherein n ranges from 0.5 to 1.5 and m ranges from 1.5 to 3.5. Preferably, the silicon oxide layer is SiO₂. Herein, SiN and SiO in the following description are used to represent SiₖNₗ and SiₙOₘ containing layers, respectively. The silicon-containing film could also be a silicon oxide based dielectric material such as organic based or silicon oxide based low-k dielectric materials such as the Black Diamond II or III material by Applied Materials, Inc. with a formula of SiOCH. Alternatively, any referenced silicon-containing layer may be pure silicon. Silicon-containing film may also include SiₐO_{b}C_{c}N_{d}Hₑ where a, b, c, d, e range from 0.1 to 6 and b, c, d, e≥0 independently. The silicon-containing films may also include dopants, such as B, C, P, As Ga, In, Sn, Sb, Bi and/or Ge.

The term “pattern etch” or “patterned etch” refers to etching a non-planar structure, such as a stack of silicon-containing films below a patterned hardmask layer.

As used herein, the term “etch” or “etching” means to use an etching compound and/or a plasma to remove material via ion bombardment, remote plasma, or chemical vapor reaction between the etching gas and substrate and refers to an isotropic etching process and/or an anisotropic etching process. The isotropic etch process involves a chemical reaction between the etching compound and the substrate resulting in part of material on the substrate being removed. This type of etching process includes chemical dry etching, vapor phase chemical etching, thermal dry etching, or the like. The isotropic etch process produces a lateral or horizontal etch profile in a substrate. The isotropic etch process produces recesses or horizontal recesses on a sidewall of a pre-formed aperture in a substrate. The anisotropic etch process involves a plasma etching process (i.e., a dry etch process) in which ion bombardment accelerates the chemical reaction in the vertical direction so that vertical sidewalls are formed along the edges of the masked features at right angles to the substrate (Manos and Flamm, Thermal etching an Introduction, Academic Press, Inc. 1989 pp. 12-13). The plasma etching process produces a vertical etch profile in a substrate. The plasma etching process produces vertical vias, apertures, trenches, channel holes, gate trenches, staircase contacts, capacitor holes, contact holes, slit etch, self-aligned contact, self-aligned vias, super vias etc., in the substrate.

The term “mask” refers to a layer that resists etching. The mask layer may be located above the layer to be etched. The mask layer also refers to a hardmask layer. The mask layer may be an amorphous carbon (a-C) layer, a doped a-C layer, a photoresist layer, an anti-reflective layer, an amorphous silicon (a-Si) layer, an organic planarization layer, and combinations thereof. The mask layer may also be a silicon layer, such as poly-Si, metal oxide such as Ti, Al, Zr, Hf, etc., oxide, and combinations thereof.

The term “aspect ratio” refers to a ratio of the height of a trench (or aperture) to the width of the trench (or the diameter of the aperture).

The term “high aspect ratio” or “HAR” used herein refers to an aspect ratio is exceeding value of 5.

The term “high aspect ratio etching” or “HAR etching” used herein refers to the formation of a vertical hole or aperture pattern in an etching target film by the disclosed plasma etching method when aspect ratio of formed vertical apertures is exceeding value of 5.

The term “etch stop” refers to a layer below the layer to be etched that protects layers underneath.

The term “device channel” refers to layers that are part of actual device and any damage to it will affect device performance.

The term “selectivity” means the ratio of the etch rate of one material to the etch rate of another material. The term “selective etch” or “selectively etch” means to etch one material more than another material, or in other words to have a greater or less than 1:1 etch selectivity between two materials.

The terms “via”, “aperture”, “trench”, and “hole” are sometimes used interchangeably, and generally mean an opening in an interlayer insulator.

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include t-butyl, but are not limited to. Examples of cyclic alkyl groups include without limitation, cyclopropyl groups, cyclopentyl groups, cyclohexyl groups, etc.

The term “organic film” used herein refers to a film formed with organic precursors, including a layer of amorphous carbon (a-C) and a layer of amorphous silicon (a-Si).

The term “Si-containing hydrofluorocarbon compounds” used herein refers to compounds have a general formula:

CₓH_{y}F_{z}Siₙ (1)

wherein 1≤x≤6, 1≤y≤9, 1≤z≤15, n=1 or 2, wherein the compound contains at least one methyl group. In some embodiments, the at least one methyl group is attached to Si atom in the Si-containing hydrofluorocarbon compounds. In some embodiments, the at least one methyl group is not attached to Si atom in the Si-containing hydrofluorocarbon compounds.

As used herein, the term “plasma etching” refers to the etching method when use of plasma involved for removal of etching target films not protected by a mask by means of ion bombardment or interaction with reactive species formed in the plasma or plasma afterglow which results in the formation of volatile byproducts that may be effectively removed from the substrate.

Note that herein, the terms “film”, “layer” and “material” may be used interchangeably. It is understood that a film may correspond to, or related to a layer or a material, and that the layer or material may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “etching compound”, “etchant”, “etching gas”, “etch gas”, and “process gas” may be used interchangeably when the etching compound is in a gaseous state under room temperature and ambient pressure. It is understood that an etching compound may correspond to, or related to an etching gas or an etchant or a process gas, and that the etching gas or the etchant or the process gas may refer to the etching compound.

Note that herein, the terms “etching film”, “etching material”, “etching target film”, “target film”, “processing film” and “processing material” may be used interchangeably. It is understood that an etching film may correspond to, or related to an etching material or an etching target film or a processing film or a processing material, and that the etching target film or the processing film or the processing material may refer to the etching film.

The terms “via”, “aperture”, “slit”, “hole” and “structure” are used interchangeably, and generally mean an opening or recess in an interlayer insulator or an opening or recess in a substrate or wafer.

As used herein, the abbreviation “NAND” refers to a “Negated AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

The standard abbreviations of the elements from the periodic table of elements are used herein. It should be understood that elements may be referred to by these abbreviations (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to help better identify the molecules disclosed.

The term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where M is an atom, x is 2 or 3, the two or three R¹ groups may, but need not be identical to each other or to R² or to R³. Further, it should be understood that unless specifically stated otherwise, values of R groups are independent of each other when used in different formulas.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is signal of C₄H₉F₃Si and C₅H₉F₅Si recorded using a quadrupole mass spectrometer in residual gas analysis mode with an electron energy of 20 eV during the scan;

FIG. 2a is an exemplary substrate having the films and non-etching films with pattern before etching;

FIG. 2b is an exemplary substrate having the films and non-etching films with pattern after etching;

FIG. 3a is an exemplary substrate having the films and multiple non-etching films with pattern before etching:

FIG. 3b is an exemplary substrate having the films and multiple non-etching films with pattern after etching;

FIG. 4a is an exemplary substrate having the etching organic film with pattern before etching;

FIG. 4b is an exemplary substrate having the etching organic film with pattern after etching; FIG. 5a is a cross-sectional side view of exemplary a stack of multiple layers with multiple materials;

FIG. 5b is a cross-sectional side view of the exemplary stack of multiple layers with multiple materials of FIG. 5a showing one of the multiple materials is selectively etched;

FIG. 5c is a cross-sectional side view of the exemplary stack of multiple layers with multiple materials of FIG. 5a showing in a consecutive etching step;

FIG. 5d is a cross-sectional side view of the exemplary stack of multiple layers with multiple materials of FIG. 5a showing a repeated etching process;

FIG. 6(a) is a SEM image of the cross-section of a substrate after plasma etching (a) using the process conditions from Example 1;

FIG. 6(b) is a SEM image of the cross-section of a substrate after plasma etching (a) using the process conditions from the Comparative Example 1;

FIG. 6(c) is a SEM image of the cross-section of a substrate after plasma etching (a) using the process conditions from Example 2;

FIG. 6(d) is a SEM image of the cross-section of a substrate after plasma etching (a) using the process conditions from the Comparative Example 2;

FIG. 7(a) is a SEM image of the cross-section of a substrate after plasma etching (a) using process conditions from Example 3;

FIG. 7(b) is a SEM image of the cross-section of a substrate after plasma etching (a) using process conditions from the Comparative Example 3;

FIG. 7(c) is a SEM image of the cross-section of a substrate after plasma etching (a) using process conditions from the Comparative Example 4:

FIG. 8(a) is a SEM image of the cross-section of a substrate after plasma etching (a) using the process conditions from Example 4;

FIG. 8(b) is SEM image of the cross-section of a substrate after plasma etching (a) using the process conditions from Comparative Example 5;

FIG. 8(c) is a SEM image of the cross-section of a substrate after plasma etching (a) using the process conditions from Comparative Example 6;

FIG. 9 is SEM image of the cross-section of a substrate after plasma etching (a) using the process conditions from Example 8;

FIG. 10 is SEM image of the cross-section of a substrate after plasma etching (a) using the process conditions from Example 9;

FIG. 11 is SEM image of the cross-section of a substrate after plasma etching (a) using the process conditions from Example 10;

FIG. 12 is SEM image of the cross-section of a substrate after plasma etching (a) using the process conditions from Example 11;

FIG. 13 is estimated etch rates as a function of O₂ flow rate for substrates including one of the following plasma etching materials: SiO₂, Si₃N₄, a-C, poly-Si and W (Example 12);

FIG. 14 is estimated etch rates as a function of C₆H₉F₅Si flow rate for substrates including one of the following plasma etching materials: SiO₂, Si₃N₄, a-C, poly-Si and W (Example 13);

FIG. 15 is estimated etch rates as a function of C₄H₉F₃Si flow rate for substrates including one of the following plasma etching materials: SiO₂, Si₃N₄, a-C, poly-Si and W (Example 14);

FIG. 16 is estimated etch rates as a function of CH₂F₂ flow rate for substrates including one of the following plasma etching materials: SiO₂, Si₃N₄, a-C, poly-Si, W, SiC, SiCN, SiON (Example 15);

FIG. 17 is estimated etch rates as a function of C₄H₉F₃Si flow rate for substrates including one of the following plasma etching materials: SiO₂, Si₃N₄, a-C, poly-Si, W, SiC, SiCN, SiON (Example 16);

FIG. 18 is estimated etch rates as a function of C₂H₆F₂Si flow rate for substrates including one of the following plasma etching materials: SiO₂, Si₃N₄, a-C, poly-Si and W (Example 17);

FIG. 19 is estimated etch rates as a function of CH₃F₃Si flow rate for substrates including one of the following plasma etching materials: SiO₂, Si₃N₄, a-C, poly-Si and W (Example 18);

FIG. 20 is estimated etch rates of O₂ flow rate for substrates including one of the following plasma etching materials: SiO₂, Si₃N₄, a-C, poly-Si and W (Example 19);

FIG. 21 is estimated etch rates as a function of O₂ flow rate for substrates including one of the following plasma etching materials: SiO₂, Si₃N₄, a-C, W doped a-C, poly-Si and W (Example 20);

FIG. 22 is estimated etch rates as a function of O₂ flow rate for substrates including one of the following plasma etching materials: SiO₂, Si₃N₄, a-C, W doped a-C, poly-Si and W (Comparative example 7);

FIG. 23 is estimated etch rates as a function of O₂ flow rate for substrates including one of the following plasma etching materials: SiO₂, Si₃N₄, a-C, poly-Si and W (Example 21);

FIG. 24 is estimated etch rates as a function of O₂ flow rate for substrates including one of the following plasma etching materials: SiO₂, Si₃N₄, a-C, poly-Si and W (Example 22);

FIG. 25 is estimated deposition rates as a function of O₂ flow rate for substrates including one of the following plasma etching materials: SiO₂, Si₃N₄, a-C, poly-Si and W (Example 23);

FIG. 26 is estimated deposition rates as a function of C₅H₉F₅Si flow rate for substrates including one of the following plasma etching materials: SiO₂, Si₃N₄, a-C, poly-Si and W (Example 24);

FIG. 27 is estimated polymer deposition rates as a function of C₅H₉F₅Si flow rate for substrates including one of the following plasma etching materials: SiO₂, Si₃N₄, a-C, poly-Si and W (Example 25);

FIG. 28 is estimated deposition rates as a function of O₂ flow rate for substrates including one of the following plasma etching materials: SiO₂, Si₃N₄, a-C, poly-Si and W (Example 26);

FIG. 29 is estimated deposition rates as a function of C₄H₉F₃Si flow rate for substrates including one of the following plasma etching materials: SiO₂, Si₃N₄, a-C, poly-Si, W, SiC, SiCN, SiON (Example 27);

FIG. 30 is estimated deposition rates as a function of CH₂F₂ flow rate for substrates including one of the following plasma etching materials: SiO₂, Si₃N₄, a-C, poly-Si, W, SiC, SiCN, SiON (Example 28);

FIG. 31 is estimated deposition rates as a function of C₄H₉F₃Si flow rate for substrates including one of the following plasma etching materials: SiO₂, Si₃N₄, a-C, poly-Si, W, SiC, SiCN, SiON (Example 29);

FIG. 32 is thickness results of SiO₂, Si₃N₄, a-C, poly-Si, W, SiC, SiCN, SiON films after the cyclic etching process as a function of number of cycles (Example 30);

FIG. 33 is estimated thickness results of studied materials films (reflecting etching of the film or deposition of polymer on surface of the film) for thickness of Si₃N₄ same as demonstrated on FIG. 32 if continuous infinite selectivity etching recipe of Si₃N₄ will be used instead of cyclic process;

FIG. 34 summarizes thickness results of Pt, a-C, poly-Si, SiC, films after one etching cycle described in Example 31 and continuous process described in Example 32; and

FIG. 35 is exemplary etching gas delivery apparatus or system.

### DESCRIPTION OF PREFERRED EMBODIMENTS

Disclosed are methods or processes of plasma dry etching using a vapor of Si-containing hydrofluorocarbon etching compound, preferably a vapor of methyl-silyl-hydrofluorocarbon etching compound, as etching gas applied in plasma etching processes including high aspect ratio (HAR) plasma etching processes, selective plasma etching processes and cyclic plasma etching processes for fabrication of semiconductor structures, such as 3D NAND structures, contact holes, DRAM capacitors, etc., but not limited to those applications. The disclosed plasma dry etching methods provide a novel chemistry to etch off silicon-containing films, organic films, metal-containing films or the like, and control formed structure profiles in the plasma etching processes. Protection of sidewalls by controlling plasma-deposited polymers during plasma dry etching is a key mechanism to keep a defined profile without distortions. The disclosed plasma dry etching methods also provide a novel chemistry to control the profile of the plasma-deposited polymers during the plasma etching processes. Furthermore, use of the disclosed Si-containing hydrofluorocarbon compounds in a cyclic plasma etching process allows enhancing control of the shape or profile of etched structures while keeping etch rate comparable.

The disclosed methods of plasma dry etching comprise methods of selective HAR plasma dry etching silicon-containing films over a patterned mask layer, selective plasma dry etching silicon-containing films versus other non-etching films, selective plasma dry etching organic films or metal-containing films versus other non-etching films, and cyclic selective plasma dry etching silicon-containing films, organic films and metal-containing films versus other non-etching films, employing the disclosed Si-containing hydrofluorocarbon etching compounds, preferably methyl-silyl-hydrofluorocarbon etching compounds.

Most of semiconductor devices are formed using processes of formation of thin films on top of a substrate and patterning of those films to receive desired structures and devices. Patterning includes lithography step, which allows defining a formed pattern and etching steps that are used to remove unnecessary materials or films from the substrate through the formed pattern. One of commonly used etching processes is a plasma dry etching when the substrate is exposed to plasma or reactive species formed in the inside of a process chamber. Combination of physical (e.g., sputtering by ion bombardment) and chemical (e.g., surface interactions with reactive species) mechanisms in plasma etching allows achieving preferential etching of a particular material selectively to other materials depending on used chemistry and process conditions.

The disclosed herein includes selective plasma etching processes that is one of key processing for patterning of thin films during fabrication of advanced semiconductor devices. The selective plasma etching processes may selectively etch undesired materials vertically, such as 3D NAND structures, contact holes, etc., and horizontally such as multiple materials on the surface of a substrate. Plasma etching is used almost in all steps of semiconductor chip fabrication that requires patterning (e.g., front end of line, back end of line, and middle end of line). Most critical parameters for the plasma etching are etch rate (to keep it high throughput during the fabrication of the semiconductor device), selectivity (to reduce damages or unintentional modifications of non-etching film), constant process development ongoing to achieve high etch rate while keeping high selectivity and an increase of the portfolio of etching materials/gases which could be processed selectively to each other.

In particular, in some cases, it is possible to achieve so-called infinite selective etching, when the etching target material is etched but some polymer is deposited on non-etching materials preserving it from etching. Typically, infinite selectivity comes at cost of lower etch rate comparing to processes with lower selectivity. In addition, if long etching process is needed infinite selectivity may lead to deposit a thick polymer film on the surface of non-etching materials, electrodes of the plasma etching device and plasma etching chamber itself, which requires further processing or cleaning to remove the deposited polymer film. In some cases, deposition of polymer may limit the applicability of infinite selectivity etching process. A possible solution to solve the problem of excessive polymer deposition during etching with infinite selectivity is to use a cyclic etching process, where undesired deposited polymer is removed during one of steps inside an etching cycle. The disclosed herein comprises cycling etching processes featuring introduction of a Si-containing hydrofluorocarbon to at least one of the steps inside etching cycles, which allows etching of etching target material with high selectivity versus non-etching materials and to keep non-etching materials and chamber walls close to their initial conditions after cyclic etching process.

The disclosed Si-containing hydrofluorocarbon compounds have a general formula:

CₓH_{y}F_{z}Siₙ (I)

where 1≤x≤6, 1≤y≤9, 1≤z≤15, n=1 or 2.

In some embodiments, the Si-containing hydrofluorocarbon compounds in formula (I) may be methyl-silyl-hydrofluorocarbons containing one or more methyl group(s).

In some embodiments, the Si-containing hydrofluorocarbon compounds in formula (I) may be methyl-silyl-hydrofluorocarbons containing one or more methyl group(s) in which at least one methyl group is attached to the Si atom.

In some embodiments, the Si-containing hydrofluorocarbon compounds in formula (I) may be methyl-silyl-hydrofluorocarbons containing one or more methyl group(s) in which none of the one or more methyl group(s) is attached to the Si atom.

In some embodiments, the Si-containing hydrofluorocarbon compounds may not contain any methyl groups.

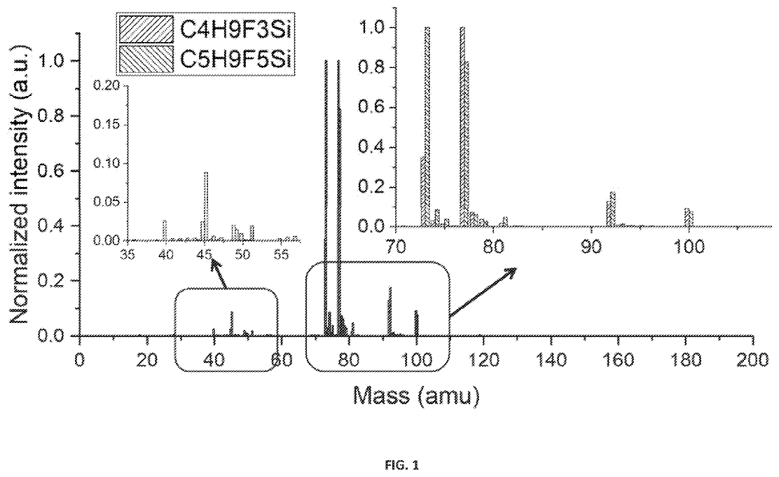

The disclosed Si-containing hydrofluorocarbon compounds may be used for promotion of the passivation process during HAR etching. Main feature of the disclosed Si-containing hydrofluorocarbon compounds is the formation of species with Si atom under plasma conditions and at least one methyl group attached to Si atom that promotes the formation of a Si-containing polymer on the surface of a substrate. FIG. 1 is signals of exemplary Si-containing hydrofluorocarbon compounds, trimethyl(trifluoromethyl)silane (C₄H₉F₃Si) and pentafluoroethyl(trimethyl)silane (C₅H₉F₅Si) recorded using a quadrupole mass spectrometer in residual gas analysis mode with an electron energy of 20 eV during the scan. As shown, dissociation results of C₄H₉F₃Si and C₅H₉F₅Si, mainly result in the formation of C₃H₉Si, C₂H₆FSi, C₃H₉FSi, CH₅Si, and C₂F₄ fragments. All of Si-containing fragments observed in the spectrum have methyl group attached to the Si atom, three methyl groups for C₃H₉Si; two methyl groups for C₂H₈FSi; three methyl groups for C₃H₉FSi; one methyl group for CH₅Si. Therefore, in the presence of plasma, the formation of radicals with at least one methyl group attached to the Si atom is expected by electron impact dissociation, collisional dissociation and ro-vibrational excitation. All of the Si-containing radicals with methyl group(s) that are produced by dissociation of initial Si-containing hydrofluorocarbons are effective for the formation of Si-containing film on all surfaces of the substrate, when C₂F₄ is one of fragments typically produced in the case of dissociation of common fluorocarbon gases (e.g., C₄F₆ and C₄F₈) and may be valuable for the etching process.

Rich deposition of a robust polymer on surfaces of the substrate achieved by the use of Si-containing hydrofluorocarbon may be used for the promotion of the passivation process during HAR etching. Therefore, a vapor of any Si-containing hydrofluorocarbon compounds covered by the formula (I) with at least one methyl group attached to Si, such as CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, and C₆H₉F₇Si, may be used for selective plasma etching. Use of the Si-containing hydrofluorocarbons with at least one methyl group attached to Si allows to deposit a robust polymer at a fast deposition rate; however, in general, the presence of Si atom in the hydrofluorocarbon will allow to deposit more robust polymer comparing to commonly used hydrofluorocarbon or fluorocarbon gas due to incorporation of Si into the deposited polymer, even in absence of methyl group attached to silicon or in the case when a Si-containing hydrofluorocarbon molecule contains methyl group not attached to Si atom.

Exemplary disclosed Si-containing hydrofluorocarbon etching compounds are listed in Table 1, in which their structure formula, CAS numbers and boiling points are included. These molecules are commercially available or may be synthesized by methods known in the art. The disclosed Si-containing hydrofluorocarbon etching compounds may also include their isomers.

As summarized in Table 1, not only Si-containing hydrofluorocarbons with methyl group attached to Si, such as C₄H₉F₃Si and C₅H₉F₅Si, may be used for the plasma etching process, but also their isomers and isomers of other Si-containing hydrofluorocarbons with at least one methyl group attached to Si may be used for the plasma etching process with molecular formula from the list of CH₄F₂Si, CH₃F₃Si, C₂H₆F₂Si, C₃H₉FSi, C₃H₉F₃Si, C₅H₉F₅Si, C₆H₉F₇Si, C₄H₁₀F₄Si₂, C₂H₆F₄Si₂.

Furthermore, besides the Si-containing hydrofluorocarbons that contain methyl group(s) and have at least one methyl attached to Si atom used for dry etching process as an etching gas, vapors of the Si-containing hydrofluorocarbons that may not have isomers with at least one methyl group attached to the Si atom or the Si-containing hydrofluorocarbons that may not have isomers with one or more methyl group(s), may also be used for dry etching process as an etching gas, for example, CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃H₄F₆Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, and C₆H₇F₉Si. Furthermore, the Si-containing hydrofluorocarbons may contain two Si atoms that may not have isomers with methyl group(s) attached to Si atoms, such as CH₅FSi₂, CH₃F₃Si₂, CH₂F₆Si₂, C₂H₇F₃Si₂, C₂H₉FSi₂, C₂H₄F₆Si₂, C₂HF₇Si₂, C₂H₂F₆Si₂, C₂H₃F₅Si₂, C₂H₄F₄Si₂, C₃H₄F₈Si₂, C₃H₆F₄Si₂, C₄H₁₀F₄Si₂, C₄H₆F₆Si₂, C₄H₁₁FSi₂, and C₄H₈F₂Si₂. The above mentioned Si-containing hydrofluorocarbons may be used for dry etching process as an etching gas due to the presence of Si atom in the hydrofluorocarbon which will allow to deposit more robust polymer comparing to commonly used hydrofluorocarbon or fluorocarbon gases due to incorporation of the Si into the deposited polymer, even in absence of methyl group attached to silicon. As stated above, the other Si-containing hydrofluorocarbons not having isomers with methyl group(s) attached to Si or not having isomers with methyl group(s) may be used for dry etching process as an etching gas to increase selectivity and etching profile control in the case of HAR etching.

TABLE 1

| | | | | Boiling point |
|---|---|---|---|---|
| | Molecular | | | (° C.) at 760 |
| Structure | formula | Name | CAS # | Torr |
| 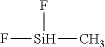 | CH₄F₂Si | Difluoromethylsilane | 420-34-8 | −35.6° C. |
| 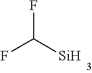 | CH₄F₂Si | (difluoromethyl)-(8Cl,9Cl) silane | 10112-10-4 | −2.4 ± 30.0° C. |
| 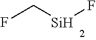 | CH₄F₂Si | Silane, fluoro(fluoromethyl)- (9Cl) | 99577-92-1 | −0.7 ± 30.0° C. |
| 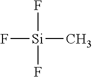 | CH₃F₃Si | Methyltrifluorosilane | 373-74-0 | −30° C. |
| 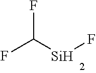 | CH₃F₃Si | Silane, (difluoromethyl)fluoro- (9Cl) | 129452-95-5 | 2.5 ± 30.0° C. |
| 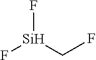 | CH₃F₃Si | Silane, difluoro(fluoromethyl)- (9Cl) | 99577-93-2 | −20.7 ± 15.0° C. |
| 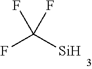 | CH₃F₃Si | (Trifluoromethyl)silane | 10112-11-5 | −22.4 ± 30.0° C. |
| 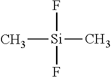 | C₂H₈F₂Si | Difluorodimethylsilane | 353-66-2 | 2-3° C. |
| 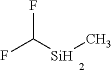 | C₂H₆F₂Si | Silane, (difluoromethyl)methyl- (9Cl) | 142208-16-0 | 23.4 ± 35.0° C. |
| 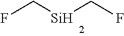 | C₂H₆F₂Si | Silane, bis(fluoromethyl)-(9Cl) | 129439-08-3 | 54.5 ± 25.0° C. |
| 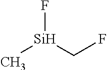 | C₂H₆F₂Si | Silane, fluoro(fluoromethyl)methyl-(9Cl) | 102867-88-9 | 22.4 ± 15.0° C. |
| 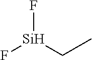 | C₂H₆F₂Si | Silane, ethyldifluoro- (7Cl,8C1,9Cl) | 867-53-8 | −12.8 ± 9.0° C. |
| 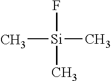 | C₃H₉FSi | Trimethylfluorosilane | 420-56-4 | 16-18° C. |
| 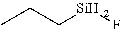 | C₃H₉FSi | Silane, fluoropropyl-(9Cl) | 204515-57-1 | 33.0 ± 23.0° C. |
| 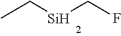 | C₃H₉FSi | Silane, ethyl(fluoromethyl)-(9Cl) | 151479-74-2 | 48.9 ± 15.0° C. |
| 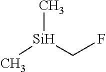 | C₃H₉FSi | Silane, (fluoromethyl)dimethyl- (9Cl) | 151479-73-1 | 28.6 ± 15.0° C. |
| 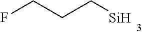 | C₃H₉FSi | Silane, (3-fluoropropyl)-(9Cl) | 64154-29-6 | 41.9 ± 15.0° C. |
| 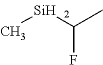 | C₃H₉FSi | (1-fluoroethyl)methylsilane | 944537-94-4 | 42.0 ± 15.0° C. |
| 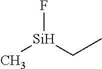 | C₃H₉FSi | Ethylfluoromethylsilane | 867-52-7 | 30° C. |
| 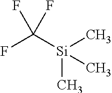 | C₄H₉F₃Si | Trimethyl(trifluoromethyl)silane | 81290-20-2 | 55° C. |
| 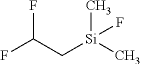 | C₄H₉F₃Si | (2,2-difluoroethyl)fluorodimethylsilane | 2251753-80-5 | 67.9 ± 35.0° C. |
| 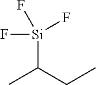 | C₄H₉F₃Si | Trifluoro(1-methylpropyl)silane | 66436-39-3 | 61.0 ± 9.0° C. |
| 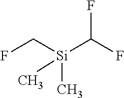 | C₄H₉F₃Si | (difluoromethyl)(fluoromethyl) dimethylsilane | 65912-15-4 | 89.5 ± 40.0° C. |
| 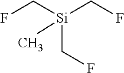 | C₄H₉F₃Si | Tris(fluoromethyl)methylsialne | 65864-65-5 | 115.4 ± 35.0° C. |
| 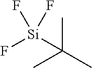 | C₄H₉F₃Si | (1,1-dimethylethyl)trifluorosilane | 60556-38-9 | 35-36° C. |
| 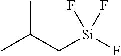 | C₄H₉F₃Si | Trifluoro(2-methylpropyl)silane | 58589-76-7 | 61.0 ± 9.0° C. |
| 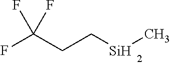 | C₄H₉F₃Si | methyl(3,3,3- trifluoropropyl)silane | 690-96-0 | 58.2° C. |
| 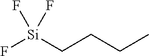 | C₄H₉F₃Si | Butyltrifluorosilane | 371-93-7 | 50-52°C |
| 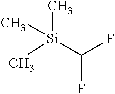 | C₄H₁₀F₂Si | Trimethyl(difluoromethyl)silane | 65864-64-4 | 65-66° C. |
| 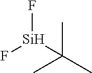 | C₄H₁₀F₂Si | (1,1-dimethylethyl)difluorosilane | 1975209-87-0 | 42.8 ± 9.0° C. |
| 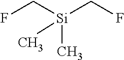 | C₄H₁₀F₂Si | bis(fluoromethyl)dimethylsilane | 65864-63-3 | 90.9 ± 25.0° C. |
| 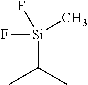 | C₄H₁₀F₂Si | difluoromethyl(1-methylethyl)silane | 56568-88-8 | 61.8 ± 9.0° C. |
| 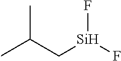 | C₄H₁₀F₂Si | difluoro(2-methylpropyl)silane | 17303-74-1 | 47.5° C. |
| 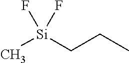 | C₄H₁₀F₂Si | difluoromethylpropylsilane | 690-17-5 | 59° C. |
| 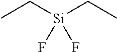 | C₄H₁₀F₂Si | diethyldifluorosilane | 358-06-5 | 61° C. |
| 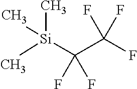 | C₅H₉F₅Si | (Pentafluoroethyl)trimethylsilane | 124898-13-1 | 60° C. |
| 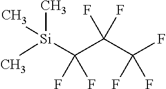 | C₆H₉F₇Si | (Heptafluoropropyl)trimethylsilane | 3834-42-2 | 88° C. |
| 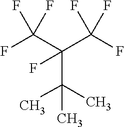 | C₆H₉F₇Si | trimethyl[1,2,2,2-tetrafluoro-1- (trifluoromethyl)ethyl]silane | 18139-72-5 | 95° C. |
| 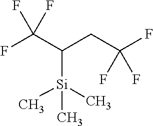 | C₆H₉F₇Si | fluorodimethyl[3,3,3-trifluoro-1- (trifluoromethyl)propyl\|silane | 2475123-40-9 | 95.9 ± 40.0° C. |
| 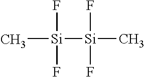 | C₂H₆F₄Si₂ | 1,2-Dimethyltetrafluorodisilane | 56998-69-7 | 21.5 ± 23.0° C. |
| 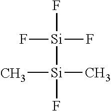 | C₂H₆F₄Si₂ | 1,1,1,2-Tetrafluoro-2,2- dimethyldisilane | 64809-83-2 | 21.5 ± 23.0° C. |
| 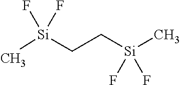 | C₄H₁₀F₄Si₂ | 1,2-Bis(difluoromethylsilyl)ethane | 170381-99-4 | 120.7 ± 23.0° C. |
| 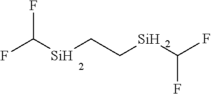 | C₄H₁₀F₄Si₂ | (difluoromethyl)({2- [(difluoromethyl)silyl]ethyl})silane | 2385703-05-7 | 104.4 ± 40.0° C. |
| 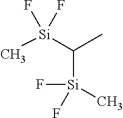 | C₄H₁₀F₄Si₂ | 1,1′-Ethylidenebis[1,1-difluoro-1- methylsilane] | 1438395-90-4 | 108.1 ± 23.0° C. |
| 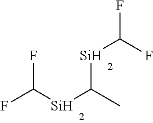 | C₄H₁₀F₄Si₂ | 1,1′-Ethylidenebis[1- (difluoromethyl)silane] | 1433981-48-6 | 103.9 ± 40.0° C. |

Considering the examples of the Si-containing hydrofluorocarbon etching compounds and their isomers listed in Table 1, and the study described in Examples that follow, it may be summarized that the vapor of any Si-containing hydrofluorocarbons and Si-containing hydrofluorocarbons may be used for plasma etching process as an etching gas, in particular any Si-containing hydrofluorocarbons that are covered by the formula (I). Preferably, in the Si-containing hydrofluorocarbons at least one methyl group attached to Si atom due to capability of depositing a robust polymer and enhancing an etching process selectivity.

The disclosed Si-containing hydrofluorocarbon compounds covered by the formula (I) include CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si, or their isomers that have at least one methyl group attached to Si atom.

The disclosed Si-containing hydrofluorocarbon compound is CH₃F₃Si, C₂H₆F₂Si, C₄H₉F₃Si, C₅H₉F₅Si or their isomers.

The disclosed Si-containing hydrofluorocarbon compound is CH₃F₃Si or its isomers.

The disclosed Si-containing hydrofluorocarbon compound is C₂H₆F₂Si or its isomers.

The disclosed Si-containing hydrofluorocarbon compound is C₄H₉F₃Si or its isomers.

The disclosed Si-containing hydrofluorocarbon compound is C₅H₉F₅Si or its isomers.

In some embodiments, the disclosed Si-containing hydrofluorocarbon compounds and their isomers that are covered by the formula (I) but do not contain methyl group(s). This type of the compounds may include some of the isomers of CHF₃Si, CH₂F₂Si, CH₃FSi, CHF₅Si, CH₂F₄Si, C₂HF₇Si, C₂H₂F₆Si, C₂H₃F₅Si, C₂H₄F₄Si, C₂H₄F₂Si, C₂H₃F₃Si, C₂H₂F₄Si, C₂HF₅Si, C₃H₄F₆Si, C₃HF₉Si, C₃HF₇Si, C₃H₃F₅Si, C₃H₄F₄Si, C₃H₅F₃Si, C₄H₅F₇Si, C₄H₃F₉Si, C₄H₂F₁₀Si, C₄HF₁₁Si, C₅H₈F₆Si, C₅H₇F₇Si, C₆HF₁₅Si, C₆H₄F₁₂Si, C₆H₇F₉Si, which may be used as an etching gas in the disclosed plasma dry etching processes even though they do not contain methyl groups.

The boiling point of the disclosed Si-containing hydrofluorocarbon compounds may range from approximately −50° C. to approximately 250° C., preferably, the boiling point of the disclosed Si-containing hydrofluorocarbon compounds may range from approximately −30° C. to approximately 200° C., more preferably, the boiling point of the disclosed Si-containing hydrofluorocarbon compounds may range from approximately −20° C. to approximately 150° C. Even more preferably. the boiling point of the disclosed Si-containing hydrofluorocarbon compounds may range from approximately 20° C. to approximately 150° C.

The disclosed Si-containing hydrofluorocarbon etching compounds are provided at greater than 95% v/v purity, preferably at greater than 99.99% v/v purity, and more preferably at greater than 99.999% v/v purity. The disclosed Si-containing hydrofluorocarbon etching compounds contain less than 5% by volume trace gas impurities, with less than 150 ppm by volume of impurity gases, such as N₂ and/or H₂O and/or CO₂, contained in said trace gaseous impurities. Preferably, the water content in the plasma etching gas is less than 20 ppm by weight. The purified product may be produced by distillation and/or passing the gas or liquid through a suitable adsorbent, such as a 4 Å molecular sieve. The disclosed Si-containing hydrofluorocarbon etching compounds contain less than 10% v/v, preferably less than 1% v/v, more preferably less than 0.1% v/v, and even more preferably less than 0.01% v/v of any of its isomers, which may be purified by distillation of the gas or liquid to remove isomers and may provide better process repeatability.

Alternatively, the disclosed Si-containing hydrofluorocarbon etching compounds may contain between 0.01% v/v and 99.99% v/v of its isomers, particularly when the isomer mixture provides improved process parameters or if isolation of the target isomer is too difficult or expensive. The mixture of isomers may also reduce the need for two or more gas lines to the reaction chamber. Some of the disclosed Si-containing hydrofluorocarbon etching compounds are gaseous at room temperature and atmospheric pressure. For the non-gaseous (i.e., liquid or solid) compounds, their gas form may be produced by vaporizing the compounds through a conventional vaporization step, such as direct vaporization or by bubbling with inert gas (such as N₂, Ar, He). The non-gaseous compounds may be fed in liquid state to a vaporizer where it is vaporized before it is introduced into a reactor.

In the disclosed methods of plasma dry etching, plasma etching gas is a gas mixture including at least one of following substances: a Si-containing hydrofluorocarbon, an oxidizing gas, an inert gas, fluorocarbon and/or hydrofluorocarbon-based chemicals, or another additional gas. The inert gas may be selected from He, Ar, Kr, Xe, or Ne; the oxidizing gas may be selected from O₂, O₃, CO, CO₂, COS, SO, SO₂, FNO, NO, NO, NO₂, N₂O, or H₂O; the additional gas may be selected from H₂, SF₆, NF₃, N₂, NH₃, Cl₂, BCl₃, BF₃, Br₂, F₂, HBr, HCl or combinations thereof. The Si-containing hydrofluorocarbon is preferably a gas of hydrofluorocarbon compound and containing Si atom with at least one methyl group (—CH₃) attached to Si atom to form molecular fragments including Si atom with several methyl groups attached to promote deposition process on non-etching materials for increase of selectivity. This is preferable due to capability to etch list of etching target materials while depositing (meaning infinite selectivity) on other non-etching materials. Furthermore, in the disclosed plasma etching methods, the Si-containing hydrofluorocarbon is preferably a gas of a compound represented by a composition formula (I). Using the inert gas is for generation of plasma and promotion of ion bombardment during the etching process and depending on gas ratio promotes or suppresses dissociation of other gases in the etching gas mixture, which causes direct impact on etching speed and anisotropy of the etching process. An addition of the oxidizing gas to the etching gas mixture allows increasing etching speed, promoting isotropic etching and surface or gas phase chemical reactions, and increasing selectivity of the etching process, depending on the etching gas mixture and type of etching and non-etching materials. The additional gas mentioned above may improve control of process or increase etch rate. The fluorocarbon or hydrofluorocarbon gas may promote both anisotropic etching process of etch film and vertical surface and/or non-etching film passivation. Examples of the fluorocarbon gases that may be used in the disclosed plasma etching method include, but is not limited to, CF₄, C₂F₆, C₃F₆, C₄F₆, C₄F₈, C₅F₈, C₅F₁₀, C₆F₁₂, C₇F₁₄, C₈F₁₆, of the like. Examples of the hydrofluorocarbon gases that may be used in the disclosed plasma etching method include, but is not limited to, CH₂F₂, CH₃F, CHF₃, C₂H₅F, C₃H₇F, C₅H₇F, C₃H₂F₆, C₃H₄F₂, C₃H₂F₄, C₄H₂F₆, C₄H₃F₇, or the like.

Under the plasma condition, various reactive species and ions are generated directly by dissociation of these compounds and chemical reactions through interaction between species presented in gas phase. Typically, plasma etching effect may be achieved with any of compounds represented by above mentioned compounds, when the above mentioned compounds are used individually or mixed with each other. Depending on the structure of individual compound, it may promote either etching performance (including increase of etching speed of particular etching material) or passivation during high aspect ratio etching process. In particular, a mixture of C₄F₆ and C₄F₈ is one of commonly used mixtures because C₄F₆ is efficient for promotion of passivation and C₄F₈ is efficient for increase of etching speed, resulting in a high anisotropy of etching processes as discussed in the Comparative Example 6 that follows. Furthermore, a hydrofluorocarbon gas such as CH₂F₂ may be added to increase the etching speed of silicon nitride film if it is desired.

In order to achieve HAR of etched structures and improve etching selectivity to certain materials or films while keeping high etch rate, etching gases may be chosen to form preferentially volatile byproducts with the etching material while not reacting with non-etching material forming less volatile byproducts. It has been discovered throughout the disclosed methods of plasma dry etching that the addition of Si-containing hydrofluorocarbons covered by the formula (I) to the process etching gas mixture allows to dramatically increase selectivity and aspect ratio during etching of Si-containing compound materials.

In the case of plasma etching processes disclosed herein, etching based on chemical reaction may be combined with physical sputtering by ion bombardment. Gases used for plasma etching are typically dissociated by plasma resulting in presence of large number of reactive species which are capable of deposition or etching or surface functionalization. This brings additional way of selective etching, when material is removed in the same time some film is deposited on non-etching material. This approach allows achieving large values of selectivity during etching process and the deposited film may be removed after the etching process or removed during the etching process.

In the disclosed plasma etching methods, use of Si-containing hydrofluorocarbons in the etching gas mixture allows achieving high or even infinite selectivity of etching target materials to other non-etching materials while keeping relatively high etching rate. Selectivity is achieved by deposition of a robust polymer on non-etching materials while the polymer is not deposited on (or react with) the etching target material. Capability of depositing a robust polymer during etching process is attributed to formation of Si-containing fragments with methyl groups attached directly to Si atom by dissociation of the Si-containing hydrofluorocarbons. Molecules having Si and methyl groups with the methyl groups attached to the Si is commonly used as a precursor for deposition of Si-containing films, which correlates well with observed results in the disclosed methods, e.g., use of trifluoromethylsilane (C₄H₉F₃Si) results in generation of trimethylsilane fragments (C₃H₉Si) by dissociation of parent molecules in plasma due to weak bounding between Si atom and trifluoromethyl group in trimethylsilane molecule.

Various disclosed methods of plasma dry etching applying the above descriptions are described herein below.

### HAR Plasma Dry Etching

In some embodiments, the disclosed method of plasma dry etching silicon-containing films is applied to etch a substrate having one or more processing or etching films (e.g. silicon oxide, silicon nitride or combinations thereof) and one or more non-etching films (e.g. amorphous carbon, amorphous silicon, doped amorphous carbon, doped amorphous silicon, metals, etc.) in HAR etching processes for fabrication of semiconductor structures, such as 3D NAND structures, contact holes, DRAM capacitors, etc., but are not limited to those applications. The disclosed method of plasma dry etching one or more processing films for forming a HAR aperture in a substrate comprise the steps of:
mounting the substrate on a mounting table in a processing chamber or a reaction chamber; the substrate having the one or more processing films deposited thereon and a non-etching film deposited on the one or more processing films;
introducing an etching gas containing a vapor of a Si-containing hydrofluorocarbon into the processing chamber;
igniting the etching gas into a plasma; and
allowing an etching reaction to proceed between the plasma and the one or more processing films so that the one or more processing films are etched versus the non-etching film, thereby forming the aperture.

The one or more processing films may be silicon-containing films including SiₐO_{b}C_{c}N_{d}Hₑ where a, b, c, d, e range from 0.1 to 6 and b, c, d, e each may be independently 0. The one or more processing films may also include dopants, such as B, C, P, As Ga, In, Sn, Sb, Bi and/or Ge. The non-etching films may be patterned hardmask layers, e.g. amorphous carbon, amorphous silicon, doped amorphous carbon, doped amorphous silicon, metals, etc.

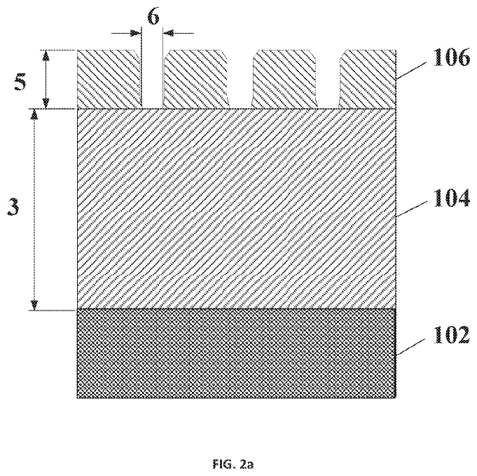

The term “high aspect ratio aperture” or “HAR aperture” used herein refers to the formation of an aperture pattern in an etching target film by the disclosed plasma etching method when aspect ratio of formed aperture structures is exceeding value of 5. High anisotropy (etching of exposed target material preferentially in a substantial vertical direction) of a plasma etching process is required to achieve HAR of etched apertures (see FIG. 2b). In order to achieve etch anisotropy, that is, directional etch in the vertical direction when lateral etching is minimized, typically formation of a polymer on the sidewall of the etched structure or aperture is formed. Formation of the polymer preferentially on the sidewall of the etched structures is achieved by competition between etching process (removal of the polymer) and deposition process (formation of the polymer). Presence of directional (in vertical direction) etching by ion bombardment allows removing the polymer on the horizontal surfaces more effectively than on vertical surfaces, resulting in promotion of formation of the polymer on vertical sidewalls. Furthermore, fine tuning of the etching and deposition process allows achieving preferential etching of the substrate in the vertical direction when etching in lateral direction is suppressed, which allows preserving horizontal dimensions of the structures.

Example of initial structure of a substrate including plasma etching film and non-etching film with some openings is presented in FIG. 2a and an HAR structure formed after the plasma etching process are presented on FIG. 2b. As shown, monocrystalline silicon wafer 102 with structures presented on FIG. 2a formed on the top was used as a substrate. Silicon dioxide film 104 with an original thickness, such as 3000 nm (arrow 3), has been used as a film. Patterned film of amorphous carbon 106 with a thickness, such as 868 nm (arrow 5), has been used as a non-etching material. An opening pattern in amorphous carbon film (arrow 6) has a bottom diameter, such as about 120 nm. Example of profile of the substrate after an etching process in presented on FIG. 2b. Where arrow 7 is a thickness of non-etching film 206 (here is amorphous carbon) after the etching process, arrow 8 is a depth of etched HAR hole in the plasma etching film 204, arrow 9 is diameter of top of the HAR hole 208 in the plasma etching film 204 (hereafter “top CD”), arrow 10 is diameter in the middle of HAR hole 208 in the plasma etching film 204 (hereafter “middle CD”) and arrow 11 is diameter of HAR hole 208 in the bottom (hereafter “bottom CD”). Here “CD” represents critical dimension.

Selection of etching gases and ratio of each gas concentration in an etching gas mixture is required to achieve balance between deposition process for protection of vertical surfaces (hereafter “passivation”) and etching process for anisotropic removal of materials. Typically, a combination or a mixture of etching gases is used, where each gas type is playing different role. The processing etching gas mixture used in the disclosed methods of plasma dry etching silicon-containing films may include at least one disclosed Si-containing hydrofluorocarbon (e.g., CH₃F₃Si, C₂H₆F₂Si, C₄H₉F₃Si, C₅H₉F₅Si), at least one fluorocarbon or hydrofluorocarbon gas (e.g. C₄F₈, C₄F₆, CF₄, CH₂F₂), optionally at least one inert gas (e.g. He, Ar, Kr, Xe, Ne), optionally an oxidizing gas (e.g. O₂, O₃, CO, CO₂, COS, SO, SO₂, FNO, NO, N₂O, NO₂, H₂O, Cl₂, F₂). optionally an additional gas selected from H₂, SF₆, NF₃, N₂, NH₃, Cl₂, BCl₃, BF₃, Br₂, F₂, HBr, HCl or combinations thereof, which are used for the formation of reactive species and ions in a plasma. Besides, at least one fluorocarbon or hydrofluorocarbon gas, selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆, C₄H₃F₇, or the like, may be added to the etch gas mixture.

More specifically, the disclosed plasma etching methods have the following steps. In the first step, a substrate containing one or more films including optionally non-etching films that may be patterned, i.e., having some patterns such as openings or apertures in the film, is placed on a mounting table or a substrate holder in a plasma etching chamber or a reactor. The substrate may be any types of etching target materials as long as it could be processed by plasma etching. For example, monocrystalline Si wafer including at least one Si-containing film, organic film or metal containing film or plural films part of which may be patterned. Example of the substrate having the films and non-etching films with pattern is shown in FIG. 2a. The reactor includes a vessel capable of providing low pressure inside the vessel by degassing; a plasma generator capable of generating plasma inside the reactor; and a substrate holder capable of holding the substrate inside the reactor exposed to the plasma with regulation of the temperature using cooling apparatus or gas flow, e.g. helium flow. Then, the etching gas mixture, including several vapors or gases in specified proportions that may change during the etching process, is introduced into the reactor and the pressure inside the reactor is maintained at defined value or several values that may be changed during the process. The etching gas mixture may be a Si-containing hydrofluorocarbon, or a Si-containing hydrofluorocarbon mixed with a hydrofluorocarbon or fluorocarbon and/or an oxidizing gas and/or an inert gas. Next, a plasma generator applies high frequency electromagnetic field to the etching gas mixture resulting in the formation of a glow discharge. When the substrate is exposed to a plasma generated inside the reactor, the etching target film is removed by a combination of ion bombardment and interaction with reactive species, resulting in the formation of volatile by-products.

The disclosed plasma etch methods using the disclosed Si-containing hydrofluorocarbon compounds as etching gas produce apertures, such as channel holes, gate trenches, staircase contacts, capacitor holes, contact holes, contact etch, slit etch, self-aligned contact, self-aligned vias, super vias etc., in the silicon-containing films. The resulting apertures may have an aspect ratio ranging from approximately 5:1 to approximately 500:1, preferably from approximately 20:1 to approximately 400:1; and a diameter ranging from approximately 5 nm to approximately 500 nm, preferably less than 100 nm. For example, one of ordinary skill in the art will recognize that a channel hole etch produces apertures in the silicon-containing films having an aspect ratio greater than 50:1.

### Selective Plasma Dry Etching Si-Containing Films

In some embodiments, the disclosed methods of plasma dry etching include methods of selective plasma dry etching silicon-containing films employing the disclosed Si-containing hydrofluorocarbon etching compounds. The disclosed methods of selective plasma dry etching of silicon-containing films may process a substrate having one or more etching target films, e.g., silicon oxide, silicon nitride or combinations thereof, and non-etching films, e.g., amorphous silicon, SiCN, SiC, doped amorphous silicon or the like, deposited thereon. The disclosed methods of selective plasma dry etching silicon-containing films provide a process of etching Si-containing materials or films with high selectivity over other materials or films. The disclosed methods of selective plasma dry etching silicon-containing films may be isotropic and anisotropic etching applied to form 2D and 3D active components on logic substrates, such as FinFET, Gate All Around (GAA)-FET or Forksheet-FET, etc.

The disclosed methods of selective plasma dry etching silicon-containing films provide a novel chemistry to increase of selectivity of etching target materials to non-etching materials by promotion of a polymer formation on the non-etching materials using an addition of the Si-containing hydrofluorocarbon to an etching gas mixture. In the disclosed plasma etching methods, the addition of the Si-containing hydrofluorocarbon to the etching gas mixture allows to inhibit etching of the non-etching materials by deposition of a polymer thereon while keeping etching target material at a reasonable etch rate resulting in high or even infinite value of selectivity. In particular, it is demonstrated that it is possible to etch silicon-containing films, such as SiO₂ and Si₃N₄ with infinite selectivity to each other, and to amorphous carbon, polycrystalline silicon, W, SiC, SiON and SiCN, which are materials commonly used in multicolor etching and advanced patterning. The Examples 12 to 18 that follow are promising for selective etching of Si-containing compounds. The disclosed methods of selective plasma dry etching Si-containing films for forming a structure in a substrate comprises the steps of:
introducing a vapor of a Si-containing hydrofluorocarbon into a reaction chamber that contains a substrate, the substrate having a pattern containing one or more processing films and at least one non-etching films deposited thereon;
igniting a plasma to produce an activated Si-containing hydrofluorocarbon; and
allowing an etching reaction to proceed between the activated Si-containing hydrofluorocarbon and the one or more processing films so that the one or more processing films are selectively etched versus the at least one non-etching films.

The one or more processing films may be silicon-containing films including SiₐO_{b}C_{c}N_{d}Hₑ where a, b, c, d, e range from 0.1 to 6 and b, c, d, e each may be independently 0. The one or more processing films may also include dopants, such as B, C, P, As Ga, In, Sn, Sb, Bi and/or Ge. The non-etching films may be all other materials used in fabrication of semiconductor devices at certain level such as, organic films (a-C or doped a-C film, a-Si, photoresist (PR), etc.), metal film, metal-containing film. The non-etching films may be other silicon-containing films different from the silicon-containing film to be etched but having the same formula as the silicon-containing film to be etched, that is, SiₐO_{b}C_{c}N_{d}Hₑ where a, b, c, d, e range from 0.1 to 6 and b, c, d, e each may be independently 0.

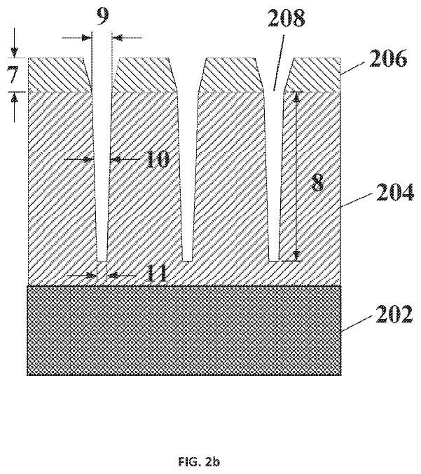

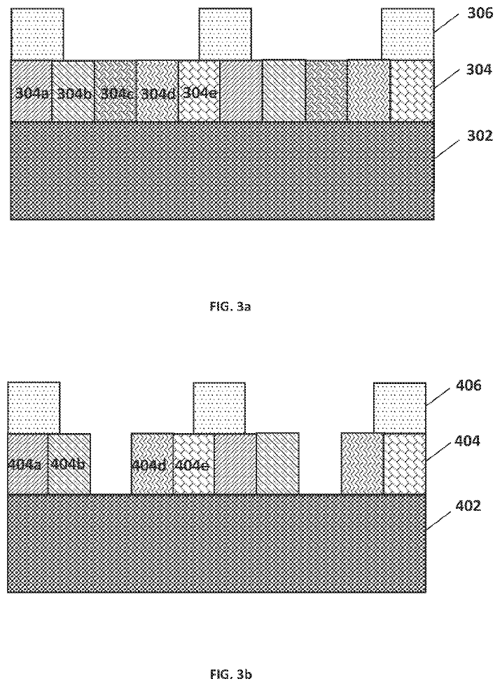

Example of initial structure of a substrate having multiple films including plasma etching films and non-etching films with some openings is presented in FIG. 3a and a structure formed after the selective plasma etching process are presented on FIG. 3b. As shown, monocrystalline silicon wafer 302 with multiple film structures formed on the top of the monocrystalline silicon wafer 302 may be used as a substrate as shown in FIG. 3a. Multiple films 304 (e.g., 304a, 304b, 304c, 304d and 304e) has been deposited on monocrystalline silicon wafer 302 and one of multiple films 304 will be used as a film. Patterned film of amorphous carbon 306 will be used as a non-etching material. Opening patterns in amorphous carbon film may expose some of multiple films 304 to the etching gas. Example profile of the substrate after a selective etching process is presented on FIG. 3b, where film 404c is selectively etched over other films 404a, 404b, 404d and 404e.

Specifically, the disclosed methods aim to etch particular Si-containing compound (e.g., silicon oxide, silicon nitride) selectively to all other materials used in fabrication of semiconductor devices at certain level (e.g., front end of line or middle end of line) employing a mixed gas including at least one of following substances: at least one Si-containing hydrofluorocarbon, inert gas, oxidizing agent, optionally fluorocarbon and/or hydrofluorocarbon and additional gas as a processing etching gas mixture. The use of Si-containing hydrofluorocarbon in the processing etching gas mixture allows to achieve high or even infinite selectivity of silicon-containing films to other materials while keeping relatively high etching speed. The at least one Si-containing hydrofluorocarbon is covered by formula (I). The inert gas may be selected from He, Ar, Kr, Xe, Ne. The oxidizing gas may be selected from O₂, O₃, CO, CO₂, SO, SO₂, FNO, NO, NO, NO₂, H₂O, H₂, or N₂O. The additional gas may be any of the following gas: H₂, SF₆, NF₃, N₂, NH₃, Cl₂, BCl₃, BF₃, Br₂, F₂, HBr, HCl or combinations thereof. The optionally fluorocarbon and/or hydrofluorocarbon may be selected from one or more of CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆, C₄H₃F₇, or the like. A selectivity of the etching film to the at least one non-etching film may be larger than 5, preferably, larger than 10.

As stated above, for example, use of trifluoromethylsilane (C₄H₉F₃Si) results in generation of trimethylsilane fragments (C₃H₉Si) by dissociation of parent molecules in plasma due to weak bounding between Si atom and trifluoromethyl group in trimethylsilane molecule, which allows deposition of a polymer in Example 14, which brings infinite selectivity discussed in the present disclosure.

### Selective Plasma Dry Etching Organic Films or Metal-Containing Films

In some embodiments, the disclosed methods of plasma dry etching include methods of selective plasma dry etching organic films or metal-containing films employing the disclosed Si-containing hydrofluorocarbon etching compounds. The disclosed methods of selective plasma dry etching organic or metal-containing films etch a substrate having one or more etching films (e.g., amorphous carbon and W-doped amorphous carbon), and non-etching films (e.g., polycrystalline silicon, silicon nitride, silicon oxide, metal or the like) deposited thereon. In particular, the disclosed selective etching methods aim to etch particular organic materials (e.g., a-C and doped a-C, a-Si, PR, etc.) or metal-containing films selectively to all other materials (e.g. Si-containing film, doped Si-containing film, etc.) used in fabrication of semiconductor device at certain level (e.g. front end of line or middle end of line) employing a mixed gas of at least one Si-containing hydrofluorocarbon, oxidizing agent, inert gas and optionally fluorocarbon and/or hydrofluorocarbon as an etching gas. The disclosed methods of selective plasma dry etching of organic films or metal-containing films comprise the steps of:
introducing a vapor of a Si-containing hydrofluorocarbon and an oxidizing gas and optionally inert gas (He, Ar, Xe, Kr, Ne) into a reaction chamber that contains a substrate, the substrate having a pattern containing an organic film or a metal-containing film and at least one non-etching films deposited thereon;
igniting a plasma to produce an activated Si-containing hydrofluorocarbon and an activated oxidizing gas; and
allowing an etching reaction to proceed between the activated Si-containing hydrofluorocarbon and the activated oxidizing gas and the organic film or metal-containing film so that the organic film or metal-containing film is selectively etched versus the at least one non-etching film.

The amorphous carbon and W-doped amorphous carbon are one of common materials for 3D NAND high aspect ratio etching mask, self-align patterning mask, contact etch mask, etc. Using Si-containing hydrofluorocarbon is possible to dramatically increase the selectivity of the etching process to other materials. Adding the oxidizing gas (e.g., O₂, O₃, CO, CO₂, SO, SO₂, FNO, NO, N₂O, NO₂, H₂O, H₂, or N₂O) and/or inert gas (e.g., He, Ar, Kr, Xe, Ne,) mixture to the etching gas may promote polymer deposition on non-etching materials. Highly selective etching of amorphous carbon and W-doped amorphous carbon over the non-etching films is promising for organic mask patterning and stripping and for patterning of other materials on the substrate.

Accordingly, the disclosed methods of selective plasma dry etching organic films or metal-containing films may enable a high selectivity of amorphous carbon and W-doped amorphous carbon over non-etching materials while keeping high etching rate of organic materials or metal-containing films presented on a substrate or a mask material for formation of a pattern on the mask material without damaging under layered materials.

The disclosed method of selective plasma dry etching organic films or metal-containing films may be used in selective etching for formation of a pattern on organic hard mask, stripping or patterning of another organic film on the substrate. The disclosed method of selective plasma dry etching of organic films or metal-containing films is a method of processing a substrate including one or more etching target film (e.g. amorphous carbon and doped amorphous carbon) and non-etching films (e.g. polycrystalline silicon, silicon nitride, silicon oxide, metal), when an etching gas mixture includes at least one Si-containing hydrofluorocarbon (e.g. C₄H₉F₃Si), an inert gas (e.g. Ar), an oxidizing gas (e.g. O₂), and an additional gas selected from H₂, SF₆, NF₃, No, NH₃, Cl₂, BCl₃BF₃, Br₂, F₂, HBr, HCl or combinations thereof used for formation of reactive species and ions in the plasma. Here, hydrofluorocarbon or fluorocarbon gases may not be included in the etching gas mixture. The substrate may be any type of materials as long as it could be processed by plasma etching. A selectivity of the etching organic films or metal-containing film to the at least one non-etching film may be larger than 5, preferably, larger than 10.

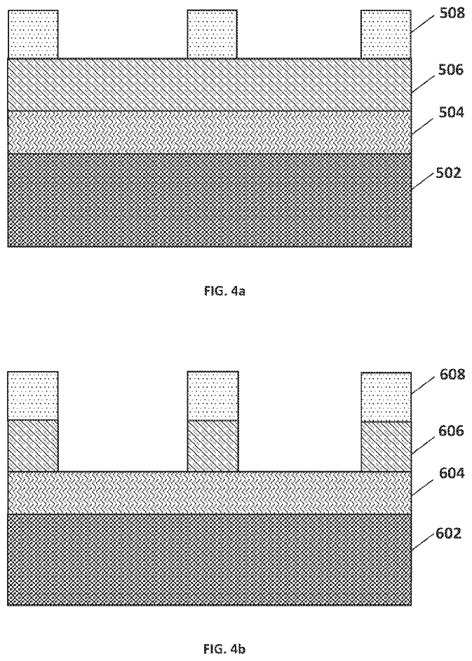

Depending on etching process, selectivity to certain materials may be achieved by use of physical or chemical properties of materials presented on substrate and the etching gas. The addition of Si-containing hydrofluorocarbon to the etching gas mixture allows dramatically increasing selectivity during etching of organic materials or metal-containing films by deposition of polymer on non-etching materials. Example of initial structure of a substrate having an organic etching films or metal-containing films and non-etching films with some openings is presented in FIG. 4a and high selectivity after the selective plasma etching process are presented on FIG. 4b. Monocrystalline silicon wafer 502 with multiple film structures formed on the top was used as a substrate as shown in FIG. 4a. Underlayer 504 has been deposited on monocrystalline silicon wafer 502 and mask material layer 506 was deposited on top of the underlayer 504. Patterned initial mask 508, for example, photoresist layer, on top of the mask material layer 506 will used as a non-etching material. Opening patterns in patterned initial mask 508 may expose some of mask material layer 506 to the etching gas. Example profile of the substrate after a selective etching process is presented on FIG. 4b, where mask material layer 606 is selectively etched over patterned initial mask 608.

### Cyclic Selective Plasma Dry Etching

In some embodiments, the disclosed methods of plasma dry etching include methods of cyclic selective plasma dry etching of silicon-containing films and metal-containing films employing the disclosed Si-containing hydrofluorocarbon etching compounds.

The disclosed methods of cyclic selective plasma dry etching of silicon-containing or metal-containing films etch a substrate including one or more etching target film, e.g. metal (e.g., platinum), silicon oxide, silicon nitride or combinations thereof and non-etching materials or films (e.g. amorphous silicon, SiCN, SiC, doped amorphous silicon), when an etching gas mixture including at least one Si-containing hydrofluorocarbon, optionally an oxidizing agent, optionally a fluorocarbon or hydrofluorocarbon gas and optionally at least one inert gas are used for formation of reactive species and ions in at least one step of cyclic plasma etching process. Etching process is performed in a cyclic way comprising several etching steps repeated in a sequence over the time, when conditions of each etching step may be altered depending on number of cycles. The substrate may be any type of materials as long as it could be processed by plasma etching. The disclosed methods of cyclic selective plasma dry etching silicon-containing or metal-containing films achieve high selectivity to non-etching materials while keeping high etch rate throughput to etching target films and low rate of polymer deposition on non-etching materials and etching chamber interior using a cyclic etching process. The disclosed methods of cyclic selective plasma dry etching of silicon-containing films or metal-containing films may be used in formation of structures by selective etching in front end of line, self-aligned multiple patterning, hard mask opening and etching, etc. The disclosed methods of cyclic selective plasma dry etching an etching film (such as silicon-containing films or metal-containing films) comprises:
i) introducing a first etching gas containing a vapor of a Si-containing hydrofluorocarbon compound into a reaction chamber that contains a substrate having a pattern containing the etching film and at least one non-etching films deposited thereon;
ii) applying an electric power to generate a plasma of an activated first etching gas;
iii) allowing an etching reaction to proceed between the activated first etching gas and the etching film so that the etching film is selectively etched versus the at least one non-etching films, simultaneously depositing a polymer by the activated first etching gas on the at least one non-etching films;
iv) introducing a second etching gas into the reaction chamber;
v) allowing an etching reaction to proceed between the activated second etching gas and both of the etching film and the polymer deposited on the at least one non-etching films, so that both of the etching film and the polymer deposited on the at least one non-etching films are etched; and
vi) repeating i) to v) until the etching film is removed.

Here, the first etching gas may contains the disclosed Si-containing hydrofluorocarbon, one or more hydrofluorocarbons or fluorocarbons, an oxidizing gas, an inert gas and/or an additional gas. The second etching gas may contains one or more hydrofluorocarbons or fluorocarbons, an oxidizing gas, an inert gas and/or an additional gas. The disclosed methods of cyclic selective plasma dry etching of silicon-containing films may further comprise introducing a third etching gas after the step v). Here, the third etching gas is the same as the second etching gas containing one or more hydrofluorocarbons or fluorocarbons, an oxidizing gas, an inert gas and/or an additional gas. However, in one or each cycle, the third etching gas and the second etching gas do not have the same combinations of etching gas compositions from each other. For example, if the second etching gas is a combination of C₄F₆, O₂, Ar and CO₂, then the third etching gas may be a combination of CH₂F₂, O₂, Ar and SF₆ or CH₂F₂, O₃, He, and SF₆. A purging step is applied to after using each etching gas, that is, the purging step is applied after steps iii) and v). During the purging, the electric power for generating the plasma may be still on or may turn off. After purging, the electric power for generating the plasma is turned on. Here, the one or more hydrofluorocarbons or fluorocarbons may be selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇; the oxidizing gas may be selected from O₂, O₃, CO, CO₂, SO, SO₂, FNO, N₂, NO, N₂O, NO₂, or H₂O, COS; the inert gas may be selected from the group consisting of He, Ar, Xe, Kr, or Ne; and the additional gas may be selected from H₂, CO₂, SF₆, NF₃, N₂, NH₃, Cl₂, BCl₃, HCl, HBr, or Br₂.

The possibility to form a polymer on the surface of the substrate, depending on the material being exposed, brings another way of highly selective etching, when the material is removed during the etching process while some film is deposited on non-etching plasma etching materials. This approach allows achieving large values of selectivity, and the deposited film could be removed after the etching process or removed during the etching if a cyclic process is employed. The disclosed cyclic etching methods improve selectivity of etching of the etching target film while keeping high etch rate and low amount of the deposited polymer on the non-etching materials. The addition of Si-containing hydrofluorocarbon to the process gas mixture allows dramatically increasing the selectivity during the etching of Si-containing films and/or metal-containing films while the use of a cyclic process allows significant reduction of polymer growth while keeping high etch rate.

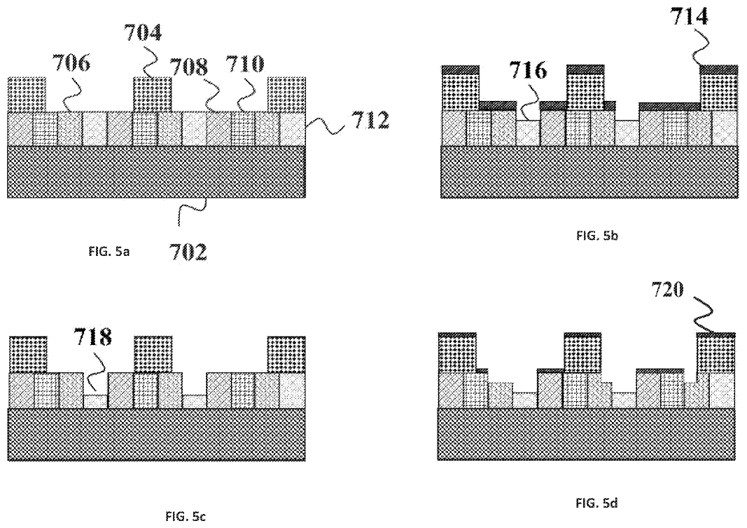

The disclosed cyclic etching process refers to the process when the substrate is processed in an etching chamber using etching steps which are repeated in a sequence. Example of substrate processed using cyclic etching is shown in FIG. 5a to FIG. 5d. Example of initial substrate is shown in FIG. 5a, consisting of a substrate 702 having multiple thin films on top of it where film 704 works as a mask, films 706. 708 and 710 are films of non-etching materials and film 712 is a film of an etching target material. The substrate after the first step of the etching cycle is presented on FIG. 5b. During the first step, the material was partially removed 716 using selective etching recipe, resulting in deposition of polymer 714 on non-etching materials and mask with polymer thickness depending on the material of the film. The substrate after the second step of the cycle is presented in FIG. 5c. For the second step, an etching recipe with not infinite selectivity to the polymer deposited during the first step was used resulting in further etching of the etching target material 718 and removing of the polymer from non-etching material. Depending on the non-etching material and conditions of the process some polymer may remain on the non-etching material films 720 or some of non-etching material films may be etched during the second step after complete removal of the polymer (not shown), as it shown in FIG. 5d.

The disclosed methods of cyclic selective plasma dry etching of silicon-containing films include etching of particular materials, e.g. Si-containing films including silicon nitride, silicon oxide, and a-C selectively to any other materials used in fabrication of semiconductor device at certain level (e.g. front end of line or middle end of line) using a mixed gas of at least one Si-containing hydrofluorocarbon, optionally inert gas, oxidizing gas and fluorocarbon and/or hydrofluorocarbon as an etching gas while etching process further contains several steps with variable etching recipes repeated in a cyclic way. Use of cyclic etching process consisting of several steps allows achieving high or infinite values of selectivity while depositing insignificant amount of polymer or just forming thin film interface on surface of non-etching materials.

The disclosed cyclic plasma etching methods may achieve preferential etching of Si-containing compound with high selectivity to other materials such as mask materials and non-etching materials while not modifying non-etching materials.

In the disclosed cyclic plasma etching method, a plasma etching gas is a gas mixture including at least one of the following substances: a Si-containing hydrofluorocarbon, an inert gas, an oxidizing agent, a fluorocarbon and/or hydrofluorocarbon, and an additional gas. Once again, the inert gas may be selected from He, Ar, Kr. Xe, Ne; the oxidizing agent may be selected from O₂, O₃, CO, CO₂, COS, SO, SO₂, FNO, NO, N₂O, NO₂, N₂O, Cl₂, F₂; the hydrofluorocarbons or fluorocarbons may be selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇; the additional gas may be selected from H₂, SF₆, NF₃, N₂, NH₃, Cl₂, BCl₃, BF₃, Br₂, F₂, HBr, HCl or combinations thereof. A selectivity of the etching film to the at least one non-etching film may be larger than 5, preferably, larger than 10.

In summary, in the disclosed plasma dry etching methods described above, an etching gas mixture includes at least one disclosed Si-containing hydrofluorocarbon compounds. In addition, at least one hydrofluorocarbon or fluorocarbon gases, at least one oxidizing gases, at least one inert gas, and/or at least one additional gas may be added to the disclosed Si-containing hydrofluorocarbon compounds forming the etching gas mixture before etching. In some embodiments, the at least one hydrofluorocarbon or fluorocarbon gases, at least one oxidizing gases, at least one inert gas, and/or at least one additional gas may be optional. For example, in the disclosed plasma etching methods of selective plasma dry etching organic films, at least one hydrofluorocarbon or fluorocarbon gases is optional and may or may not be included in the etching gas mixture.

Under the plasma condition, various reactive species and ions are generated directly by dissociation of these compounds and chemical reactions through interaction between species presented in the gas phase. Typically, plasma etching effect could be achieved with any of compounds represented by above mentioned compounds, when the above mentioned compounds are used individually or mixed with each other. Depending on the structure of individual compound, it may promote either etching performance (including increase of etching speed of particular etching target material) or passivation during high aspect ratio etching process. In particular, a mixture of C₄F₆ and C₄F₈ is one of commonly used mixtures because C₄F₈ is efficient for promotion of passivation and C₄F₈ is efficient for increase of etching speed, resulting in a high anisotropy of etching processes as discussed in the Comparative Example 6 that follows. Furthermore, hydrofluorocarbon gas such as CH₂F₂ may be added to increase the etching speed of silicon nitride film if it is desired.

Other gases such as an inert gas or an oxidizing gas may be added to the etching gas mixture. Using an inert gas is to increase ion bombardment during the etching process and depending on gas ratio promotes or suppresses dissociation of other gases in the etching gas mixture, which causes direct impact on etching speed and anisotropy of the etching process. Furthermore, an addition of the oxidizing gas to the etching gas mixture allows increasing the etching speed, depending on the etching gas mixture and type of target and non-etching materials isotropy and selectivity of the etching process. Furthermore, an additional gas selected from H₂, SF₆, NF₃, N₂, NH₃, Cl₂, BCl₃, BF₃, Br₂, F₂, HBr, HCl or combinations thereof may be added to the etching gas mixture in order to improve control of process or increase etch rate.

The disclosed etching gas mixtures are suitable for plasma etching semiconductor structures, such as, channel holes, gate trenches, staircase contacts, slits, capacitor holes, contact holes, self-aligned contact, self-aligned vias, super vias etc., in the silicon-containing films. The disclosed etching gas mixtures are not only compatible with currently available mask materials but also compatible with the future generations of mask materials because the disclosed Si-containing etching compounds induce little to no damage on the mask along with good profile of high aspect ratio structures. In other words, the disclosed etching gas mixtures may produce vertical etched patterns having minimal to no bowing, pattern collapse, or roughness. In order to achieve these properties, the disclosed etching gas mixtures may deposit an etch-resistant polymer layer during etching to help reduce the direct impact of the oxygen and fluorine radicals during the etching process. The disclosed etching gas mixtures may also reduce damage to p-Si or crystalline Si channel structure during etching.

Material compatibility tests are important to determine if any of the disclosed etching gas mixtures will react with chamber materials and degrade the performance of the chamber with short term or long-term use. Key materials involved in parts of the chamber, valves, etc. include stainless steel, aluminum, nickel, PCTFE, PVDF, PTFE, PFA, PP, kalrez, viton and other metals and polymers. At times these materials are exposed to high temperatures, for example, higher than 20° C., and high pressures, for example, higher than 1 atm, which may enhance their degradation. The metrology methods may include visual inspection, weight measurement, measuring nanometer scale changes in scanning electron microscopy (SEM), tensile strength, hardness, etc.

The disclosed etching gas mixtures may be used to plasma etch silicon-containing films on a substrate. The disclosed plasma etching method may be useful in the manufacture of semiconductor devices such as NAND or 3D NAND gates or Flash or DRAM memory capacitors or transistors such as fin-shaped field-effect transistor (FinFET). Gate All Around (GAA)-FET, Nanowire-FET, Nanosheet-FET, Forksheet-FET, Complementary FET (CFET), Bulk complementary metal-oxide-semiconductor (Bulk CMOS), MOSFET, fully depleted silicon-on-insulator (FD-SOI) structures. The disclosed etching gas mixtures may be used in other areas of applications, such as different front end of the line (FEOL) and back end of the line (BEOL) etch applications such as metal films patterning, formation of metal interconnects, buried power lines and signal lines. Additionally, the disclosed etching gas mixtures may also be used for etching Si in 3D through silicon via (TSV) etch applications for interconnecting memory to logic on a substrate and in MEMS applications.

The disclosed plasma etching method includes providing a reaction chamber having a substrate disposed therein. The reaction chamber may be any enclosure or chamber within a device in which etching methods take place such as, and without limitation, reactive ion etching (RIE), capacitively coupled plasma (CCP) with single or multiple frequency RF sources, inductively coupled plasma (ICP), or microwave plasma reactors, or other types of etching systems capable of selectively removing a portion of the silicon-containing film or generating active species. One of ordinary skill in the art will recognize that the different plasma reaction chamber designs provide different electron density and temperature control. Suitable commercially available plasma reaction chambers include but are not limited to the Applied Materials magnetically enhanced reactive ion etcher sold under the trademark eMAX™ or the Lam Research Dual CCP reactive ion etcher dielectric etch product family sold under the trademark 2300® Flex™. The RF power in such may be pulsed to control plasma properties and thereby improving the etch performance (selectivity and damage) further.

In the disclosed plasma etching method, the plasma etching chamber is equipped with parallel plate electrodes plasma generators where a high frequency electromagnetic field of frequency in range from 2 to 100 MHz is applied to the upper electrode or lower electrode or both electrodes and a low frequency electromagnetic field of frequency in range from 40 KHz to 2 MHz is applied to the lower electrode, when a gap between the electrodes is kept in a range between 10 and 35 mm. A combination of these electric fields allows to apply power to the upper electrode within a range of 0-10,000 W and to the lower electrode within the range of 0-100,000 W. Pressure in the etching chamber during the plasma etching process is kept between 5 and 100 mTorr with introduced the etching gas mixture. Alternatively, plasma-treated reactants of the disclosed etching gas mixtures may be produced outside of a reaction chamber. For example the MKS Instruments' ASTRONI® reactive gas generator or the like may be used to treat the reactants prior to passage into the reaction chamber. For example, operated at 2.45 GHz, 7 KW plasma power, and a pressure ranging from approximately 0.5 Torr to approximately 10 Torr, the reactant O₂ may be decomposed into two O′ radicals. Preferably, the remote plasma may be generated with a power ranging from about 1 KW to about 10 KW, more preferably from about 2.5 KW to about 7.5 KW. The reaction chamber may contain one or more than one substrate. For example, the reaction chamber may contain from 1 to 200 silicon wafers having from 25.4 mm to 450 mm diameters. The substrates may be any suitable substrates used in semiconductor, photovoltaic, flat panel or LCD-TFT device manufacturing. Examples of suitable substrates include wafers, such as silicon, silica, glass, Ge, SiGe, GeSn, InGaAs, GaSb, InP, or GaAs wafers. The wafer will have multiple films or layers on it from previous manufacturing steps, including silicon-containing films or layers. The layers may or may not be patterned. Examples of suitable layers include without limitation silicon (such as amorphous silicon, p-Si, crystalline silicon, any of which may further be p-doped or n-doped with B, C, P, As, Ga, In, Sn, Sb, Bi and/or Ge), silica, silicon nitride, silicon oxide, silicon oxynitride, SiₐO_{b}H_{c}C_{d}Nₑ, (wherein a>0; b, c, d, e≥0), Ge, SiGe, GeSn, InGaAs, GaSb, InP; mask layer materials such as amorphous carbon with or without dopants, antireflective coatings, photoresist materials, a metal oxide, such as AlO, TiO, HfO, ZrO, SnO, TaO etc. or a metal nitride layer such as AIN, ZrN, SnN, HfN, titanium nitride, tantalum nitride etc. or combinations thereof; etch stop layer materials such as SiₐO_{b}H_{c}C_{d}Nₑ, (wherein a>0; b, c, d, e≥0) selected from silicon nitride, polysilicon, crystalline silicon, silicon carbide, SiON, SiCN or combinations thereof, or device channel materials such crystalline silicon, epitaxial silicon, doped silicon, or combinations thereof. The silicon oxide layer may form a dielectric material, such as an organic based or silicon oxide based low-k dielectric material (e.g., a porous SiCOH film). An exemplary low-k dielectric material is sold by Applied Materials under the trade name Black Diamond II or III. Additionally, layers comprising tungsten, cobalt, copper or noble metals (e.g. platinum, palladium, rhodium or gold) may be used. Furthermore, examples of the silicon-containing films may be SiₐO_{b}H_{c}C_{d}Nₑ, (wherein a>0; b, c, d, e≥0). Throughout the specification and claims, the wafer and any associated layers thereon are referred to as substrates.

The vapor of the disclosed etching gas mixture is introduced into the reaction chamber containing the substrate having silicon-containing films deposited thereon. The vapor of the disclosed etching gas mixture or the vapor of each component in the disclosed etching gas mixture may be introduced to the chamber at a flow rate ranging from approximately 0.1 sccm to approximately 1 sim. For example, for a 300 mm wafer size, the vapor may be introduced to the chamber at a flow rate ranging from approximately 1 sccm to approximately 50 sccm. Alternatively, for a 450 mm wafer size, the vapor may be introduced to the chamber at a flow rate ranging from approximately 25 sccm to approximately 250 sccm. One of ordinary skill in the art will recognize that the flow rate may vary from tool to tool. The disclosed Si-containing hydrofluorocarbon etching compounds and the hydrofluorocarbon or fluorocarbon compounds may be supplied either in neat form or in a blend with an inert gas, such as N₂, Ar, Kr, Ne He, Xe, etc., or solvent. The disclosed Si-containing hydrofluorocarbon etching compounds and the hydrofluorocarbon or fluorocarbon compounds may be present in varying concentrations in the blend. For liquid Si-containing hydrofluorocarbon etching compounds and the hydrofluorocarbon or fluorocarbon compounds, the vapor form of the Si-containing hydrofluorocarbon etching compounds and the hydrofluorocarbon or fluorocarbon compounds may be produced by vaporizing the neat or blended Si-containing hydrofluorocarbon etching compound solution and the hydrofluorocarbon or fluorocarbon compound solution through a conventional vaporization step such as direct vaporization or by bubbling. The neat or blended Si-containing hydrofluorocarbon etching compounds and the neat or blended hydrofluorocarbon or fluorocarbon compounds may be fed in liquid state to a vaporizer where it is vaporized before it is introduced into the reactor.

Alternatively, the neat or blended Si-containing hydrofluorocarbon etching compounds may be vaporized by passing a carrier gas into a container containing the disclosed Si-containing hydrofluorocarbon etching compounds and the hydrofluorocarbon or fluorocarbon compounds or by bubbling the carrier gas into the disclosed Si-containing hydrofluorocarbon etching compounds and the hydrofluorocarbon or fluorocarbon compounds. The carrier gas may include, but is not limited to, Ar, He, N₂, Kr, Xe, Ne and mixtures thereof. Bubbling with a carrier gas may also remove any dissolved oxygen present in the neat or blended Si-containing hydrofluorocarbon etching compound solution and the hydrofluorocarbon or fluorocarbon compound solution. The carrier gas and disclosed Si-containing hydrofluorocarbon etching compounds are then introduced into the reactor as a vapor.

If necessary, a container containing the disclosed Si-containing hydrofluorocarbon etching compounds may be heated to a temperature that permits the Si-containing hydrofluorocarbon etching compounds to be in liquid phase and to have a sufficient vapor pressure for delivery into an etching tool. The container may be maintained at temperatures in the range of, for example, approximately 0° C. to approximately 150° C., preferably from approximately room temperature to approximately 100° C., more preferably from approximately room temperature to approximately 50° C. More preferably, the container is maintained at room temperature in order to avoid heating lines to an etch tool. Those skilled in the art recognize that the temperature of the container may be adjusted in a known manner to control the amount of Si-containing hydrofluorocarbon etching compounds vaporized.

For 3D NAND applications, plasma activated vapor of the disclosed etching gas mixture or the disclosed plasma activated etching gas preferably exhibits high selectivity toward the mask and etches through the alternating layers of SiO and SiN or alternating layers of polysilicon and SiO₂ resulting in a vertical etch profile with no profile distortion (such as bowing or roughness), which is important for 3D NAND applications. Additionally, the plasma activated vapor deposits polymer on sidewall to minimize feature profile deformation. For other applications, such as DRAM and 2D NAND, for example, the plasma activated vapor of the disclosed etching gas mixture under different process conditions may selectively etch SiO from SiN. The disclosed plasma activated etching gas may selectively etch SiO and/or SiN from mask layers, such as a-C, photoresist, a-Si, p-Si, or silicon carbide; or from metal contact layers, such as Cu, W, Ru, etc.; or from channel regions consisting of SiGe or polysilicon regions. The disclosed plasma activated etching gas may selectively etch organic films from other films, such as a-C, photoresist, a-Si, p-Si, or silicon carbide; or from metal contact layers, such as Cu, W, Ru, etc.; or from channel regions consisting of SiGe or polysilicon regions.

The disclosed activated etching gas mixture (e.g., through igniting a plasma of the etching gas mixture) including Si-containing hydrofluorocarbon etching gas reacts with the silicon-containing films deposited on the substrate to form volatile by-products that are removed from the reaction chamber. The a-C mask, antireflective coating, and photoresist layer on the substrate are less reactive with the activated etching gas. Thus, the activated etching gas selectively reacts with the silicon-containing films to form volatile by-products.

Alternatively, the disclosed activated etching gas mixture (e.g., through igniting a plasma of the etching gas mixture) including Si-containing hydrofluorocarbon etching gas reacts with organic films deposited on the substrate to form volatile by-products that are removed from the reaction chamber. In this case, with varying processes and different etching conditions, the organic films, such as a-C mask, are more reactive with the activated etching gas. Thus, the activated etching gas selectively reacts with the organic films to form volatile by-products.

Temperature and pressure within the reaction chamber are held at conditions suitable for the silicon-containing film to react with the activated etching gas. For instance, the pressure in the chamber may be held between approximately 0.1 mTorr and approximately 1000 Torr, preferably between approximately 1 mTorr and approximately 10 Torr, more preferably between approximately 10 mTorr and approximately 1 Torr, and more preferably between approximately 10 mTorr and approximately 100 mTorr, as required by the etching parameters. Likewise, substrate temperature in the chamber may range between about approximately −196° C. to approximately 500° C., preferably between approximately −120° C. to approximately 300° C., more preferably between approximately −100° C. to approximately 50° C.; and more preferably between approximately −70° C. to approximately 40° C. Chamber wall temperatures may range from approximately −196° C. to approximately 300° C. depending on the process requirements.

Alternatively, the temperature and the pressure within the reaction chamber are held at conditions suitable for the organic film to react with the activated etching gas. For instance, the pressure in the chamber may be held between approximately 0.1 mTorr and approximately 1000 Torr, preferably between approximately 1 mTorr and approximately 10 Torr, more preferably between approximately 10 mTorr and approximately 1 Torr, and more preferably between approximately 10 mTorr and approximately 100 mTorr, as required by the etching parameters. Likewise, the substrate temperature in the chamber may range between about approximately −196° C. to approximately 500° C., preferably between approximately −120° C. to approximately 300° C., more preferably between approximately −100° C. to approximately 50° C., and more preferably between approximately −70° C. to approximately 40° C. Chamber wall temperatures may range from approximately −196° C. to approximately 300° C. depending on the process requirements.

The reactions, between the silicon-containing film and the activated etching gas, and between the organic films and the activated etching gas, result in anisotropic removal of the silicon-containing films and the organic films from the substrate depending on process parameters. Atoms of nitrogen, oxygen, and/or carbon may also be present in the silicon-containing films and organic films. The removal is due to a physical sputtering of silicon-containing films and organic films from plasma ions (accelerated by the plasma) and/or by chemical reaction of plasma species to convert Si to volatile species, such as SiFₓ, wherein x ranges from 1-4.

The disclosed plasma etch methods using the disclosed Si-containing hydrofluorocarbon compounds as etching gas produce apertures, such as channel holes, gate trenches, staircase contacts, capacitor holes, contact holes, contact etch, slit etch, self-aligned contact, self-aligned vias, super vias etc., in the silicon-containing films. The resulting apertures may have an aspect ratio ranging from approximately 5:1 to approximately 500:1, preferably approximately 20:1 to approximately 400:1, and a diameter ranging from approximately 5 nm to approximately 500 nm, preferably less than 100 nm. For example, one of ordinary skill in the art will recognize that a channel hole etch produces apertures in the silicon-containing films having an aspect ratio greater than 50:1.

Typical materials that need to be etched may be SiO. A process of etching SiO may be relevant to etching trenches in Borophosphosilicateglass (BPSG), Tetraethylorthosilicate (TEOS), or low deposition rate TEOS (LDTEOS). An etch stop layer may be silicon nitride or silicon oxygen nitride (SiON) or poly silicon or metal or metal nitride (e.g. W or TiN). A mask material used may be a-C, p-Si, amorphous silicon B-doped a-C, W-doped a-C, B-doped amorphous silicon, or photo resist materials. Herein, the disclosed Si-containing hydrofluorocarbon etching compounds are applied to etch SiO, SiN, p-Si and/or a-C substrate films.

The disclosed etching methods are not limited to above stated experimental conditions in any way and type of plasma etching tool (capacity coupled or inductively coupled plasma), process conditions (pressure, power, temperature, duration of process), process gas mixture, combination and proportion of gases in the gas mixture, gas flow, workpiece or substrate and plasma etching chamber itself may be altered for each process and during the process.

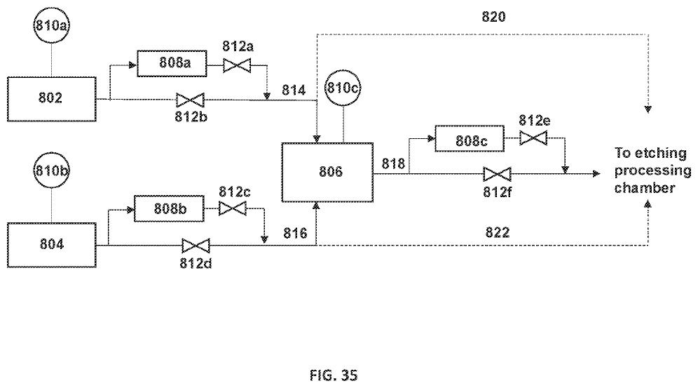

The disclosed also includes etching gas delivery systems. FIG. 35 shows an exemplary etching gas delivery apparatus or system. As shown, two fluidic conduits 814 and 816 connect first etchant source 802 and second etchant source 804 to common fluidic conduit 818, respectively. First etchant source 802 contains the first etchant and second etchant source 804 contains the second etchant. Thermal elements 810a, 810b and 810c are connected to first etchant source 802, second etchant source 804 and gas mixer 806, respectively, which are configured for and adapted to regulate the temperature of the first etchant, the second etchant and/or a mixture of the first and second etchants thereof. Optionally, vaporizer elements 808a, 808b and 808c are fluidically connected to one or more of the at least two fluidic conduits 814 and 816 and/or common fluidic conduit 818. Vaporizer elements 808a, 808b and 808c are configured for and adapted to produce a vapor of the first etchant, the second etchant and/or the mixture thereof, respectively. Mixing element 806 is optionally connected to two fluidic conduits 814 and 816 and common fluidic conduit 818. Mixing element 806 is configured for and adapted to mix the first etchant and the second etchant. Valves 812a, 821b, 812c, 812d, 812e, and 812f are installed in conduits 814, 816, 818, vapor elements 808a, 808b and 808c to control the usage of vapor elements 808a, 808b and 808c. If vapor elements 808a, 808b and 808c are not used, valves 812a, 812c and 812e are shut off; valves 812b, 812d and 812f are turned on; vice versa.

Here, a programmable logic controller (PLC) (not shown) may installed to the system and is configured for and adapted to control all elements, valves, gas sources, and the like in the apparatus. The etching gas delivery apparatus is specifically adapted to regulate the flow of the first etchant and the second etchant to form the etching gas composition having a predefined ratio of the first etchant and the second etchant based on a chemical formula of the first etchant and the second etchant. The first etchant and the second etchant may or may not be mixed before introducing into an etching processing chamber or a reactor. The first etchant and the second etchant may be mixed in mixing element 806 before introducing into an etching processing chamber or a reactor. The first etchant and the second etchant may be independently introduced into an etching processing chamber or a reactor and mixed therein. The dashed lines 820 and 822 show the first etchant and the second etchant are directly introduced into an etching processing chamber or a reactor without mixing, respectively. In some embodiments, the first etchant is a disclosed Si-containing hydrofluorocarbon and a container of the first etchant may operatively be connected to a device used for semiconductor etching process(es).

In some embodiments, the second enchant may be an inert gas selected from Ar, Kr, Xe, N₂, He, Ne or combination thereof, an oxidizer or an oxidizing gas selected from O₂, O₃, CO, CO₂, COS, SO, SO₂, FNO, NO, N₂O, NO₂, H₂O, N₂O, Cl₂, F₂, or the like, or an additional gas selected from H₂, SF₆, NF₃, N₂, NH₃, Cl₂, BCl₃, BF₃, Br₂, F₂, HBr, HCl or combinations thereof. In addition, the etching gas delivery apparatus shown in FIG. 35 is not limited to first and second etchant sources 802 and 804, one or more etchant sources may be added parallel to first and second etchant sources 802 and 804 and mixed in mixing element 806 mixing with the first and second etchants. For example, if the disclosed etching gas mixture comprises a Si-containing hydrofluorocarbon, an inert gas, an oxidizer and an addition gas, four etchant sources will be installed in the etching gas delivery apparatus.

### EXAMPLES

A detailed description of the present disclosure through examples and comparative examples is provided as follows to further illustrate embodiments of the invention. However, the present disclosure is not limited to presented examples in any way, and etching conditions, etching gas mixture, combination and proportion of gases or vapors in the etching gas mixture, substrate and plasma etching chamber itself may vary.

Examples 1-11 and Comparative Examples 1-6 have the following conditions.

Plasma etching device: In the disclosed methods, parallel plate (capacity coupled plasma) plasma generator was used as the plasma etching device. The parallel plate configuration included upper electrode and lower electrode, on which a substrate was placed (lower electrode was used as sample holder with cooling capability). The separation between the electrodes was either 13 or 30 mm. Upper electrode was connecter either to 27 MHz or 60 MHz generator when lower electrode was connected to 2 MHz generator.

Plasma etching condition: During the plasma etching process power supplied to the upper electrode was varied in range from 500 to 2000 W, when power applied to the lower electrode was varied in range from 750 to 7000 W. Pressure was maintained constant during the process in a range between 5 and 100 mTorr. The plasma etching time was set at value between 30 and 300 seconds. Etch rate was estimated in nanometers per minute. Plasma etching gas mixture included Ar, O₂, C₄F₆ and/or C₄F₈ used as a fluorocarbon gas and C₂H₆F₂Si or CH₃F₃Si, C₄H₉F₃Si or C₅H₉F₅Si used as a Si-containing hydrofluorocarbon gas and optionally included CH₂F₂ used as a hydrofluorocarbon gas.

Substrate: The substrates used in Examples 1-11 and Comparative Examples 1-6 were shown in FIG. 2a-2b. The substrates in Examples 5-7 were a piece of monocrystalline silicon wafer with thin film of one of materials from the following list on top of silicon wafer: SiO₂, Si₃N₄, amorphous carbon (hereafter “a-C”), W, Ru, Co, Mo, TiN, TiO₂.

Plasma etching profile and selectivity: As a criteria for comparison of high aspect ratio etching performance of the disclosed plasma etching process and reference plasma etching processes using a typical etching gas mixture, e.g., a mixture of Ar, O₂, C₄F₆ and/or C₄F₈, selectivity, top CD, middle CD and bottom CD were chosen, since they are reflecting control of an etched pattern profile. Selectivity has been calculated as the ratio of silicon dioxide etching depth (arrow 8 on FIG. 2b) to difference between thickness of initial amorphous carbon mask (arrow 5 on FIG. 2a, 868 nm) to thickness of mask after the etching process (arrow 7 on FIG. 2b). In the event when negative value of selectivity has been obtained, that is, when thickness of amorphous carbon mask has been increased after the etching process, this condition has been referred as condition with “infinite selectivity”, meaning that thickness of mask was increasing because of polymer deposition during the etching process. In the event when the width of the etched hole in SiO₂ was increased comparing to top CD at certain depth, bow CD may be used instead of middle CD. Bow CD represents widest area in the etched hole in SiO₂ film. Additionally, neck CD (which is smallest width of the a-C mask hole) can be used as a measure if hole diameter in a-C mask is shrunk due to deposition of polymer on mask during etching process.

During comparison, higher value of selectivity or infinite selectivity was targeted, when neck CD, top CD, bottom CD, bow CD and middle CD were targeted to be as close as possible to the value of diameter of bottom of opening in the amorphous carbon mask (120 nm, arrow 3 on FIG. 2a).

### Example 1

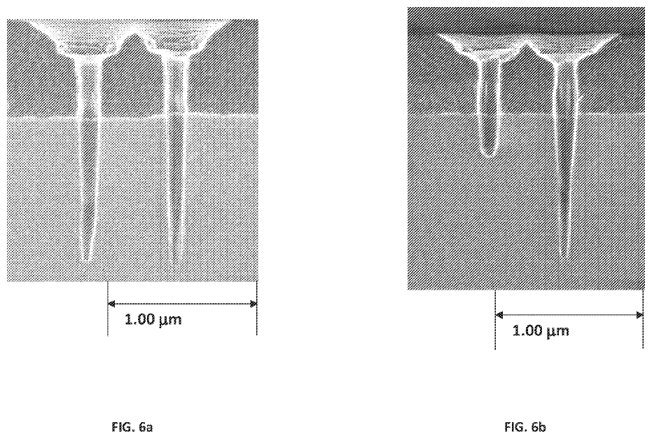

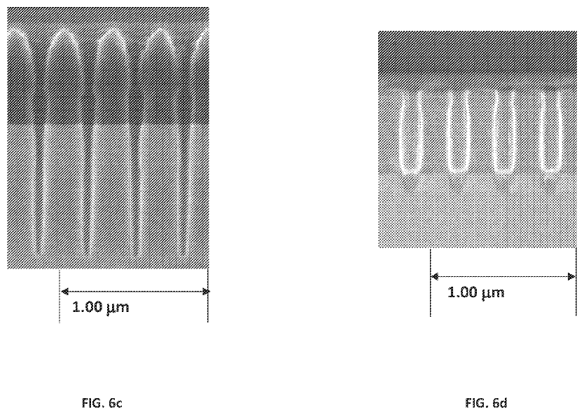

Plasma etching was performed in a plasma etching chamber where a power of 750 W was applied to the top electrode at frequency of 27 MHz, a power of 1500 W was applied to the bottom electrode at a frequency of the 2 MHz, a pressure in chamber was maintained at 30 mTorr and a gap between the electrodes was set at 13 mm. An etching gas mixture including following flows of gases was introduced to the plasma etching chamber: 150 sccm of Ar, 12 sccm of C₄F₈, 12 sccm of O₂ and 1.2 sccm of C₅H₉F₅Si. Plasma etching process was carried out for 2 minutes. Resulting structure of a cross-section of the substrate after the plasma etching process is shown on FIG. 6a and parameters for comparison are summarized at Table 2.

TABLE 2

| | | | | | | Measured values | | | | |
|---|---|---|---|---|---|---|---|---|---|---|
| | | | | | | | Top | Middle | Bottom | |
| | Process gas mixture (flow rate, sccm) | | | | | | CD | CD | CD | Etch rate |
| | Ar | O₂ | C₄F₆ | C₄F₈ | C₅H₉F₅Si | selectivity | (nm) | (nm) | (nm) | (nm/min) |
| Ex 1 | 150 | 12 | 0 | 12 | 1.2 | 13 | 117 | 95 | 65 | 610 |
| Com ex 1 | 150 | 12 | 0 | 12 | 0 | 7 | 151 | 130 | 70 | 630 |
| Ex 2 | 75 | 10 | 15 | 0 | 0.6 | ∞ | 102 | 80 | 65 | 600 |
| Com ex 2 | 75 | 10 | 15 | 0 | 0 | N.A | 130 | N.A. | N.A. | 0 |
| | | | | | | | Top | Middle | Bottom | |
| | | | | | | | CD | CD | CD | Etch rate |
| | Ar | O₂ | C₄F₆ | C₄F₈ | C₄H₉F₃Si | selectivity | (nm) | (nm) | (nm) | (nm/min) |
| Ex 3 | 150 | 30 | 0 | 60 | 5 | ∞ | 121 | 116 | 80 | 545 |
| Com ex 3 | 150 | 30 | 0 | 60 | 0 | 5.1 | 145 | 140 | 90 | 685 |
| Com ex 4 | 150 | 30 | 5 | 60 | 0 | 17 | 135 | 130 | 65 | 680 |
| Ex 4 | 150 | 35 | 0 | 60 | 5 | 10.5 | 151 | 155 | 105 | 460 |
| Com ex 5 | 150 | 30 | 0 | 60 | 0 | <3.3 | 220 | 230 | 200 | 586 |
| Com ex 6 | 150 | 30 | 5 | 60 | 0 | 4 | 250 | 175 | 160 | 594 |

### Example 2

Plasma etching was performed in the same way as in Example 1, with exception that process gas mixture was replaced by the following: 75 sccm of Ar, 15 sccm of C₄F₆, 10 sccm of O₂ and 0.6 sccm of C₅H₉F₅Si. Resulting structure of a cross-section of the substrate after the etching process is shown on FIG. 6c and parameters for comparison are summarized at Table 2.

### Example 3

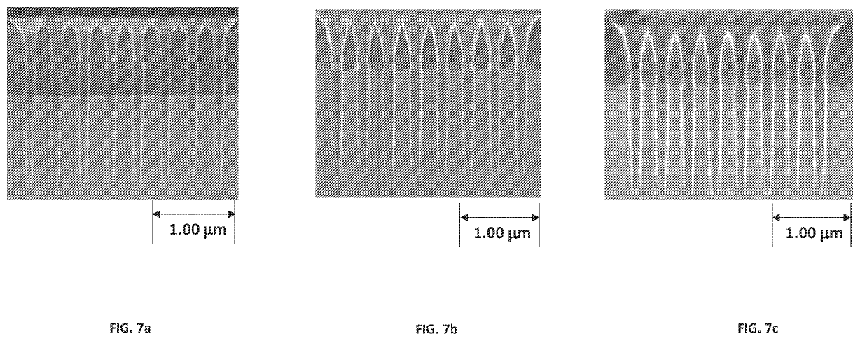

Plasma etching was performed in a plasma etching device where power of 1000 W was applied to the top electrode at frequency of 60 MHz, power of 7000 W was applied to the bottom electrode at a frequency of the 2 MHz, pressure in chamber was maintained at 20 mTorr and gap between the electrodes was set at 20 mm. Process gas mixture including following flows of gases was introduced to the plasma etching chamber: 150 sccm of Ar, 60 sccm of C₄F₈, 30 sccm of O₂ and 5 sccm of C₄H₉F₃Si. Plasma etching process was carried for 2 minutes. Resulting structure of a cross-section of the substrate after the etching process is shown on FIG. 7a and parameters for comparison are summarized at Table 2.

### Example 4

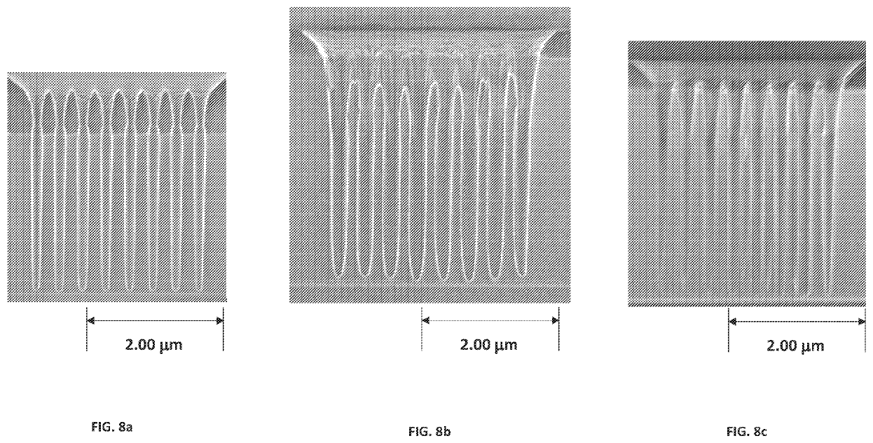

Plasma etching was performed in a plasma etching device where power of 1000 W was applied to the top electrode at frequency of 60 MHz, power of 7000 W was applied to the bottom electrode at a frequency of the 2 MHz, pressure in chamber was maintained at 20 mTorr and gap between the electrodes was set at 20 mm. Process gas mixture including following flows of gases was introduced to the plasma etching chamber: 150 sccm of Ar, 60 sccm of C₄F₈, 35 sccm of O₂ and 5 sccm of C₄H₉F₃Si. Plasma etching process was carried for 5 minutes. Resulting structure of a cross-section of the substrate after the etching process is shown on FIG. 8a and parameters for comparison are summarized at Table 3.

### Example 5

Plasma etching was performed in a plasma etching device where power of 1000 W was applied to the top electrode at frequency of 60 MHz, power of 7000 W was applied to the bottom electrode at a frequency of the 2 MHz, pressure in chamber was maintained at 20 mTorr and gap between the electrodes was set at 20 mm. Process gas mixture including following flows of gases was introduced to the plasma etching chamber: 150 sccm of Ar, 60 sccm of C₄F₈, 30 sccm of O₂ and 5 sccm of C₄H₉F₃Si. Plasma etching process was carried for 30 seconds. Etch rate for each studied material is summarized in Table 3.

TABLE 3

| | Process gas mixture (flow rate, sccm) | | | | | Measured etch rate (nm/min) | | | | | | | | |
|---|---|---|---|---|---|---|---|---|---|---|---|---|---|---|
| | Ar | O₂ | C₄F₈ | C₄H₉F₃Si | CH₂F₂ | SiO₂ | Si₃N₄ | a-C | poly-Si | W | Ru | Co | TiN | TiO₂ |
| Ex 5 | 150 | 30 | 60 | 5 | 0 | 410 | 10 | 0 | 0 | 0 | 0 | 10 | 116 | 126 |
| Ex 6 | 150 | 30 | 40 | 5 | 20 | 376 | 50 | 0 | 0 | 0 | 0 | 0 | — | 138 |
| Ex 7 | 150 | 30 | 30 | 5 | 30 | 506 | 300 | 0 | 0 | 0 | 0 | 0 | 60 | — |

### Example 6

Plasma etching was performed in the same way as in Example 5, with exception that process gas mixture was replaced by the following: 150 sccm of Ar, 40 sccm of C₄F₈, 20 sccm of CH₂F₂, 30 sccm of O₂ and 5 sccm of C₄H₉F₃Si. Plasma etching process was carried for 30 seconds. Etch rate for each studied material is summarized in Table 3.

### Example 7

Plasma etching was performed in the same way as in Example 5, with exception that process gas mixture was replaced by the following: 150 sccm of Ar, 30 sccm of C₄F₈, 30 sccm of CH₂F₂, 30 sccm of O₂ and 5 sccm of C₄H₉F₃Si. Plasma etching process was carried for 30 seconds. Etch rate for each studied material is summarized in Table 3.

### Comparative Example 1

Plasma etching was performed in the same way as in Example 1, with exception that C₅H₉F₅Si was not added to the process gas mixture. Resulting structure of a cross-section of the substrate after the etching process is shown on FIG. 6b and parameters for comparison are summarized at Table 2.

### Comparative Example 2

Plasma etching was performed in the same way as in Example 2, with exception that C₅H₉F₅Si was not added to the process gas mixture. Resulting structure of a cross-section of the substrate after the etching process is shown on FIG. 6d and parameters for comparison are summarized at Table 2.

### Comparative Example 3

Plasma etching was performed in the same way as in Example 3, with exception that C₄H₉F₃Si was not added to the process gas mixture. Resulting structure of a cross-section of the substrate after the etching process is shown on FIG. 7b and parameters for comparison are summarized at Table 2.

### Comparative Example 4

Plasma etching was performed in the same way as in Example 3, with exception that 5 sccm flow of C₄H₉F₃Si was replaced by 5 sccm flow of C₄F₆. Resulting structure of a cross-section of the substrate after the etching is shown on FIG. 7c and parameters for comparison are summarized at Table 2.

### Comparative Example 5

Plasma etching was performed in the same way as in Example 4, with exception that C₄H₉F₃Si was not added to the process gas mixture. Resulting structure of a cross-section of the substrate after the etching process is shown on FIG. 8b and parameters for comparison are summarized at Table 2.

### Comparative Example 6

Plasma etching was performed in the same way as in Example 4, with exception that 5 sccm flow of C₄H₉F₃Si was replaced by 5 sccm flow of C₄F₆. Resulting structure of a cross-section of the substrate after the etching process is shown on FIG. 8c and parameters for comparison are summarized at Table 2. It is clearly shown in Table 2 that in all of the studied conditions addition of 0.6-1.2 sccm of C₅H₉F₅Si or 5 sccm of C₄H₉F₃Si allows to improve most of criteria for comparison. For instance, selectivity was improved and top CD was closer to initial value for all examples where Si-containing hydrofluorocarbon was added to the process gas mixture.

Specifically, in Example 1, where 1.3 sccm of C₅H₉F₅Si was added to the working gas mixture of Ar, O₂ and C₄F₈ selectivity to the mask material was 13, which is much higher comparing to Comparative Example 1 where under the same conditions without C₅H₉F₅Si value of selectivity was 7, which is almost twice lower. In Examples 2 and 3, where 0.6 sccm of C₅H₉F₅Si or 5 sccm of C₄H₉F₃Si was added to the process gas mixture of Ar, O₂ and C₄F₆ or C₄F₈ respectively. selectivity to the mask material was infinite (thickness of mask increased after the process), when in Comparative Examples 2, 3 and 4 where under the same conditions without Si-containing hydrofluorocarbon, or when Si-containing hydrofluorocarbon was replaced by C₄F₆, value of selectivity was in range from 5 to 20 and which is significantly lower. Moreover, as it can be observed at scanning electron microscopy cross section images of substrates, in the case of Comparative Example 2 plasma etching target material was not etched due to excessive passivation (FIG. 6d), when in the case of Comparative Example 1 etching of the plasma etch target material was occasionally interrupted and stopped (FIG. 6b) also due to excessive passivation. This clearly demonstrates that fluorocarbon fragments (e.g., C₂F₄) produced by dissociation of initial Si-containing hydrofluorocarbon can enhance etching process as well and achieve acceptable etching profile (e.g., Example 2) when under the same conditions without Si-containing hydrofluorocarbon etching process of target material is not possible (e.g., Comparative Example 2).

Most crucial comparative criteria which indicating etching profile control capability are top and middle CD, since they both are directly affecting etching profile at higher depth. Bottom CD is important but less crucial criteria, since profile distortions such as tapering at bottom could be fixed by over etching (continue of etching process after reaching desired depth or stop layer), when in comparison expansion or clogging in top CD is irreversible. From Table 2 it may be clearly observed that in case of addition of Si-containing hydrofluorocarbon (C₄H₉F₃Si or C₅H₉F₅Si) to the working gas mixture in examples 1-4, both top and middle CD are closer or identical to initial value of opening in the mask (120 nm, arrow 3 on FIG. 2a), when in Comparative Examples 1-6 where Si-containing hydrofluorocarbon was not used or replaced by C₄F₆, top and middle CD is significantly increased comparing to examples 1-4, which would be unacceptable for semiconductor device fabrication process. Even though, in few cases bottom CD for comparative examples was closer to initial mask opening CD value (120 nm, arrow 3 on FIG. 2a) comparing to Examples 1-4 where Si-containing hydrofluorocarbon was used, it comes in a cost of significant lateral recess of the etched structure at upper part, which cannot be fixed, when shrunk bottom CD may be compensated by over etch.

As it may be observed from Table 3, in the case when 20 or 30 sccm of CH₂F₂ was added to the process gas mixture it was possible to etch not only SiO₂ selectively to a-C and polycrystalline silicon, but also Si₃N₄. Specifically, in Example 7 when 30 sccm of CH₂F₂ was added to the process gas mixture it was possible to etch SiO₂ and Si₃N₄ with comparable etch rate and infinite selectivity to a-C and polycrystalline silicon, which are commonly used as a mask material. Observed results are suggesting that the same process as for high aspect ratio etching of SiO₂ demonstrated in Examples 1-4 could be implemented for high aspect ratio etching of Si₃N₄ or alternating layers of SiO₂ and Si₃N₄ (ONON stack) if CH₂F₂ will be added to the process gas mixture. Moreover, observed infinite selectivity of etching SiO₂ or Si₃N₄ to metal films tested in Examples 5-7 (Ru, Co, Mo, W) indicates that those metals or another metal films (e.g., Al, Pt, Au) may be used as a stop layer for etching process. It means that if metal thin film (e.g. contact pad, buried power rail) exists under target plasma etching material (e.g., SiO₂ or Si₃N₄) high aspect ratio etching process will stop when etched opening with reach metal film and damage to the metal film will be minimized due to infinite selectivity. Additionally etch rate of metal oxide and metal nitride films (TiO₂ and TiN) in Example 7 was considerably smaller comparing to SiO₂ and Si₃N₄ etch rate, meaning that it is possible to achieve soft landing on metal oxide or nitride film as well if etching process is well optimized. This effect may be useful for high aspect ratio contact hole etching or etching of other high aspect ratio structures which will land on metal, metal nitride or oxide film (e.g., 3D NAND channel or DRAM capacitor high aspect ratio etching). From summarizing observations in Examples 1-4 and Comparative Examples 1-6, it may be concluded that addition of Si-containing hydrofluorocarbon, preferably with at least one methyl group attached to Si, and more preferably C₄H₉F₃Si or C₅H₉F₅Si to the process gas mixture allows to improve selectivity and preserve lateral dimensions of the structure during high aspect ratio etching. Additionally, formation of fluorocarbon fragments (such as C₂F₄ observed in the quadrupole mass spectra) during dissociation of Si-containing hydrofluorocarbon can support plasma etching of the material, as it was observed in Examples 1, 2 and Comparative Examples 1, 2. Moreover, as it was demonstrated in Examples 5-7, addition of CH₂F₂ to the process gas mixture is effective to improve etching of Si₃N₄, enabling high aspect ratio etching of Si₃N₄ film or alternating films of SiO₂ and Si₃N₄ while keeping high selectivity to metals.

### Example 8

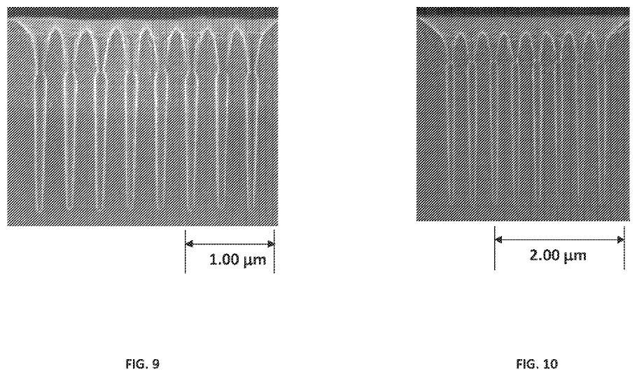

Plasma etching was performed in a plasma etching device where power of 1000 W was applied to the top electrode at frequency of 60 MHz, power of 7000 W was applied to the bottom electrode at a frequency of the 2 MHz, pressure in chamber was maintained at 20 mTorr and gap between the electrodes was set at 20 mm. Process gas mixture including following flows of gases was introduced to the plasma etching chamber: 150 sccm of Ar, 60 sccm of C₄F₈, 30 sccm of O₂ and 5 sccm of C₂H₆F₂Si. Plasma etching process was carried for 2 minutes. Resulting structure of a cross-section of the substrate after the etching process is shown on FIG. 9 and parameters for comparison are summarized at Table 4.

TABLE 4

| | | | | | | Measured values | | | | | |
|---|---|---|---|---|---|---|---|---|---|---|---|
| | | | | | | | Neck | Top | Bow | | Etch |
| | Process gas mixture (flow rate, sccm) | | | | | | CD | CD | CD | Bottom | rate |
| | Ar | O₂ | C₄F₆ | C₄F₈ | C₂H₆F₂Si | selectivity | (nm) | (nm) | (nm) | CD (nm) | (nm/min) |
| Ex 8 | 150 | 30 | 0 | 60 | 5 | ∞ | 78 | 120 | 120 | 70 | 570 |
| Com ex 3 | 150 | 30 | 0 | 60 | 0 | 5.1 | 138 | 145 | 156 | 90 | 685 |
| Com ex 4 | 150 | 30 | 5 | 60 | 0 | 17 | | 135 | 130 | 65 | 680 |
| Ex 9 | 150 | 30 | 0 | 60 | 5 | 18 | 58 | 125 | 125 | 57 | 400 |
| Com ex 5 | 150 | 30 | 0 | 60 | 0 | <3.3 | N.A. | 220 | 230 | 200 | 586 |
| Com ex 6 | 150 | 30 | 5 | 60 | 0 | 4 | N.A. | 250 | 175 | 160 | 594 |
| | | | | | | | Neck | Top | Bow | | Etch |
| | | | | | | | CD | CD | CD | Bottom | rate |
| | Ar | O₂ | C₄F₆ | C₄F₈ | CH₃F₃Si | selectivity | (nm) | (nm) | (nm) | CD (nm) | (nm/min) |
| Ex 10 | 150 | 30 | 0 | 60 | 5 | ∞ | 10 | 129 | 129 | 68 | 635 |
| Com ex 3 | 150 | 30 | 0 | 60 | 0 | 5.1 | 138 | 145 | 140 | 90 | 685 |
| Com ex 4 | 150 | 30 | 5 | 60 | 0 | 17 | | 135 | 130 | 65 | 680 |
| Ex 11 | 150 | 30 | 0 | 60 | 5 | 6 | 78 | 95 | 172 | 68 | 492 |
| Com ex 5 | 150 | 30 | 0 | 60 | 0 | <3.3 | N.A. | 220 | 230 | 200 | 586 |
| Com ex 6 | 150 | 30 | 5 | 60 | 0 | 4 | N.A. | 250 | 175 | 160 | 594 |

### Example 9

Plasma etching was performed in the same way as in Example 8, with exception that plasma etching process was carried for 5 minutes. Resulting structure of a cross-section of the substrate after the etching process is shown on FIG. 10 and parameters for comparison are summarized at Table 4.

### Example 10

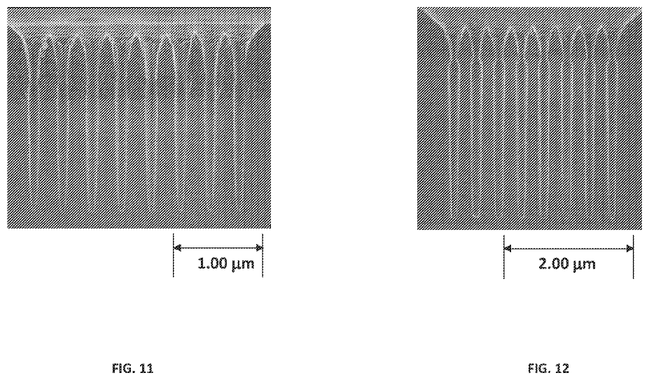

Plasma etching was performed in the same way as in Example 8, with exception that process gas mixture was replaced by the following: 150 sccm of Ar, 60 sccm of C₄F₈, 30 sccm of O₂ and 5 sccm of CH₃F₃Si. Resulting structure of a cross-section of the substrate after the etching process is shown on FIG. 11 and parameters for comparison are summarized at Table 4.

### Example 11

Plasma etching was performed in the same way as in Example 9, with exception that process gas mixture was replaced by the following: 150 sccm of Ar, 60 sccm of C₄F₈, 30 sccm of O₂ and 5 sccm of CH₃F₃Si. Resulting structure of a cross-section of the substrate after the etching process is shown on FIG. 12 and parameters for comparison are summarized at Table 4.

Most crucial comparative criteria which indicating etching profile control capability are top and middle CD, since they both are directly affecting etching profile at higher depth. Bottom CD is important but less crucial criteria, since profile distortions such as tapering at bottom could be fixed by over etching (continue of etching process after reaching desired depth or stop layer), when in comparison expansion or clogging in top CD is irreversible. From Table 2 it may be clearly observed that in case of addition of C₂H₆F₂Si or CH₃F₃Si to the working gas mixture in examples 8-11, both top and middle CD are closer or identical to initial value of opening in the mask (120 nm, arrow 3 on FIG. 2a), when in Comparative Examples 1-6 where Si-containing hydrofluorocarbon was not used or replaced by C₄F₆, top and middle CD is significantly increased comparing to examples 8-11, which would be unacceptable for semiconductor device fabrication process due to pattern degradation and possible structure collapse at prolonged etching process. Even though, in few cases neck CD for the case of use of C₂H₆F₂Si or CH₃F₃Si which is not favorable effect, it is still more reliable for fabrication of semiconductor device than significant neck CD expansion in the case of comparative examples 1-6. In the case of neck shrink during etching process neck CD can be opened by short cleaning step when it is more complicated to recover expanded neck CD which was observed in comparative Examples 1-6 without use of Si-containing hydrofluorocarbon.

Examples 12-18 have the following conditions.

Plasma etching device: In the disclosed methods, parallel plate (capacity coupled plasma) plasma generator was used as the plasma etching device. The parallel plate configuration included upper electrode and lower electrode, on which a substrate was placed (lower electrode was used as sample holder with cooling capability). The separation between the electrodes was either 13 or 20 mm. Upper electrode was connecter either to 27 MHz or 60 MHz generator when lower electrode was connected to 2 MHz generator.

Plasma etching conditions: During the plasma etching process power supplied to the upper electrode was varied in range from 500 to 2000 W, when power applied to the lower electrode was varied in range from 750 to 7000 W. Pressure was maintained constant during the process in a range between 1 and 100 mTorr. The plasma etching time was set at value between 30 and 300 seconds. Etch rate was estimated in nanometers per minute. Plasma etching gas mixture included Ar, O₂, C₄F₈ used as a fluorocarbon gas and C₂H₆F₂Si or CH₃F₃Si or C₄H₉F₃Si or C₅H₉F₅Si used as a Si-containing hydrofluorocarbon gas

Substrate: referring to FIG. 3a and FIG. 3b, a piece of monocrystalline silicon wafer with thin film of target plasma etching material on top of the wafer was used as a substrate. Target plasma etching material was one from the list: SiO₂, Si₃N₄, amorphous carbon (hereafter “a-C”). polycrystalline silicon (hereafter “poly-Si”), W. Initial thickness of each target plasma etching material was as follows: 300 nm of a-C, 110 nm of W, 550 nm of poly-Si, 300 nm of Si₃N₄, 2000 nm of SiO₂. Plasma etch rate and selectivity: Plasma etch rate was estimated as a difference between initial thickness of plasma etching target material film and thickness of the film after etching process divided by time, to receive etch rate in nm/min. Selectivity was estimated as ratio of etch rate calculated for two different plasma etching materials. Etch rate of 0 nm/min corresponds to condition when target material was not etched or polymer was deposited on top of it, resulting in infinite value of selectivity if this material was non-etching material in certain example.

### Example 12

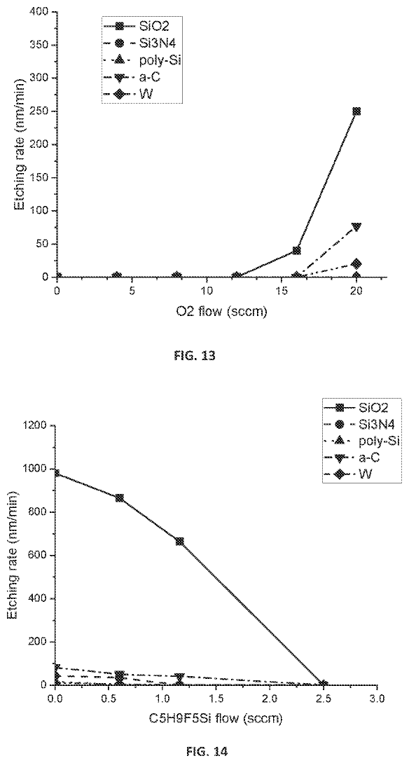

Plasma etching was performed in a plasma etching device where power of 750 W was applied to the top electrode at frequency of 27 MHz, power of 1500 W was applied to the bottom electrode at a frequency of the 2 MHz, pressure in chamber was maintained at 30 mTorr and gap between the electrodes was set at 13 mm. Process gas mixture including following flows of gases was introduced to the plasma etching chamber: 75 sccm of Ar, 7.6 sccm of C₅H₉F₅Si and flow of O₂ varied in a range between 0 and 20 sccm. Plasma etching process was carried out for 1 minute. FIG. 13 summarizes estimated etch rate as a function of O₂ flow rate for substrates including one of the following plasma etching materials: SiO₂, Si₃N₄, a-C, poly-Si and W. Experimental conditions representing etching window with high selectivity together with recorded etch rate for tested materials are summarized in Table 5.

### Example 13

Plasma etching was performed in the same way as in Example 12, with exception that process gas mixture was replaced by the following: 125 sccm of Ar, 9 sccm of C₄F₆, 14 sccm of O₂ and flow of C₅H₉F₅Si varying in the range between 0 and 2.5 sccm. FIG. 14 summarizes estimated etch rate as a function of C₅H₉F₅Si flow rate for substrates including one of the following plasma etching materials: SiO₂, Si₃N₄, a-C, poly-Si and W. Experimental conditions representing etching window with high selectivity together with recorded etch rate for tested materials are summarized in Table 5.

### Example 14

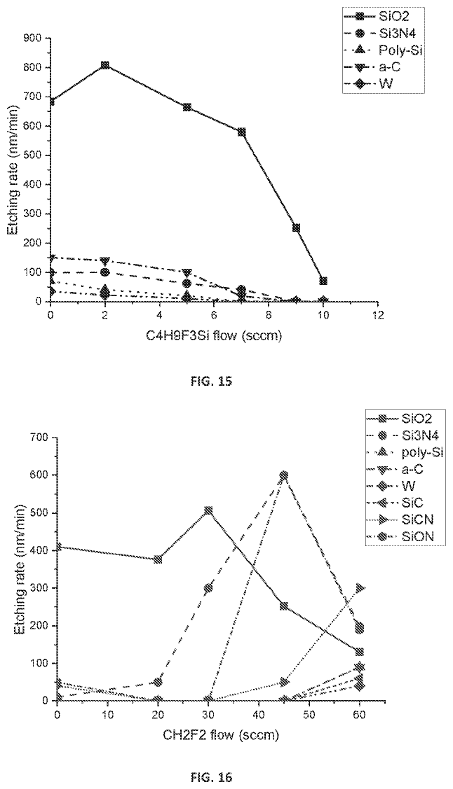

Plasma etching was performed in a plasma etching device where power of 1000 W was applied to the top electrode at frequency of 60 MHz, power of 7000 W was applied to the bottom electrode at a frequency of the 2 MHz; power for both top and bottom electrode was pulsed at frequency of 500 Hz and duty cycle 60%. Pressure in chamber was maintained at 20 mTorr and gap between the electrodes was set at 20 mm. Process gas mixture including following flows of gases was introduced to the plasma etching chamber: 150 sccm of Ar, 40 sccm of O₂, 65 sccm of C₄F₈ and flow of C₄H₉F₃Si varying in the range between 0 and 10 sccm. Plasma etching process was carried out for 30 seconds. FIG. 15 summarizes estimated etch rate as a function of C₄H₉F₃Si flow rate for substrates including one of the following plasma etching materials: SiO₂, Si₃N₄, a-C, poly-Si and W. Experimental conditions representing etching window with high selectivity together with recorded etch rate for tested materials are summarized in Table 5.

### Example 15

Plasma etching was performed in the same way as in Example 14, with exception that process gas mixture was replaced by the following: 150 sccm of Ar, 30 sccm of O₂, 5 sccm of C₄H₉F₃Si and flows of C₄F₈ and CH₂F₂ varying in the range between 0 and 60 sccm, while keeping total flow of both C₄F₈ and CH₂F₂ at 60 sccm. FIG. 16 summarizes estimated etch rate as a function of CH₂F₂ flow rate for substrates including one of the following plasma etching materials: SiO₂, Si₃N₄, a-C, poly-Si, W, SiC, SiCN, SiON. Experimental conditions representing etching window with high selectivity together with recorded etch rate for tested materials are summarized in Table 5.

### Example 16

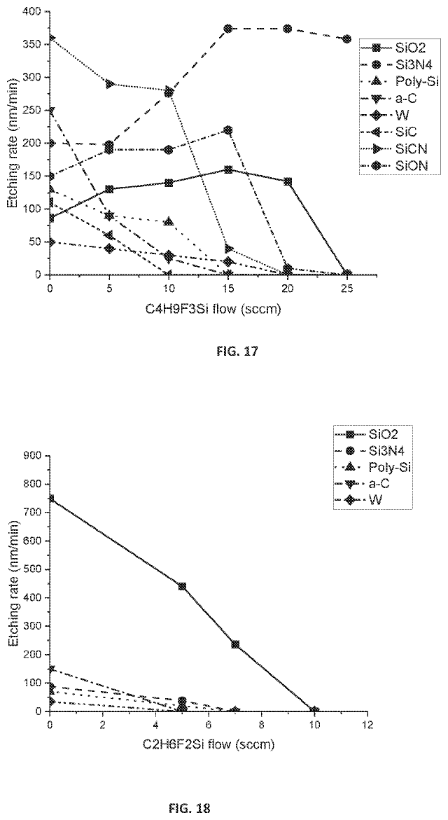

Plasma etching was performed in the same way as in Example 14, with exception that process gas mixture was replaced by the following: 150 sccm of Ar, 30 sccm of O₂, 60 sccm of CH₂F₂ and flow of C₄H₉F₃Si varying in the range between 0 and 25 sccm. FIG. 17 summarizes estimated etch rate as a function of C₄H₉F₃Si flow rate for substrates including one of the following plasma etching materials: SiO₂, Si₃N₄, a-C. poly-Si, W, SiC, SiCN, SiON. Experimental conditions representing etching window with high selectivity together with recorded etch rate for tested materials are summarized in Table 5.

As it could be observed from Table 5, etch rate varies in a wide range depending on chosen gas mixture and type of material used as etching target. There are few combinations of gas flows where particular material could be etched exclusively with infinite selectivity to other tested materials. For instance in Example 12 and 14 it was possible to etch SiO₂ with infinite selectivity to all other tested materials when conditions listed in Table 5 were used for the etching process. Moreover, it could be clearly observed from FIG. 14 that when C₄H₉F₃Si was not added to the process gas mixture (condition with 0 sccm of C₄H₉F₃Si) all of tested materials were etched during the process, therefore selectivity of SiO₂ etching was decreased. The same trend was reflected in FIG. 17, where selectivity of SiO₂ etching was gradually increased with increase of added flow of CH₉F₅Si to the point when infinite selectivity was achieved to poly-Si, Si₃N₄ and W together with high selectivity to a-C. Observed in FIG. 15 and FIG. 16 decrease of etch rate on all of materials with increase of Si-containing hydrofluorocarbon flow directly indicates that etching process inhibition is related to the polymer deposition promoted by addition of C₄H₉F₃Si or C₅H₉F₅Si. Important point is that when etching of Si₃N₄, poly-Si, a-C and W was suppressed, etch rate of SiO₂ remained at relatively high value (620 nm/min in Example 14), which indicates that despite effective promotion of polymer deposition it is still possible to keep etching of certain materials at reliable etch rate even when Si-containing hydrofluorocarbon is added to the working gas mixture.

In the Example 14, C₄F₈ was used as a main etchant, which is effective for SiO₂ etching, when C₄H₉F₃Si was added to the gas mixture to promote polymer deposition and increase of selectivity to other than SiO₂ materials. The same approach may be used for selective etching of other materials if another main etchant is used. In Example 16 CH₂F₂ was used as a main etchant, which is effective for Si₃N₄ etching. As a result it was possible to suppress etching of materials other than Si₃N₄ by addition of C₄H₉F₃Si to the gas mixture and promotion of polymer deposition while keeping reasonable etch rate of Si₃N₄. Moreover, at flow rates of C₄H₉F₃Si above 10 sccm etch rate of Si₃N₄ was even promoted due to presence of trifluoromethyl group in the C₄H₉F₃Si molecule, which can supply fluorocarbon to the process and promote etching of Si₃N₄, when polymer will be deposited on another materials. In the case of condition highlighted in Table 5 for Example 16, when 25 sccm of C₄H₉F₃Si was added to the process gas mixture it was possible to achieve infinite selectivity to a-C, poly-Si, W, SiO₂, SiC, SiCN, SiON; when at lower flow rates of C₄H₉F₃Si or when C₄H₉₃Si was not added to the process gas mixture (condition with 0 sccm on FIG. 17) at least one more material from the list was etched together with Si₃N₄ resulting in compromised selectivity.

In addition, there were several conditions where it was possible to etch combination of materials with infinite selectivity to other tested materials. For instance, in Example 15 it was possible to etch both Si₃N₄ and SiO₂ with infinite selectivity to a-C, poly-Si, W, SiC, SiCN, SiON. In some cases it is necessary to etch multiple materials simultaneously with high selectively to rest of substrate, and demonstrated in the present disclosure selective etching using Si-containing hydrofluorocarbon mixed with common gases (e.g. mixture including either inert gas, fluorocarbon, hydrofluorocarbon, oxidizing gas or combinations of thereof) may be essential for this purpose.

In particular, for the application of multicolor etching typically several Si-containing films are presented on the substrate and exposed during the etching process. Commonly used Si-containing films are SiO₂, Si₃N₄, SiC, SiCN and SiON; therefore, demonstrated etching of SiO₂, Si₃N₄ or both of those materials with high or infinite selectivity to another Si-containing materials achieved by addition of Si-containing hydrofluorocarbon to the process gas mixture will be essential for advanced patterning of a substrate using multicolor etching.

TABLE 5

| | Process gas mixture (flow rate, sccm) | | | | | | Measured etch rate (nm/min) | | | | | | | |
|---|---|---|---|---|---|---|---|---|---|---|---|---|---|---|
| | O₂ | C₄F₆ | C₄F₈ | C₄H₉F₃Si | C₅H₉F₅Si | CH₂F₂ | SiO₂ | Si₃N₄ | a-C | poly-Si | W | SiC | SiCN | SiON |
| Ex 12 | 16 | 0 | 0 | 0 | 7.6 | 0 | 50 | 0 | 0 | 0 | 0 | — | — | — |
| Ex 13 | 14 | 9 | 0 | 0 | 1.2 | 0 | 700 | 0 | 25 | 0 | 0 | — | — | — |
| Ex 14 | 40 | 0 | 65 | 10 | 0 | 0 | 620 | 0 | 0 | 0 | 0 | — | — | — |
| Ex 15 | 30 | 0 | 40 | 5 | 0 | 20 | 376 | 50 | 0 | 0 | 0 | 0 | 0 | 0 |
| Ex 15 | 30 | 0 | 30 | 5 | 0 | 30 | 506 | 300 | 0 | 0 | 0 | 0 | 0 | 0 |
| Ex 16 | 30 | 0 | 0 | 25 | 0 | 60 | 0 | 368 | 0 | 0 | 0 | 0 | 0 | 0 |

### Example 17

Plasma etching was performed in a plasma etching device where power of 1000 W was applied to the top electrode at frequency of 60 MHz, power of 7000 W was applied to the bottom electrode at a frequency of the 2 MHz; power for both top and bottom electrode was pulsed at frequency of 500 Hz and duty cycle 60%. Pressure in chamber was maintained at 20 mTorr and gap between the electrodes was set at 20 mm. Process gas mixture including following flows of gases was introduced to the plasma etching chamber: 150 sccm of Ar, 30 sccm of O₂, 60 sccm of C₄F₈ and flow of C₂H₆F₂Si varying in the range between 0 and 10 sccm. Plasma etching process was carried out for 30 seconds. FIG. 18 summarizes estimated etch rate as a function of C₂H₆F₂Si flow rate for substrates including one of the following plasma etching materials: SiO₂, Si₃N₄, a-C, poly-Si and W. Experimental conditions representing etching window with high selectivity together with recorded etch rate for tested materials are summarized in Table 6.

### Example 18

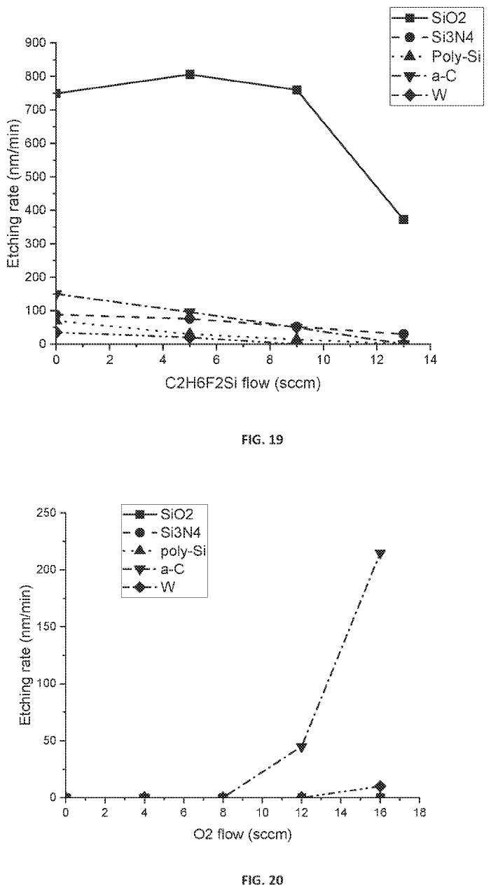

Plasma etching was performed in the same way as in Example 17, with exception that process gas mixture was replaced by the following: 150 sccm of Ar, 30 sccm of O₂, 60 sccm of C₄F₈ and flow of CH₃F₃Si varying in the range between 0 and 13 sccm. FIG. 19 summarizes estimated etch rate as a function of CH₂F₂ flow rate for substrates including one of the following plasma etching materials: SiO₂, Si₃N₄, a-C, poly-Si, W. Experimental conditions representing etching window with high selectivity together with recorded etch rate for tested materials are summarized in Table 6.

TABLE 6

| | Process gas mixture | | | | Measured etch rate (nm/min) | | | | |
|---|---|---|---|---|---|---|---|---|---|
| | (flow rate, sccm) | | | | | | | poly- | |
| | O₂ | C₄F₈ | C₂H₆F₂Si | CH₃F₃Si | SiO₂ | Si₃N₄ | a-C | Si | W |
| Ex 17 | 30 | 60 | 5 | 0 | 440 | 38 | 0 | 20 | 0 |
| Ex 17 | 30 | 60 | 7.5 | 0 | 236 | 0 | 0 | 0 | 0 |
| Ex 18 | 30 | 60 | 0 | 13 | 372 | 30 | 0 | 0 | 0 |

As it could be observed from Table 6, etch rate varies in a wide range depending on chosen gas mixture and type of material used as etching target. There are few combinations of gas flows where particular material could be etched with high selectivity or even exclusively with infinite selectivity to other tested materials. For instance in Example 17 and 18 it was possible to etch SiO₂ with high or infinite selectivity to all other tested materials when conditions listed in Table 6 were used for the etching process. Moreover, it could be clearly observed from FIG. 18 that when C₂H₆F₂Si was not added to the process gas mixture (condition with 0 sccm of C₂H₆F₂Si) all of tested materials were etched during the process, therefore selectivity of SiO₂ etching was decreased. The same trend was reflected in FIG. 19, where selectivity of SiO₂ etching was gradually increased with increase of added flow of CH₃F₃Si to the point when infinite selectivity was achieved to poly-Si, a-C and W together with high selectivity to Si₃N₄. Observed in FIG. 18 and FIG. 19 decrease of etch rate on all of materials with increase of Si-containing hydrofluorocarbon flow directly indicates that etching process inhibition is related to the polymer deposition promoted by addition of CH₃F₃Si or CH₃F₅Si in the same way as it was observed for C₄H₉F₃Si and C₅H₉F₅Si.

Examples 19-22 and Comparative Example 7 have the following conditions.

Plasma etching device: In the disclosed methods, parallel plate (capacity coupled plasma) plasma generator was used as the plasma etching device. The parallel plate configuration included upper electrode and lower electrode, on which substrate was placed (lower electrode was used as sample holder with cooling capability). The separation between the electrodes was either 13 or 20 mm. Upper electrode was connected either to 27 MHz or 60 MHz power generator when lower electrode was connected to 2 MHz power generator.

Plasma etching conditions: During the plasma etching process power supplied to the upper electrode was varied in range from 500 to 1000 W, when power applied to the lower electrode was varied in range from 750 to 7000 W; power applied to both top and bottom electrodes may be pulsed at lower frequency (e.g. 1-1000 Hz) and duty cycle in range from 10-99%. Pressure has been maintained constant during the process at values selected in range between 5 and 100 mTorr. The plasma etching time was set at value between 30 and 60 seconds. Plasma process gas mixture included Ar, O₂ and CH₃F₃Si or C₂H₆F₂Si or C₄H₉F₃Si as Si-containing hydrofluorocarbon gas.

Substrate: referring to FIG. 4a and FIG. 4b, a piece of monocrystalline silicon wafer with thin film of target plasma etching material on top of the wafer was used as a substrate. Target plasma etching material was one from the list: SiO₂, Si₃N₄, amorphous carbon (hereafter “a-C”), polycrystalline silicon (hereafter “poly-Si”), W.

Initial thickness of each target plasma etching material was as follows: 300 nm of a-C, 110 nm of W, 550 nm of poly-Si, 300 nm of Si₃N₄, 2000 nm of SiO₂.

Plasma etch rate and selectivity: Plasma etch rate was estimated as a difference between initial thickness of plasma etching target material film and thickness of the film after etching process divided by duration of etching process in minutes, to receive etch rate in nm/min. Selectivity was estimated as ratio of etch rate calculated for two different plasma etching materials. Term “infinite selectivity” refers to the case where material is removed from the substrate while non-etching material remains intact or thin film is deposited on top of non-etching material during etching process.

### Example 19

Plasma etching was performed in a plasma etching device where power of 750 W was applied to the top electrode at frequency of 27 MHz, power of 1500 W was applied to the bottom electrode at a frequency of the 2 MHz, pressure in chamber was maintained at 30 mTorr and gap between the electrodes was set at 13 mm. Process gas mixture including following flows of gases was introduced to the plasma etching chamber: 75 sccm of Ar, 7.6 sccm of C₄H₉F₄Si and flow of O₂ varied in a range between 0 and 20 sccm. Plasma etching process was carried out for 1 minute. FIG. 20 summarize estimated etch rate of O₂ flow rate for substrates including one of the following plasma etching materials: SiO₂, Si₃N₄, a-C, poly-Si and W. Experimental conditions representing etching window for a-C with high selectivity together with recorded etch rate for tested materials are summarized in Table 7. Value of etch rate of 0 nm/min indicates that polymer was deposited on the studied film, meaning that film was not etched, resulting in infinite selectivity in the case of non-etching material film.

TABLE 7

| | Process gas mixture | | | | Measured etch rate (nm/min) | | | | | |
|---|---|---|---|---|---|---|---|---|---|---|
| | (flow rate, sccm) | | | | | | | a-C (W | poly- | |
| | Ar | O₂ | C₄H₉F₃Si | C₄F₆ | SiO₂ | Si₃N₄ | a-C | doped) | Si | W |
| Ex 19 | 75 | 12 | 7.6 | 0 | 0 | 0 | 45 | — | 0 | 0 |
| Ex 19 | 75 | 16 | 7.6 | 0 | 0 | 0 | 215 | — | 0 | 10 |
| Ex 20 | 150 | 45 | 15 | 0 | 0 | 0 | 160 | 74 | 0 | 40 |
| Ex 20 | 150 | 65 | 15 | 0 | 0 | 0 | 540 | 320 | 0 | 0 |
| Ex 20 | 150 | 85 | 15 | 0 | 0 | 0 | 520 | 165 | 0 | 0 |
| Com ex 7 | 150 | 45 | 0 | 15 | 224 | 146 | 250 | 30 | 120 | 76 |
| Com ex 7 | 150 | 65 | 0 | 15 | 144 | 130 | 600 | 230 | 130 | 140 |
| Com ex 7 | 150 | 85 | 0 | 15 | 200 | 96 | 600 | 348 | 100 | 154 |

### Example 20

Plasma etching was performed in a plasma etching device where power of 700 W was applied to the top electrode at frequency of 60 MHz, power of 7000 W was applied to the bottom electrode at a frequency of the 2 MHz; power applied to both top and bottom electrode was pulsed at 500 Hz with duty cycle of 60%. Pressure in chamber was maintained at 25 mTorr and gap between the electrodes was set at 30 mm. Process gas mixture including following flows of gases was introduced to the plasma etching chamber: 150 sccm of Ar, 20 sccm of C₄H₉F₃Si and flow of O₂ varied in a range between 5 and 90 sccm. Plasma etching process was carried out for 30 seconds. FIG. 21 summarizes estimated etch rate as a function of O₂ flow rate for substrates including one of the following plasma etching materials: SiO₂, Si₃N₄, a-C, W doped a-C, poly-Si and W. Experimental conditions representing etching window for a-C and W doped a-C with high selectivity together with recorded etch rate for tested materials are summarized in Table 7. Value of etch rate of 0 nm/min indicates that polymer was deposited on the studied film, meaning that film was not etched, resulting in infinite selectivity in the case of non-etching material film.

### Comparative Example 7

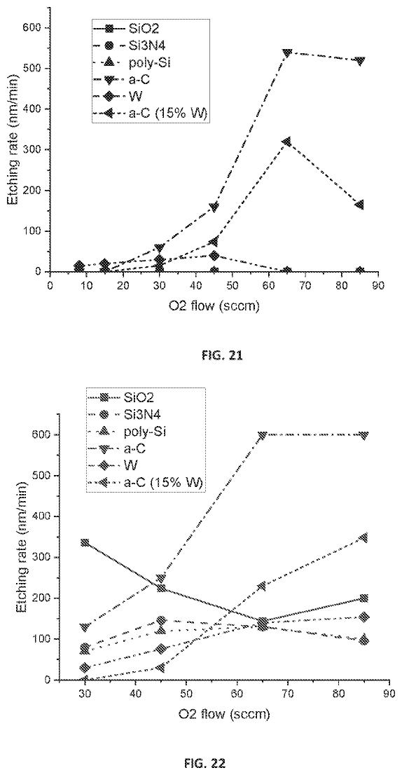

Plasma etching was performed in the same way as in Example 20, with exception that 15 sccm flow of C₄H₉F₃Si in process gas mixture was replaced with 15 sccm flow of C₄F₆. FIG. 22 summarizes estimated etch rate as a function of O₂ flow rate for substrates including one of the following plasma etching materials: SiO₂, Si₃N₄, a-C, W doped a-C, poly-Si and W. Table 7 summarize recorded etch rate for each material compared to identical conditions with addition of C₄H₉F₃Si in Example 20.

As it could be observed from Table 7 and FIG. 21 and FIG. 22 there is a good consistency between results in Experiments 1 and 2. With increase of O₂ flow rate while keeping other parameters the same etch rate of a-C is increasing, while keeping high or infinite selectivity to another tested materials due to deposition of polymer. In particular, in Example 19 when O₂ flow rate was 12 sccm and in Example 20 when O₂ flow rate was above 65 sccm etching of amorphous carbon with infinite selectivity to poly-Si, SiO₂, Si₃N₄ and W was observed. Those conditions look promising for patterning of a-C hard mask, or another organic material, due to infinite selectivity to materials which are commonly protected by hard mask. Infinite selectivity will allow fast etching of the mask without concern of damaging layers under mask and mask pattern distortions after etching (such as undercut). Difference in a-C etch rate at small O₂ flow rates between Examples 19 and 20 may be explained by stronger ion bombardment in Example 20 as a result of higher applied power, which brings additional etch rate by sputtering. It may also be noted that at certain conditions it is possible to etch both a-C and W selectively to all other tested materials, suggesting that etching of W doped a-C is possible at those conditions.

Furthermore, it was possible to etch W doped a-C in Example 20 when O₂ flowrate was above 45 sccm which can be essential for high aspect ratio etching applications (such as ONON channel etching or staircase contact etching in 3D NAND) where robust mask is required due to long time of process resulting in use of doped a-C as a hard mask. Observed infinite selectivity to other tested materials will ensure that films covered by mask (such as Si₃N₄ or SiO₂) will not be damaged during patterning of mask itself.

Another possible application is selective mask removal using studied in the present disclosure gas mixture. Use of Si-containing hydrofluorocarbon in a process gas mixture will allow selective removal of a-C mask from the substrate while not damaging another materials. On the other hand, as it may be observed in Comparative Example 19 that it is possible to etch a-C and W doped a-C when C₄H₉F₃Si is not added to the process gas mixture and the same flow of C₄F₆ added instead. However, selectivity to other tested materials is dramatically decreased in case of use of C₄F₆, even though C₄F₆ is commonly used gas for enhancement of polymerization to preserve hard mask or sidewalls during high aspect ratio etching process. Poor selectivity of a-C and doped a-C etching will limit process window for the mask patterning or removal and may make practical use of the process impossible for certain applications.

Therefore, it may be concluded that addition of Si-containing hydrofluorocarbon gas to the process gas mixture allows significant increase of selectivity to non-etching material by deposition of robust polymer, while keeping reasonable etching speed of the target organic film, comparable to common Ar+O₂+C₄F₆ gas mixture. Benefits of use of Si-containing hydrofluorocarbon are expected to be the same when compared to the use of an Ar+O₂ gas mixture to selectively etch organic films.

### Example 21

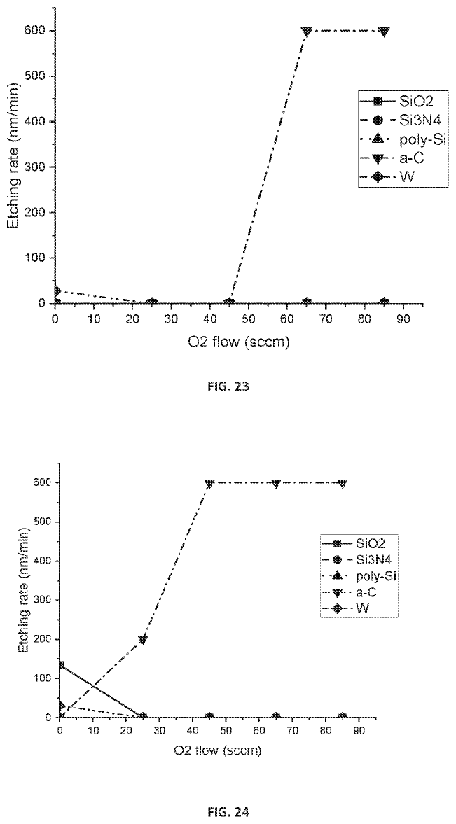

Plasma etching was performed in a plasma etching device where power of 700 W was applied to the top electrode at frequency of 60 MHz, power of 7000 W was applied to the bottom electrode at a frequency of the 2 MHz; power applied to both top and bottom electrode was pulsed at 500 Hz with duty cycle of 60%. Pressure in chamber was maintained at 25 mTorr and gap between the electrodes was set at 20 mm. Process gas mixture including following flows of gases was introduced to the plasma etching chamber: 150 sccm of Ar, 20 sccm of C₂H₆F₂Si and flow of O₂ varied in a range between 0 and 90 sccm. Plasma etching process was carried out for 30 seconds. FIG. 23 summarizes estimated etch rate as a function of O₂ flow rate for substrates including one of the following plasma etching materials: SiO₂, Si₃N₄, a-C, and W. Experimental conditions representing etching window for a-C and with high selectivity together with recorded etch rate for tested materials are summarized in Table 8. Value of etch rate of 0 nm/min indicates that polymer was deposited on the studied film, meaning that film was not etched, resulting in infinite selectivity in the case of non-etching material film.

TABLE 8

| | Process gas mixture (flow rate, | | | | | | | | |
|---|---|---|---|---|---|---|---|---|---|
| | sccm) | | | | Measured etch rate (nm/min) | | | | |
| | Ar | O₂ | C₂H₆F₂Si | CH₃F₃Si | SiO₂ | Si₃N₄ | a-C | poly-Si | W |
| Ex 21 | 150 | 65 | 20 | 0 | 0 | 0 | >600 | 0 | 0 |
| Ex 21 | 150 | 85 | 20 | 0 | 0 | 0 | >600 | 0 | 0 |
| Ex 22 | 150 | 45 | 25 | 0 | 0 | 0 | >600 | 0 | 0 |
| Ex 22 | 150 | 65 | 25 | 0 | 0 | 0 | >600 | 0 | 0 |
| Ex 22 | 150 | 85 | 25 | 0 | 0 | 0 | >600 | 0 | 0 |

### Example 22

Plasma etching was performed in the same way as in Example 21, with exception that process gas mixture was replaced by the following: 150 sccm of Ar, 25 sccm of CH₃F₃Si and flow of O₂ varied in a range between 0 and 90 sccm. FIG. 24 summarizes estimated etch rate as a function of O₂ flow rate for substrates including one of the following plasma etching materials: SiO₂, Si₃N₄, a-C, poly-Si and W. Experimental conditions representing etching window for a-C with high selectivity together with recorded etch rate for tested materials are summarized in Table 8. Value of etch rate of 0 nm/min indicates that polymer was deposited on the studied film, meaning that film was not etched, resulting in infinite selectivity in the case of non-etching material film.

As it could be observed from Table 8 and FIG. 23-24 there is a good consistency between results in experiments 21-22 with gas mixture including Si-containing hydrofluorocarbons. With increase of O₂ flow rate while keeping other parameters the same etch rate of a-C is increasing, while keeping high or infinite selectivity to another tested materials due to deposition of polymer. In particular, in Example 21 when O₂ flow rate was more than 65 sccm and in Example 22 when O₂ flow rate was above 45 sccm etching of amorphous carbon with infinite selectivity to poly-Si, SiO₂, Si₃N₄ and W was observed. Those conditions look promising for patterning of a-C hard mask, or another organic material, due to infinite selectivity to materials which are commonly protected by hard mask. Infinite selectivity will allow fast etching of the mask without concern of damaging layers under mask and mask pattern distortions after etching (such as undercut). Observed results for CH₃F₃Si and C₂H₆F₂Si are demonstrating the same trend as described in Examples 19-20 for C₄H₉F₃Si, confirming that Si-containing hydrofluorocarbons are promising for development of selective etching processes of organic materials.

Examples 23 to 32 regarding cyclic plasma dry etching methods have the following conditions.

Plasma etching device: In the disclosed methods, parallel plate (capacity coupled plasma) plasma generator was used as the plasma etching device. The parallel plate configuration included upper electrode and lower electrode; on which substrate was placed (lower electrode was used as sample holder with cooling capability). The separation between the electrodes was either 13 or 20 mm. Upper electrode was connecter either to 27 MHz or 60 MHz generator when lower electrode was connected to 2 MHz generator.

Plasma etching condition: During the plasma etching process power supplied to the upper electrode was varied in range from 500 to 2000 W, when power applied to the lower electrode was varied in range from 750 to 7000 W. Power applied to the top and the bottom electrode may be both pulsed at lower frequency (e.g. 1-1000 Hz) with duty cycle in range 199%. Pressure has been maintained constant during the process at values selected in range between 5 and 100 mTorr. The plasma etching time was set at value between 10 and 60 seconds. Deposition rate has been estimated in nanometers per minute. Negative deposition rate represents condition when material on the substrate was etched. Plasma process gas mixture included at least one of the following gases: Ar, O₂, C₄F₆ and/or C₄F₈ as a fluorocarbon gas, C₄H₉F₃Si or C₅H₉F₅Si as Si-containing hydrofluorocarbon gas, CH₂F₂ as hydrofluorocarbon gas.

Substrate: referring to FIG. 5a and FIG. 5d, a piece of monocrystalline silicon wafer with thin film of target plasma etching material on top of the wafer was used as a substrate. Target plasma etching material was one from the list: SiO₂, Si₃N₄, amorphous carbon (hereafter “a-C”), polycrystalline silicon (hereafter “poly-Si”), W, SiC, SiCN, SiON. Initial thickness of each target plasma etching material was as follows: 300 nm of a-C, 110 nm of W, 550 nm of poly-Si, 2050 nm of Si₃N₄, 200 nm of SiO₂, 105 nm of SiC, 300 nm of SiCN, 315 nm of SiON.

Plasma etch rate and selectivity: Plasma deposition or etch rate was estimated as a difference between initial thickness of plasma etching target material film and thickness of the film after etching process divided by time, to receive etching or deposition rate in nm/min. Negative deposition rate in some of examples represents etching of the sample (in fact equivalent to etch rate value).

Cyclic etching process: The disclosed cyclic etching process refers to the process when the substrate is processed in an etching chamber using several etching steps which are repeated in a sequence. Example of substrate processed using cyclic etching shown in FIG. 5a to FIG. 5d. Example of initial substrate is shown in FIG. 5a, consisting of a substrate 702 having multiple thin films on top of it where film 704 works as a mask, films 706, 708 and 710 are films from non-etching materials and film 712 is a film from of the etching target material.

The substrate after the first step of the etching cycle is presented on FIG. 5b. During the first step material was partially removed 716 using selective etching recipe, resulting in deposition of polymer 714 on non-etching materials and mask with polymer thickness depending on the material of the film. The substrate after the second step of the cycle is presented in FIG. 5c. For the second step etching recipe with not infinite selectivity to the polymer deposited during the first step was used resulting in further etching of the target material 718 and removing of the polymer from non-etching material. Depending on the non-etching material and conditions of the process, some polymer may remain on the non-etching material films or some of non-etching material films may be etched during the second step after complete removal of the polymer, as it shown in FIG. 5d. However, the cyclic process in the present disclosure is not limited to presented examples in any way and process steps, number of process steps in the cycle, substrate and plasma etching process may be varied. For instance, some steps within the cycle may be only deposition steps without etching and the substrate may have a single material film instead of plural films 706, 708, 710, 712 presented in the example.

### Example 23

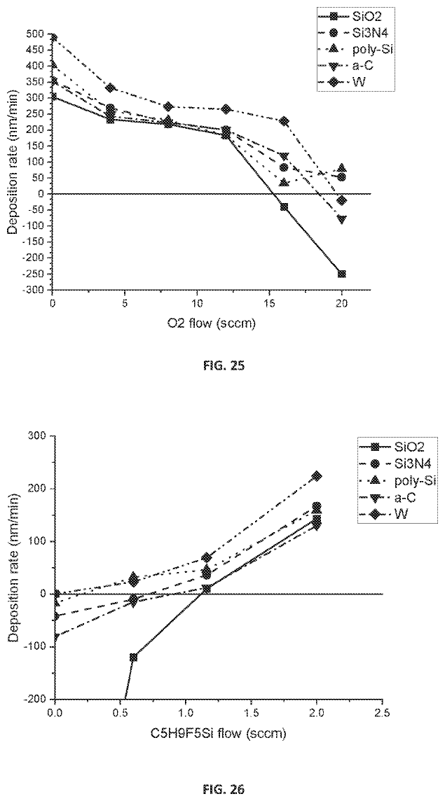

Plasma etching condition: Plasma etching was performed in a plasma etching device where power of 750 W was applied to the top electrode at frequency of 27 MHz, power of 1500 W was applied to the bottom electrode at a frequency of the 2 MHz, pressure in chamber was maintained at 30 mTorr and gap between the electrodes was set at 13 mm. Process gas mixture including following flows of gases was introduced to the plasma etching chamber: 75 sccm of Ar, 7.6 sccm of C₅H₉F₅Si and flow of O₂ varied in a range between 0 and 20 sccm. Plasma etching process was carried out for 1 minute. FIG. 25 summarizes estimated deposition rate as a function of O₂ flow rate for substrates including one of the following plasma etching materials: SiO₂, Si₃N₄, a-C, poly-Si and W.

### Example 24

Plasma etching was performed in the same way as in Example 23, with exception that process gas mixture was replaced by the following: 75 sccm of Ar, 9 sccm of C₄F₆, 14 sccm of O₂ and flow of C₅H₉F₅Si varying in the range between 0 and 2.5 sccm. FIG. 26 summarizes estimated deposition rate as a function of C₅H₉F₅Si flow rate for substrates including one of the following plasma etching materials: SiO₂, Si₃N₄, a-C, poly-Si and W.

### Example 25

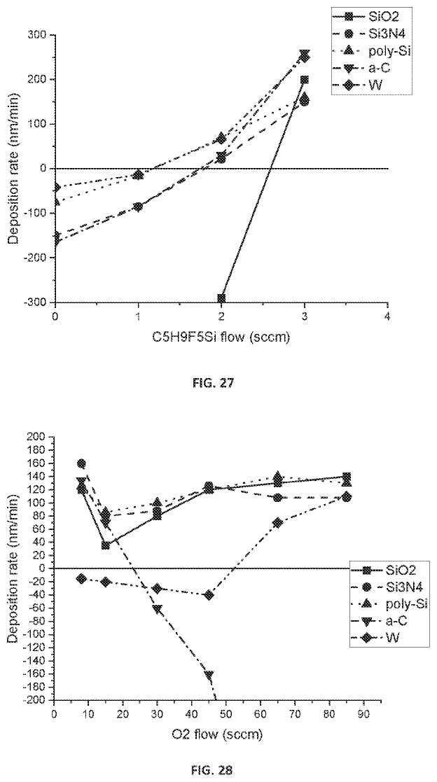

Plasma etching was performed in the same way as in Example 23, with exception that process gas mixture was replaced by the following: 125 sccm of Ar, 9 sccm of C₄F₈, 14 sccm of O₂ and flow of C₅H₉F₅Si varying in the range between 0 and 2.5 sccm. FIG. 27 summarizes estimated polymer deposition rate as a function of C₅H₉F₅Si flow rate for substrates including one of the following plasma etching materials: SiO₂, Si₃N₄, a-C, poly-Si and W.

### Example 26

Plasma etching condition: Plasma etching was performed in a plasma etching device where power of 700 W was applied to the top electrode at frequency of 60 MHz, power of 7000 W was applied to the bottom electrode at a frequency of the 2 MHz; power for both top and bottom electrode was pulsed at frequency of 500 Hz and duty cycle 60%. Pressure in chamber was maintained at 20 mTorr and gap between the electrodes was set at 20 mm. Process gas mixture including following flows of gases was introduced to the plasma etching chamber: 150 sccm of Ar, 15 sccm of C₄H₉F₃Si, flow of O₂ varying in the range between 0 and 90 sccm. Plasma etching process was carried out for 30 seconds. FIG. 28 summarizes estimated deposition rate as a function of O₂ flow rate for substrates including one of the following plasma etching materials: SiO₂, Si₃N₄, a-C, poly-Si and W.

### Example 27

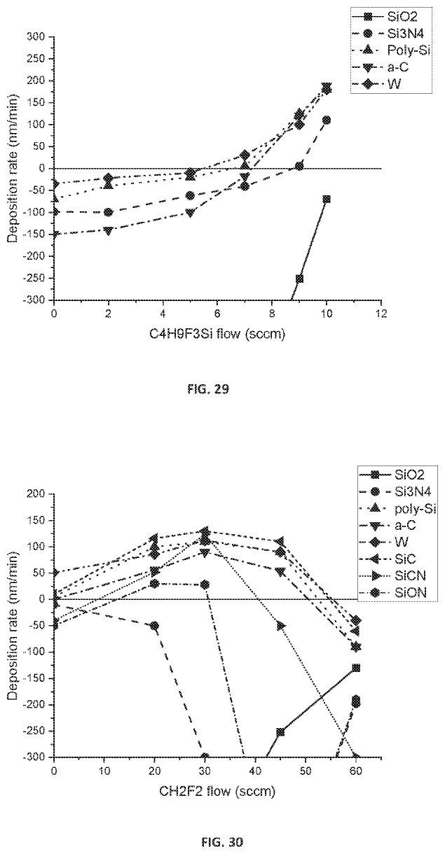

Plasma etching was performed in the same way as in Example 26, with exception that power applied to the top electrode was 1000 W and process gas mixture was replaced by the following: 150 sccm of Ar, 40 sccm of O₂, 65 sccm of C₄F₈ and flow of C₄H₉F₃Si varying in the range between 0 and 10 sccm. FIG. 29 summarizes estimated deposition rate as a function of C₄H₉F₃Si flow rate for substrates including one of the following plasma etching materials: SiO₂, Si₃N₄, a-C, poly-Si, W, SiC, SiCN, SiON.

### Example 28

Plasma etching was performed in the same way as in Example 26, with exception that power applied to the top electrode was 1000 W and process gas mixture was replaced by the following: 150 sccm of Ar, 30 sccm of O₂, 5 sccm of C₄H₉F₃Si and flows of C₄F₈ and CH₂F₂ varying in the range between 0 and 60 sccm, while keeping total flow of both C₄F₈ and CH₂F₂ at 60 sccm. FIG. 30 summarizes estimated deposition rate as a function of CH₂F₂ flow rate for substrates including one of the following plasma etching materials: SiO₂, Si₃N₄, a-C, poly-Si, W, SiC, SiCN, SiON.

### Example 29

Plasma etching was performed in the same way as in Example 26, with exception that power applied to the top electrode was 1000 W and process gas mixture was replaced by the following: 150 sccm of Ar, 30 sccm of O₂, 60 sccm of CH₂F₂ and flow of C₄H₉F₃Si varying in the range between 0 and 25 sccm. FIG. 31 summarizes estimated deposition rate as a function of C₄H₉F₃Si flow rate for substrates including one of the following plasma etching materials: SiO₂, Si₃N₄, a-C, poly-Si, W, SiC, SiCN, SiON.

### Example 30

Plasma etching condition: Cyclic plasma etching process was performed in a plasma etching device where power of 1000 W was applied to the top electrode at frequency of 60 MHz, power of 7000 W was applied to the bottom electrode at a frequency of the 2 MHz; power for both top and bottom electrode was pulsed at frequency of 500 Hz and duty cycle 60%. Pressure in chamber was maintained at 20 mTorr and gap between the electrodes was set at 20 mm.

Each cycle contained two etching steps. First, step selective etching of Si₃N₄ (with deposition of polymer on materials other than Si₃N₄) and second step aggressive etching of Si₃N₄ with low selectivity (which is etching polymer deposited during 1^{st} step and materials other than Si₃N₄).

During the first etching cycle, the first step was performed using process gas mixture supplied to the chamber including following flows of gases: 150 sccm of Ar, 25 sccm of C₄H₉F₃Si, 60 sccm of CH₂F₂ and 30 sccm of O₂. Plasma etching process during first step was carried out for 17 seconds. Second step was performed using process gas mixture supplied to the chamber including following flows of gases: 150 sccm of Ar, 15 sccm of C₄F₈, 45 sccm of CH₂F₂ and 30 sccm of O₂. Plasma etching process during second step was carried out for 10 s.

Second and following cycles were using the same gas mixtures for the first and second step inside each cycle as during the first cycle, however duration of each step was altered. Duration of first step with selective etching was set to 10 s and duration of second with not selective etching was set to 40 s for second and following etching cycles.

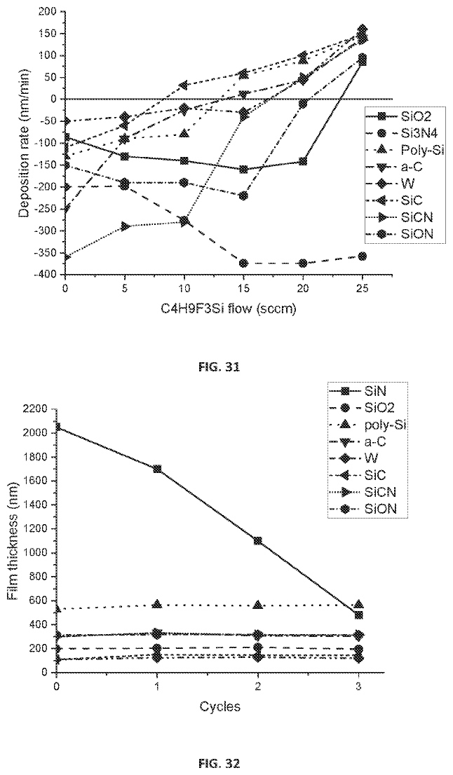

FIG. 32 summarizes thickness of SiO₂, Si₃N₄, a-C, poly-Si, W, SiC, SiCN, SiON films after the cyclic etching process as a function of number of cycles. Decrease in thickness of studied film reflects etching of the substrate when increase of thickness of the studied film reflects deposition of polymer on top of a substrate. Values presented for 0 cycles representing initial thickness of studied films.

### Example 31

Plasma etching condition: Cyclic plasma etching process was performed in a plasma etching device where power of 700 W was applied to the top electrode at frequency of 60 MHz, power of 7000 W was applied to the bottom electrode at a frequency of the 2 MHz; power for both top and bottom electrode was pulsed at frequency of 500 Hz and duty cycle 60%. Pressure in chamber was maintained at 25 mTorr and gap between the electrodes was set at 20 mm.

Each cycle contained two etching steps. First step selective etching of Pt (with deposition of polymer on materials other than Pt) and second step etching of Pt with low selectivity (which is etching polymer deposited during 1^{st} step and materials other than Pt).

The first step was performed using process gas mixture supplied to the chamber including following flows of gases: 150 sccm of Ar, 15 sccm of C₄H₉F₃Si, and 15 sccm of O₂. Plasma etching process during first step was carried out for 60 seconds. Second step was performed using process gas mixture supplied to the chamber including following flows of gases: 150 sccm of Ar, 65 sccm of C₄F₈ and 30 sccm of O₂. Plasma etching process during second step was carried out for 9 s. Estimated etch rate for each material per etching cycle is summarized in Table 9. FIG. 34 summarize thickness of Pt, a-C, poly-Si, SiC, Si₃N₄, films after one etching cycle. Decrease in thickness of studied film reflects etching of the workpiece when increase of thickness of the studied film reflects deposition of polymer on top of a workpiece. Values presented for 0 cycles representing initial thickness of studied films.

### Example 32

Plasma etching condition: Plasma etching was performed in a plasma etching device where power of 700 W was applied to the top electrode at frequency of 60 MHz, power of 7000 W was applied to the bottom electrode at a frequency of the 2 MHz; power for both top and bottom electrode was pulsed at frequency of 500 Hz and duty cycle 60%. Pressure in chamber was maintained at 25 mTorr and gap between the electrodes was set at 20 mm. Process gas mixture including following flows of gases was introduced to the plasma etching chamber: 150 sccm of Ar, 15 sccm of C₄H₉F₃Si, 15 sccm of O₂. Plasma etching process was carried out for 30 seconds. Estimated etch rate for each material per etching cycle is summarized in Table 9. Negative etch rate corresponds to the case when polymer was deposited on the studied material and reflects deposition rate.

Based on assumption that amount of removed etching target material or deposited polymer scales linearly with the process time it was estimated that it will be necessary to run process described in the present example for around 54 s to remove same amount of Pt as it was reported for one cycle of etching in Example 31. FIG. 34 summarize estimated thickness of Pt, a-C, poly-Si, SiC and Si₃N₄ for the process reported in Example 32 with duration of 54 s.

TABLE 9

| | Pt | a-C | Poly-Si | SiC | Si₃N₄ |
|---|---|---|---|---|---|
| Etch rate (nm/cycle) | | | | | |
| Ex 31 | 90 | 3 | 5 | 5 | 5 |
| Etch rate (nm/min) | | | | | |
| Ex 32 | 100 | −80 | −84 | −78 | −80 |

As it could be observed from Examples 23 to 32 in FIG. 25 to FIG. 32, polymer deposition or etch rate varies strongly depending on used gas mixture and target material. Conditions where one of materials was etched when polymer was deposited on other materials (case of infinite selectivity) or conditions where polymer was deposited at different rate on various materials may be used for development of cyclic etching processes. For instance, in FIG. 25 at condition using 16 sccm of O₂, SiO₂ was etched with infinite selectivity to other tested materials; in FIG. 27 at condition using 2 sccm of C₅H₉F₅Si, SiO₂ was etched with infinite selectivity to other tested materials; in FIG. 28 at conditions using flow of O₂ more than 60 sccm a-C was etched with infinite selectivity to other materials; in FIG. 29 at condition when C₄H₉F₃Si flowrate is above 8 sccm SiO₂ was etched with infinite selectivity to other materials; in FIG. 30 at conditions when CH₂F₂ flow was between 20 and 40 sccm either SiO₂ or Si₃N₄ can be etched with infinite selectivity to other materials; in FIG. 31 at condition when flow rate of C₄H₉F₃Si was 25 sccm, Si₃N₄ can be etched with infinite selectivity to another treated materials. Those conditions with infinite selectivity may be used for development of cyclic recipe employing at least two steps within the cycle when first step during the cycle is etching of target material with infinite selectivity and second step is aggressive etching of target material with high etch rate and low selectivity. In this case, polymer deposited during the first step of selective etching will protect non-etching materials during aggressive etching, when use of aggressive etching will allow increasing of etch rate and throughput. Additionally, use of aggressive etching step or etching step with low selectivity will allow removing polymer from surface of non-etching material and after fine-tuning it is possible to reach condition when after each cycle target material is etched at reasonable rate when non-etching material remains in condition close to initial.

In Example 30, cyclic etching process was developed using condition with infinite selectivity etching of Si₃N₄ from Example 29 for the first step inside etching cycles. As it could be observed from FIG. 32, use of cyclic etching recipe including selective and aggressive etching steps inside each cycle allows to achieve reasonably fast etch rate of Si₃N₄ when nearly no polymer was deposited on SiO₂ and SiON and few tens of nanometers of polymer were deposited on other materials. Current etching process was optimized for etching of Si₃N₄ selectively to SiO₂ and SiON; however, cyclic etching process may be further tuned to etch Si₃N₄ selectively to other tested materials by altering each step duration of process conditions. In Example 30 duration of steps inside the cycle was changed after first cycle due to surface modification of non-etching material. Thin film of polymer (few nm) was remaining on surface of SiO₂ and SiON after first cycle resulting in change of polymer deposition rate starting from second cycle. Important observation from FIG. 32 is that polymer growth was reduced by utilization of cyclic recipe and polymer thickness was not strongly developing after 2nd and following cycles.

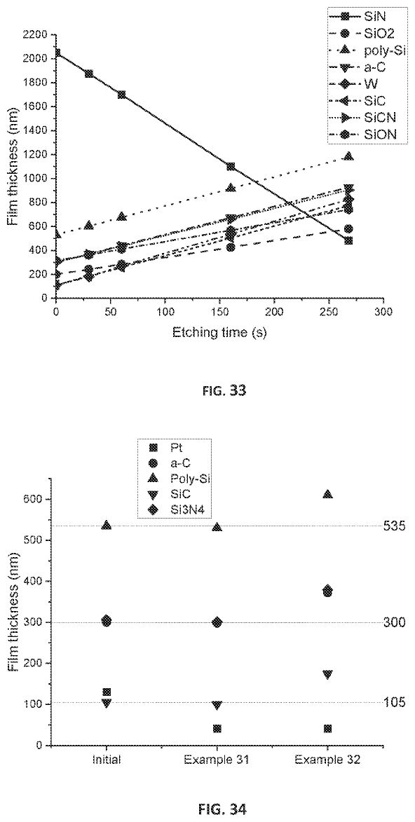

FIG. 33 presents estimated thickness of studied materials films (reflecting etching of the film or deposition of polymer on surface of the film) for thickness of Si₃N₄ same as demonstrated on FIG. 32 if continuous infinite selectivity etching recipe of Si₃N₄ will be used instead of cyclic process. Estimation was based on condition from Example 29 featuring infinite selectivity etching of Si₃N₄ (25 sccm of C₄H₉F₃Si on FIG. 31) and assumption that etching or deposition rate scales linearly with increase of duration of the process.

From a comparison of FIG. 32 and FIG. 33, it could be clearly noted that it is possible to effectively reduce deposition of polymer on non-etching material and keeping non-etching material close to initial condition when developed cyclic recipe is employed. In the case of continuous selective etching polymer is continuously deposited during the process resulting in thickness of polymer higher than thickness of initial film for some of tested materials. Similar observation may be done for the Examples 31 and 32. As it shown in FIG. 34, if Pt is etched using cyclic recipe from Example 31 high selectivity of etching of Pt to a-C, poly Si and SiC (selectivity to a-C is 45, to poly-Si is 18, to Si₃N₄ is 18 and to SiC is 18) may be achieve when no polymer is remaining on non-etching materials. In contrast, if Pt would be etched using continuous recipe from Example 32, it would result in deposition of thick polymer on non-etching materials, which despite infinite selectivity can limit application of the process due to problems with further processing of the workpiece with thick polymer film.

Presence of thick polymer after continuous selective etching will require use of cleaning recipe after the etching process to remove polymer, which may damage exposed target material, mask and structure further limiting use of the selective etching process in fabrication of novel semiconductor devices. On the other hand, in the case of presently disclosed cyclic etching process only thin film of polymer or thin modified layer on surface of non-etching material will be present after etching process, which may be easily removed by sort cleaning, minimizing possible damage and reducing processing time. Additionally, soft cleaning steps or another etching steps may be included inside each cycle or some defined cycles to further tune cyclic etching process and eliminate presence of polymer or modified layer on surface of non-etching material and keeping non-etching material film close to initial condition after cyclic etching.

On the other hand, different rate of deposition of polymer on the surface of various materials observed in examples 1-7 may be used for development of cyclic etching recipe using steps within each cycle including deposition of polymer and etching. For instance in FIG. 26 at condition when 1.25 sccm of C₅H₉F₅Si was used thinner film of polymer deposited on a-C and SiO₂ comparing to W, SiN and poly-Si; in FIG. 28 at condition when 15 sccm flow of O₂ was used only few nanometers of polymer deposited on SiO₂, when more than 40 nm deposited on a-C, Si₃N₄ and poly-Si after 1 min process. If demonstrated deposition of polymer with different rate on various materials will be used as a first step inside cycle and will be followed by non-selective etching step, it will result in removal of thinnest film of polymer and etching of exposed material under thinnest film first, when another films will have some polymer remaining due to higher thickness of polymer film after deposition step. Fine tuning of cyclic etching process as in Example 30 will allow to etch target material and keep the non-etching material close to initial condition after cyclic etch process, if target material is material with lowest polymer deposition rate from selected group of materials.

Results demonstrated in the present disclosure show that reach polymer deposition with variable rate depending on the target material and etching of particular materials with infinite selectivity which is possible when Si-containing hydrofluorocarbon is added to the process gas mixture (Examples 23 to 32) looks promising for development of cyclic etching processes. It was further demonstrated, that it is possible to inhibit polymer deposition using cyclic process and keep condition of the non-etching material close to initial, when in the case of continuous process with infinite selectivity thick polymer film will deposit, requiring further processing or additional cleaning. Developed cyclic etching process using Si-containing hydrofluorocarbon in at least one of the cycle step looks promising for advanced patterning of substrate during fabrication of semiconductor device. In particular for the application of multiple patterning, multicolor etching or low-contrast etching, when typically several Si-containing films are presented on the substrate and exposed during the etching process. Commonly used Si-containing films in those processes are SiO₂, Si₃N₄, SiC, SiCN and SiON; therefore, demonstrated capability of selective etching of SiO₂, Si₃N₄ or both of those materials achieved by cyclic etching process with addition of Si-containing hydrofluorocarbon to the process gas mixture in at least one of cycle steps will be essential for advanced patterning of a substrate using multicolor etching. Additionally, demonstrated capability of selective etching or deposition of thinner polymer film on organic material (e.g., a-C) looks promising for organic mask patterning or removal because it will provide high selectivity to materials other than the processed mask and will not lead to deposition of thick film on those materials.

Although the subject matter described herein may be described in the context of illustrative implementations to process one or more computing application features/operations for a computing application having user-interactive components the subject matter is not limited to these particular embodiments. Rather, the techniques described herein can be applied to any suitable type of user-interactive component execution management methods, systems, platforms, and/or apparatus.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

1. An etching method for forming an aperture in a substrate, the method comprising:
mounting the substrate on a mounting table in a reactor, the substrate including a Si-containing film deposited thereon and a patterned mask layer deposited on the Si-containing film;
introducing an etching gas containing a vapor of a Si-containing hydrofluorocarbon into the reactor;
converting the etching gas into a plasma; and
allowing an etching reaction to proceed between the plasma and the Si-containing film so that the Si-containing film is etched versus the patterned mask layer, thereby forming the aperture.

2. The method of claim 1, wherein the etching gas contains a vapor of a fluorocarbon or hydrofluorocarbon selected from CF₄, C₂F₆, C₃F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇.

3. The method of claim 1, wherein the etching gas contains an oxidizing gas selected from O₂, O₃, CO, CO₂, SO, SO₂, FNO, NO, N₂O, NO₂, H₂O, COS or combinations thereof.

4. The method of claim 1, wherein the etching gas contains an inert gas selected from He, Ar, Xe, Kr or Ne.

5. The method of claim 1, wherein the etching gas contains an additional gas selected from H₂, SF₆, NF₃, N₂, NH₃, Cl₂, BCl₃, BF₃, Br₂, F₂, HBr, HCl or combinations thereof.

6. The method of claim 1, wherein the Si-containing hydrofluorocarbon has a general formula CₓH_{y}F_{z}Siₙ, where 1≤x≤6, 1≤y≤9, 1≤z≤15, n=1 or 2.

7. The method of claim 6, wherein the Si-containing hydrofluorocarbon comprises one or more methyl group(s).

8. The method of claim 7, wherein the Si-containing hydrofluorocarbon comprises at least one methyl group attached to the Si atom.

9. The method of claim 1, wherein the Si-containing hydrofluorocarbon is selected from CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom.

10. The method of claim 1, wherein the Si-containing hydrofluorocarbon is CH₃F₃Si, or its isomers.

11. The method of claim 1, wherein the Si-containing hydrofluorocarbon is C₂H₆F₂Si, or its isomers.

12. The method of claim 1, wherein the Si-containing hydrofluorocarbon is C₄H₉F₃Si or its isomers.

13. The method of claim 1, wherein the Si-containing hydrofluorocarbon is C₅H₉F₅Si or its isomers.

14. The method of claim 1, wherein the silicon-containing film comprises a layer of SiₐO_{b}H_{c}C_{d}Nₑ, where a>0, b, c, d and e≥0, selected from silicon oxide, silicon nitride, crystalline Si, poly-silicon, polycrystalline silicon, amorphous silicon, low-k SiCOH, SiOCN, SiC, SiON, or a layer of alternating silicon oxide and silicon nitride (ONON) layers or alternating silicon oxide and poly-silicon (OPOP) layers.

15. The method of claim 1, wherein the aperture formed in the substrate has an aspect ratio between approximately 1:1 and approximately 500:1.

16. An etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing C₅H₉F₅Si into the reactor;
converting the etching gas into a plasma; and
allowing an etching reaction to proceed between the plasma and the silicon-containing film so that the silicon-containing film is etched versus the patterned mask layer forming the aperture.

17. An etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing C₄H₉F₃Si into the reactor;
converting the etching gas into a plasma; and
allowing an etching reaction to proceed between the plasma and the silicon-containing film so that the silicon-containing film is etched versus the patterned mask layer forming the aperture.

18. An etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing CH₃F₃Si into the reactor;
converting the etching gas into a plasma; and
allowing an etching reaction to proceed between the plasma and the silicon-containing film so that the silicon-containing film is etched versus the patterned mask layer forming the aperture.

19. An etching method for forming an aperture in a substrate, the method comprising:
mounting the substrate on a mounting table in a reactor, the substrate having a silicon-containing film deposited thereon and a patterned mask layer deposited on the silicon-containing film;
introducing an etching gas containing C₂H₆F₂Si into the reactor;
converting the etching gas into a plasma; and
allowing an etching reaction to proceed between the plasma and the silicon-containing film so that the silicon-containing film is etched versus the patterned mask layer forming the aperture.

20. An etching gas composition suitable for use in semiconductor etching reactions, the etching gas composition comprising:
a first etchant vapor being a Si-containing hydrofluorocarbon selected from the formula CₓH_{y}F_{z}Siₙ, where 1≤x≤6, 1≤y≤9, 1≤z≤15, n=1 or 2.

21. The etching gas composition of claim 20, wherein the first etching gas comprises one or more methyl group(s).

22. The etching gas composition of claim 20, wherein the first etching gas comprises at least one methyl group attached to the Si atom.

23. The etching gas composition of claim 20, wherein the first etching gas is selected from CH₄F₂Si, CH₃F₃Si, C₂H₆F₂Si, C₃H₉FSi, C₄H₉F₃Si, C₅H₉F₅Si, C₄H₁₀F₄Si₂, C₂H₆F₄Si₂, C₃H₉F₃Si₂, C₆H₉F₇Si or their isomers that has at least one methyl group attached to the Si atom.

24. The etching gas composition of claim 20, further comprising a second etchant vapor selected from a hydrofluorocarbon or fluorocarbon.

25. The etching gas composition of claim 24, wherein the hydrofluorocarbon or fluorocarbon is selected from CF₄, C₂F₆, C₅F₆, C₄F₆, C₄F₈, C₅F₈, C₅F₁₀, C₆F₁₂, C₇F₁₄, C₈F₁₆, CH₂F₂, CH₃F, CHF₃, C₂H₅F, C₃H₇F, C₅HF₇, C₃H₂F₆, C₃H₄F₂, C₃H₂F₄, C₄H₂F₆ or C₄H₃F₇.

26. The etching gas composition of claim 20, further comprising an oxidizing gas selected from O₂, O₃, CO, CO₂, SO, SO₂, FNO, NO, N₂O, NO₂, H₂O or COS.

27. The etching gas composition of claim 20, further comprising an inert gas selected from He, Ar, Xe, Kr or Ne.

28. The etching gas composition of claim 20, further comprising an additional gas selected from H₂, SF₆, NF₃, N₂, NH₃, Cl₂, BCl₃, BF₃, Br₂, F₂, HBr, HCl or combinations thereof.

29. The etching gas composition of claim 20, wherein a purity of the first etching gas is greater than 95% v/v.

30. The etching gas composition of claim 20, wherein a purity of the first etching gas is greater than 99.99% v/v.

31. The etching gas composition of claim 20, wherein the boiling point of the first etching gas is between approximately −50 to 250° C.

32. Use of the etching gas composition of claim 20, in a semiconductor etching process.
